(19) United States
(12) Patent Application Publication
(10) Pub. No.: US 2019/0035771 A1
(43) Pub. Date: Jan. 31, 2019

(54) POWER MODULE

(71) Applicant: ROHM CO., LTD., Kyoto-shi (JP)

(72) Inventors: Seita IWAHASHI, Kyoto-shi (JP); Masao SAITO, Kyoto-shi (JP)

(21) Appl. No.: 16/135,780

(22) Filed: Sep. 19, 2018

Related U.S. Application Data
(63) Continuation of application No. PCT/JP2017/013741, filed on Mar. 31, 2017.

(30) Foreign Application Priority Data
Apr. 4, 2016 (JP) 2016-075161
Apr. 27, 2016 (JP) 2016-089103

(51) Int. Cl. H01L 25/07; H01L 25/18; H02M 7/48; H01L 23/12; H01L 23/538; H01L 23/498; H01L 23/373; H01L 23/00; H05K 1/11; H05K 1/02

(52) U.S. Cl. CPC H01L 25/072; H05K 2201/095; H02M 7/48; H01L 23/12; H01L 23/5385; H01L 23/49838; H01L 23/3735; H01L 24/49; H05K 1/115; H05K 1/0296; H01L 2224/48091; H01L 2924/181; H01L 2924/13055; H01L 2924/13091; H01L 25/18

(57) ABSTRACT

A power module includes: a first insulating substrate including a first conductive layer; a first semiconductor device Q4 disposed on the first conductive layer 14D, the first semiconductor device of which one side of a main electrode is connected to the first conductive layer; a second insulating substrate disposed on the first insulating substrate so as to be opposite to the first semiconductor device and including a second conductive layer and a third conductive layer; a first pillar electrode connecting between the first conductive layer and the second conductive layer; and a second pillar electrode connecting between another side of the main electrode of the first semiconductor device and the third conductive layer. The second conductive layer is connected to any one of a positive or negative electrode pattern for supplying power to the first semiconductor device, and the third conductive layer is connected to another electrode pattern.

### CROSS REFERENCE TO RELATED APPLICATIONS

This is a continuation application (CA) of PCT Application No. PCT/JP2017/13741, filed on Mar. 31, 2017, which claims priority to Japan Patent Applications No. P2016-075161 filed on Apr. 4, 2016 and No. P2016-089103 filed on Apr. 27, 2016 and is based upon and claims the benefit of priority from prior Japanese Patent Applications No. P2016-075161 filed on Apr. 4, 2016, No. P2016-089103 filed on Apr. 27, 2016 and PCT Application No. PCT/JP2017/13741, filed on Mar. 31, 2017, the entire contents of each of which are incorporated herein by reference.

### FIELD

The embodiments described herein relate a power module.

### BACKGROUND

Many research institutions have been currently conducting research to develop Silicon Carbide (SiC) devices. Advantages of SiC power devices over Si power devices include low on resistance, high switching speed, high temperature operation characteristics, etc.

SiC power modules can conduct a large electric current, and can be easily operated under high temperature conditions operation, since losses produced by Si power devices are relatively smaller. However, power module design has been required for achieving such SiC power modules.

SiC power devices constitute power modules formed by resin-sealing with transfer molds. High reliability is required for power modules since such power modules are operated at high temperatures.

There has also been disclosed an example of holding adhesion of sealing resins in order to improve reliability of resin sealed power modules.

Moreover there has also been disclosed a conventional example for preventing deformations of power modules.

Furthermore, there has also been disclosed an example for preventing warped deformations of power modules in order to improve thermal fatigue life, even at high temperatures.

Furthermore, there has also been disclosed a conventional example of thermally dissipating heat of power modules from both surfaces thereof.

### SUMMARY

The embodiments provide a highly reliable power module capable of being miniaturized and a fabrication method for such a power module.

Moreover, the embodiments provide a highly reliable ultra-thin power module capable of being miniaturized and a fabrication method for such a power module.

According to one aspect of the embodiments, there is provided a power module comprising: a first insulating substrate comprising a first conductive layer; a first semiconductor device disposed on the first conductive layer, the first semiconductor device of which one side of a main electrode is connected to the first conductive layer; a second insulating substrate disposed on the first insulating substrate so as to be opposite to the first semiconductor device, the second insulating substrate including a second conductive layer formed on a front side surface thereof and a third conductive layer formed on a back side surface thereof; a first pillar electrode configured to connect between the first conductive layer and the second conductive layer; and a second pillar electrode configured to connect between another side of the main electrode of the first semiconductor device and the third conductive layer, wherein the second conductive layer is connected to any one of a positive electrode pattern or a negative electrode pattern for supplying power to the first semiconductor device, and the third conductive layer is connected to another electrode pattern.

According to another aspect of the embodiments, there is provided a fabrication method of a power module, the fabrication method comprising: mounting a semiconductor device on a conductive layer on a front side surface of a first insulating substrate; forming at least one pillar electrode on each of the main electrode of the semiconductor device and a surface of the conductive layer; and connecting any one of edge parts of the pillar electrode to the conductive layer of one surface of the second insulating substrate disposed to be opposite to the first insulating substrate, and connecting another edge part of the pillar electrode to the conductive layer on another surface of the second insulating substrate.

According to still another aspect of the embodiments, there is provided a power module comprising: a first insulating substrate; a second insulating substrate disposed at an upper side of the first insulating substrate; and a first semiconductor device disposed on the first insulating substrate, the first semiconductor device comprising a first main electrode and a first control electrode on a front side surface thereof, wherein the first main electrode is disposed at a superimposed portion between the first insulating substrate and the second insulating substrate, and the first control electrode is disposed at a non-superimposed portion between the first insulating substrate and the second insulating substrate.

According to yet another aspect of the embodiments, there is provided a power module comprising: a first insulating substrate comprising a first conductive layer; a second insulating substrate of which at least a portion is disposed so as to be opposite to the first insulating substrate, the second insulating substrate comprising a second conductive layer formed so as to be opposite to the first conductive layer; a first semiconductor device of which a first main electrode is connected to the first conductive layer; a second semiconductor device of which a first main electrode is connected to the second conductive layer; a non-superimposed portion comprising only any one of the first conductive layer and the second conductive layer, in a planar view; and a superimposed portion comprising both of the first conductive layer and the second conductive layer, in a planar view, wherein the second main electrode of the first semiconductor device and the second conductive layer, and the second main electrode of the second semiconductor device and the first conductive layer are disposed at the superimposed portion, in a planar view, and the first control electrode of the first semiconductor device and the second control electrode of the second semiconductor device are disposed at the non-superimposed portion, in a planar view.

According to a further aspect of the embodiments, there is provided a fabrication method of a power module, the fabrication method comprising: connecting a first main electrode of a first semiconductor device to a first conductive layer on an upper side surface of a first insulating substrate; connecting a first main electrode of a second semiconductor device to a second conductive layer on a lower side surface of a second insulating substrate; and connecting the first insulating substrate and the second insulating substrate to each other in a disposition so that a second main electrode of the first semiconductor device and the second conductive layer, and the second main electrode of the second semiconductor device and first conductive layer are disposed at the superimposed portion, in a planar view, and a first control electrode of the first semiconductor device and the second conductive layer are not superimposed on each other, and a second control electrode of the second semiconductor device and the first conductive layer are not superimposed on each other. According to a still further aspect of the embodiments, there is provided a fabrication method of a power module, the fabrication method comprising: pattern-forming a non-superimposed portion including only any one of a first conductive layer and a second conductive layers and a superimposed portion including both of the first conductive layer and the second conductive layer, in a planar view of a second insulating substrate disposed so as to be opposite to at least one surface of a first insulating substrate including the first conductive layer, the second insulating substrate including the second conductive layer formed so as to be opposite to the first conductive layer; connecting a first main electrode of the first semiconductor device to the superimposed portion of the first conductive layer in a position where a first control electrode of the first semiconductor device is disposed at the non-superimposed portion; connecting a first main electrode of the second semiconductor device to the superimposed portion of the second conductive layer in a position where a second control electrode of the second semiconductor device is disposed at the non-superimposed portion; and connecting a second main electrode of the first semiconductor device to the second conductive layer, and connecting a second main electrode of the second semiconductor device to the first conductive layer.

According to the embodiments, there can be provided the highly reliable power module capable of being miniaturized and the fabrication method for such a power module.

According to the embodiments, there can be provided the highly reliable ultra-thin power module capable of being miniaturized and the fabrication method for such a power module.

### BRIEF DESCRIPTION OF DRAWINGS

FIG. 1 is a schematic plain diagram showing a principal portion of a 2-in-1 module according to a comparative example 1.

FIG. 2 is a circuit configuration diagram showing the 2-in-1 module according to the comparative example 1 to which SiC Metal Oxide Semiconductor Field Effect Transistors (MOSFET) are applied as a semiconductor device.

FIG. 3 is a schematic cross-sectional structure diagram taken in the line I-I of FIG. 1.

FIG. 4 is a schematic plain diagram showing a principal portion of a 6-in-1 module according to a comparative example 2.

FIG. 5 is a circuit configuration diagram showing the 6-in-1 module according to the comparative example 2 to which SiC MOSFETs are applied as a semiconductor device.

FIG. 6 is a schematic cross-sectional structure diagram showing a basic configuration of power modules according first to third embodiments.

FIG. 7A is a schematic cross-sectional diagram of a second insulating substrate of power modules according first to sixth embodiments.

FIG. 7B is a schematic cross-sectional diagram showing a first insulating substrate of the power modules according first to sixth embodiments.

FIG. 8A is a schematic plain diagram showing the power module according to the first embodiment.

FIG. 8B is a schematic plain diagram showing a mounting surface of the first insulating substrate of the power module according to the first embodiment.

FIG. 9 is a schematic cross-sectional structure diagram taken in the line II-II of FIG. 8B.

FIG. 10A is a schematic plain diagram showing the power module according to the second embodiment.

FIG. 10B is a schematic plain diagram showing a configuration after mounting of the first insulating substrate of the power module according to the second embodiment.

FIG. 11A is a schematic plain diagram showing a surface opposite to semiconductor devices of the second insulating substrate of the power module according to the second embodiment.

FIG. 11B is a schematic plain diagram of a surface at an opposite side of the surface shown in FIG. 11A.

FIG. 12 is a schematic cross-sectional structure diagram taken in the line of FIG. 11B.

FIG. 13 is a circuit configuration diagram of a 6-in-1 module to which SiC MOSFETs are applied as a semiconductor device and a direction of an electric current is added.

FIG. 14A is a schematic plain diagram showing a surface opposite to semiconductor devices of the second insulating substrate of the power module according to a modified example of the second embodiment.

FIG. 14B is a schematic plain diagram of a surface side opposite to FIG. 14A.

FIG. 15 is a schematic cross-sectional structure diagram taken in the line IV-IV of FIG. 14A.

FIG. 16 is a schematic plain diagram showing a configuration after mounting of the first insulating substrate of the power module according to the third embodiment.

FIG. 17 is a schematic plain diagram showing a surface opposite to semiconductor devices of the second insulating substrate of the power module according to the third embodiment.

FIG. 18 is a schematic plain diagram showing a surface at an opposite side of the surface of the second insulating substrate shown in FIG. 17.

FIG. 19 is a schematic side view diagram showing the second insulating substrate of the power module according to the third embodiment observed from an output terminal side.

FIG. 20 is a schematic bird's-eye view configuration diagram showing the second insulating substrate shown in FIG. 19 observed from the arrow A of FIG. 17.

FIG. 21 is a schematic plain diagram showing the first insulating substrate of the power module according to the third embodiment.

FIG. 22 is a schematic bird's-eye view configuration diagram showing the first insulating substrate after mounting semiconductor devices thereon and connecting pillar electrodes thereto, observed from the arrow B of FIG. 21.

FIG. 23 is a schematic bird's-eye view configuration diagram showing the first insulating substrate after mounting the semiconductor devices thereon and connecting the pillar electrode thereto, observed from the arrow C of FIG. 21.

FIG. 24 is a schematic bird's-eye view configuration diagram showing an aspect immediately before bonding the first insulating substrate of the power module according to the third embodiment to the second insulating substrate observed from the arrow C of FIG. 21.

FIG. 25 is a schematic plain diagram showing an aspect after bonding the first insulating substrate to the second insulating substrate of the power module according to the third embodiment.

FIG. 26 is a schematic plain diagram showing an outer appearance of the power module according to the third embodiment subjected to resin molding.

FIG. 27 is a schematic bird's-eye view configuration diagram showing the outer appearance of the power module according to the third embodiment subjected to the resin molding.

FIG. 28A is a schematic circuit representative diagram showing an SiC MOSFET of a 1-in-1 module, which is the power module according to the embodiments.

FIG. 28B is a schematic circuit representative diagram showing an IGBT of a 1-in-1 module.

FIG. 29 is a detail circuit representative diagram showing the SiC MOSFET of the 1-in-1 module, which is the power module according to the embodiments.

FIG. 30A is a schematic circuit representative diagram showing an SiC MOSFET of a 2-in-1 module, which is the power module according to the embodiments.

FIG. 30B is a schematic circuit representative diagram showing an IGBT of a 2-in-1 module, which is the power module according to the embodiments.

FIG. 31A is a schematic cross-sectional structure diagram showing an SiC MOSFET, which is an example of a semiconductor device applied to the power module according to the embodiments.

FIG. 31B is a schematic cross-sectional structure diagram showing an IGBT, which is an example of the semiconductor device to be applied to the power module according to the embodiments.

FIG. 32 is a schematic cross-sectional structure diagram showing an SiC MOSFET including a source pad electrode SP and a gate pad electrode GP, which is an example of the semiconductor device applied to the power module according to the embodiments.

FIG. 33 is a schematic cross-sectional structure diagram showing an IGBT including an emitter pad electrode EP and a gate pad electrode GP, which is an example of the semiconductor device to be applied to the power module according to the embodiments.

FIG. 34 is a schematic cross-sectional structure diagram showing an SiC Double Implanted MOSFET (SiC DIMOSFET), which is an example of the semiconductor device applicable to the power module according to the embodiments.

FIG. 35 is a schematic cross-sectional structure diagram showing an SiC Trench MISFET (SiC TMISFET), which is an example of a semiconductor device which can be applied to the power module according to the embodiments.

FIG. 36A shows an example of a circuit configuration in which the SiC MOSFET is applied as a semiconductor device, and a snubber capacitor is connected between a power terminal PL and an earth terminal (ground terminal) NL, in a schematic circuit configuration of a three-phase alternating current (AC) inverter composed using the power module according to the embodiments.

FIG. 36B shows an example of a circuit configuration in which the IGBT is applied as a semiconductor device, and the snubber capacitor is connected between the power terminal PL and the earth terminal (ground terminal) NL, in the schematic circuit configuration of a three-phase AC inverter composed using the power module according to the embodiments.

FIG. 37 is a schematic circuit configuration diagram showing a three-phase AC inverter composed using the power module according to the embodiments to which the SiC MOSFET is applied as the semiconductor device.

FIG. 38 is a schematic circuit configuration diagram showing a three-phase AC inverter composed using the power module according to the embodiments to which the IGBT is applied as the semiconductor device.

FIG. 39 is a schematic cross-sectional structure diagram showing a power module including a cooling apparatus, which is the power module according to the first to third embodiments.

FIG. 40 is a schematic plain diagram showing a principal portion of a 2-in-1 module according to a basic technology of the fourth to sixth embodiments.

FIG. 41 is a schematic cross-sectional structure diagram taken in the line IA-IA of FIG. 40.

FIG. 42 is a schematic plain diagram showing a principal portion of a power module according to the fourth embodiment.

FIG. 43 is a schematic cross-sectional structure diagram taken in the line IIA-IIA of FIG. 42.

FIG. 44 is a schematic side view diagram showing a side surface of the first insulating substrate and a side surface of the second insulating substrate, after mounting the power module thereon.

FIG. 45A is a schematic plain diagram showing an example of a planar positional relationship between the first insulating substrate and the second insulating substrate.

FIG. 45B is a schematic plain diagram showing another example of the planar positional relationship between the first insulating substrate and the second insulating substrate.

FIG. 45C is a schematic plain diagram showing still another example of the planar positional relationship between the first insulating substrate and the second insulating substrate.

FIG. 46 is a schematic plain diagram showing a principal portion of a modified example of the power module according to the fourth embodiment.

FIG. 47 is a schematic cross-sectional structure diagram taken in the line IIIA-IIIA of FIG. 46.

FIG. 48A is a schematic plain diagram showing a plane of the first insulating substrate after mounting the power module according to the fifth embodiment thereon.

FIG. 48B is a schematic plain diagram showing a plane of the second insulating substrate after mounting the power module according to the fifth embodiment thereon.

FIG. 49 is a schematic cross-sectional structure diagram taken in the line IVA-IVA of FIGS. 48A and 48B.

FIG. 50 is a schematic cross-sectional structure diagram taken in the VA-VA of FIGS. 48A and 48B.

FIG. 51 is a schematic cross-sectional structure diagram taken in the line VIA-VIA of FIGS. 48A and 48B.

FIG. 52 is a schematic cross-sectional structure diagram taken in the line VIA-VIA of FIGS. 48A and 48B, according to a modified example.

FIG. 53 is a schematic cross-sectional structure diagram taken in the line VA-VA of FIGS. 48A and 48B, according to the modified example.

FIG. 54 is a schematic plain diagram showing a plane of the second insulating substrate of the power module according to the sixth embodiment.

FIG. 55 is a schematic plain diagram showing a plane of the second insulating substrate of the power module according to the sixth embodiment after mounting.

FIG. 56 is a schematic plain diagram showing a plane of the first insulating substrate of the power module according to the sixth embodiment after mounting.

FIG. 57 is a circuit configuration diagram showing a 6-in-1 module according to the sixth embodiment to which SiC MOSFETs are applied as a semiconductor device.

FIG. 58 is a schematic cross-sectional structure diagram taken in the VIIA-VIIA shown in FIGS. 54, 55, and 56.

FIG. 59 is a schematic plain diagram showing an outer appearance of the second insulating substrate of the power module according to the sixth embodiment.

FIG. 60 is a schematic plain diagram showing a pattern of a back side surface of the second insulating substrate shown in FIG. 55.

FIG. 61 is a schematic plain diagram showing an outer appearance of the first insulating substrate of the power module according to the sixth embodiment.

FIG. 62 is a schematic bird's-eye view configuration diagram showing an aspect immediately before bonding the first insulating substrate of the power module according to the sixth embodiment to the second insulating substrate observed from the arrow A of FIG. 59.

FIG. 63 is a schematic plain diagram showing an aspect after bonding the first insulating substrate to the second insulating substrate of the power module according to the sixth embodiment.

FIG. 64 is a schematic plain diagram showing an outer appearance of the power module according to the sixth embodiment subjected to resin molding.

FIG. 65 is a schematic plain diagram showing an outer appearance of the power module according to the sixth embodiment subjected to the resin molding, observed from the arrow A of FIG. 64.

FIG. 66 is a schematic cross-sectional structure diagram showing a power module including a cooling apparatus, which is the power module according to the fourth to sixth embodiments.

### DESCRIPTION OF EMBODIMENTS

Next, the embodiments will be described with reference to drawings. In the description of the following drawings, the identical or similar reference sign is attached to the identical or similar part. However, it should be noted that the drawings are schematic and therefore the relation between thickness and the plane size and the ratio of the thickness differs from an actual thing. Therefore, detailed thickness and size should be determined in consideration of the following explanation. Of course, the part from which the relation and ratio of a mutual size differ also in mutually drawings is included.

Moreover, the embodiments shown hereinafter exemplify the apparatus and method for materializing the technical idea; and the embodiments do not specify the material, shape, structure, placement, etc. of each component part as the following. The embodiments may be changed without departing from the spirit or scope of claims.

### COMPARATIVE EXAMPLES OF FIRST TO THIRD EMBODIMENTS

### Comparative Example 1

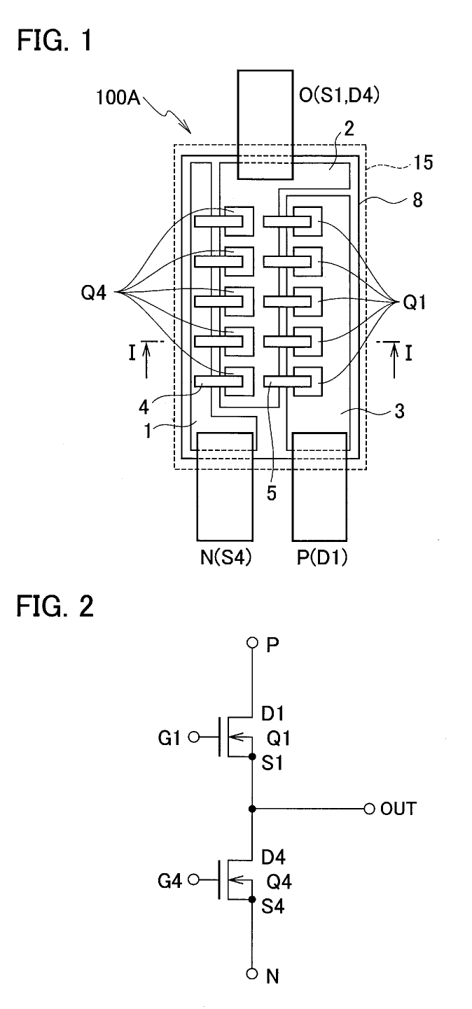

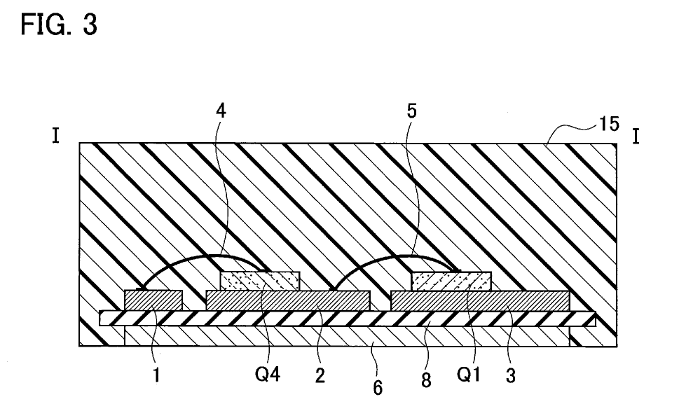

FIG. 1 shows a schematic plain diagram of a principal portion of a power module 100A according to a comparative example 1, and FIG. 2 shows a circuit configuration of a 2-in-1 module corresponding to FIG. 1 to which SiC MOSFETs are applied, as a semiconductor device (chip). Moreover, FIG. 3 shows a schematic cross-sectional structure taken in the line I-I of FIG. 1.

The power module 100A includes: an insulating substrate 8; a source electrode pattern 1, an output electrode pattern 2, and a drain electrode pattern 3, disposed on the insulating substrate 8; a semiconductor device Q1 disposed on the drain electrode pattern 3; a lead member 5 connected between the semiconductor device Q1 and the output electrode pattern 2; a semiconductor device Q4 disposed on the output electrode pattern 2; a lead member 4 connected between the semiconductor device Q4 and the source electrode pattern 1; a negative-side power terminal N configured to extract the source electrode pattern 1 to the outside; a positive-side power terminal P configured to extract the drain electrode pattern 3 to the outside; and an output terminal O configured to extract the output electrode pattern 2 to the outside.

The semiconductor devices Q1 and Q4 of the comparative example 1 respectively are SiC MOSFETs, for example. FIG. 1 shows an example of 5-chip semiconductor devices Q1 arranged in parallel to one another and 5-chip semiconductor devices Q4 arranged in parallel. An illustration of a gate signal electrode pattern etc. which are control terminals of the semiconductor devices Q1 and Q4 is omitted.

A principal portion of the power module 100A is sealed with a mold resin 15. The insulating substrate 8 is a substrate having conductive layers on both surfaces thereof, and the conductive layer 6 formed on a surface at an opposite side where the semiconductor devices Q1, Q4 are mounted is exposed to the outside thereof, for example (refer to FIG. 3).

The positive-side power terminal P and the drain electrode pattern 3 are connected to each other by means of soldering etc. A source electrode pad of the semiconductor device Q1 disposed on the drain electrode pattern 3 and the output electrode pattern 2 are connected to each other with the lead member 5.

A source electrode pad of the semiconductor device Q4 disposed on the output electrode pattern 2 and the source electrode pattern 1 are connected to each other with the lead member 4. The source electrode pattern 1 and the negative-side power terminal N are connected to each other by means of soldering etc.

The negative-side power terminal N, the positive-side power terminal P, and the output terminal O of the power module 100A are led from the same plane. Accordingly, if each terminal is led from one side, a size of the one side of the power module 100A becomes large, and therefore it is difficult to miniaturize the power module 100A.

### Comparative Example 2

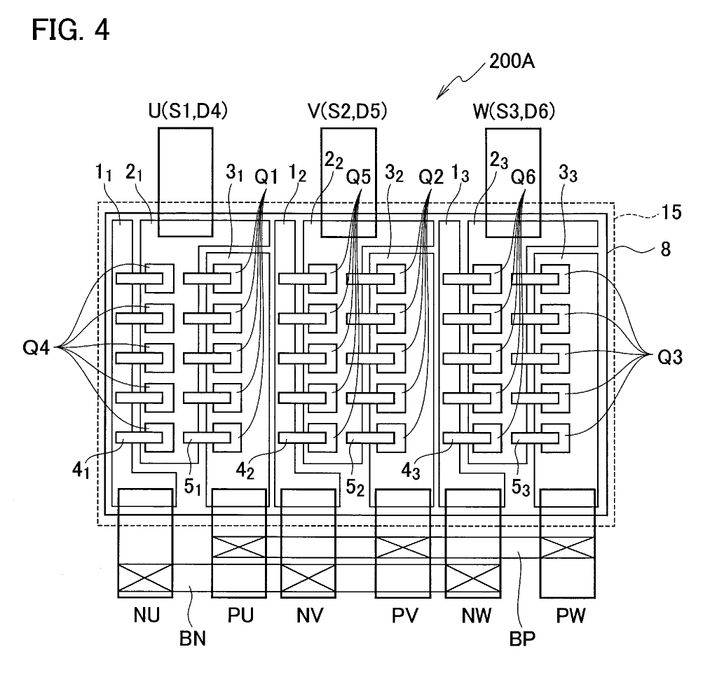

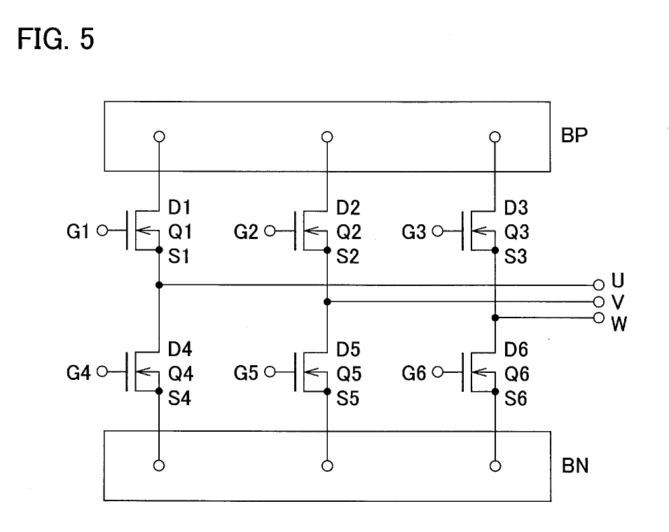

FIG. 4 shows a schematic plain diagram of a principal portion of a power module 200A according to a comparative example 2, and FIG. 5 shows a circuit configuration of a 6-in-1 module corresponding to FIG. 4 to which SiC MOSFETs are applied, as a semiconductor device (chip).

Reference signs shown hereinafter will be expressed with a subscript (s) in order to clarify a position (s) in power modules, but such a subscript (s) will be omitted if it is unnecessary to clarify.

The power module 200A is a three-phase (U, V, W) output power module in which three power modules 100A are arranged. The power module 200A includes: three sets of a source electrode pattern 1, an output electrode pattern 2, and a drain electrode pattern 3, formed on the insulating substrate 8; semiconductor devices Q4, Q1, Q5, Q2, Q6, Q3; lead members 4, 5; output terminals U, V, W of the respective phase; negative-side power terminals NU, NV, NW of the respective phase; and positive-side power terminals PU, PV, PW of the respective phase.

The respective electrode patterns are disposed in a long side direction of the insulating substrate 8 of which a plane shape is a rectangle, in order of the source electrode pattern 1₁, the output electrode pattern 2₁, the drain electrode pattern 3₁, the source electrode pattern 1₂, the output electrode pattern 2₂, the drain electrode pattern 3₂, the source electrode pattern 1₃, the output electrode pattern 2₃, and the drain electrode pattern 3₃.

The semiconductor device Q4 is disposed on the output electrode pattern 2₁, the semiconductor device Q1 is disposed on the drain electrode pattern 3₁, the semiconductor device Q5 is disposed on the output electrode pattern 2₂, the semiconductor device Q2 is disposed on the drain electrode pattern 3₂, the semiconductor device Q6 is disposed on the output electrode pattern 2₃, and the semiconductor device Q3 is disposed on the drain electrode pattern 3₃. 5-chip semiconductor devices Q4 are arranged in parallel to one another, 5-chip semiconductor devices Q1 are arranged in parallel to one another, 5-chip semiconductor devices Q5 are arranged in parallel to one another, 5-chip semiconductor devices Q2 are arranged in parallel to one another, 5-chip semiconductor devices Q6 are arranged in parallel to one another, and 5-chip semiconductor devices Q3 are arranged in parallel to one another.

The U-phase positive-side power terminal PU is connected to the drain electrode pattern 3₁ and is led to an opposite side of the semiconductor device Q1. The U-phase negative-side power terminal NU is connected to the source electrode pattern 1₁ and is led in the same direction as that of the U-phase positive-side power terminal PU. The drain electrode pattern 3₁ and the output electrode pattern 2₁ are connected to each other with the lead member 5₁ and the output electrode pattern 2₁ and the source electrode pattern 1₁ are connected to each other with the lead member 4₁, in the same manner as the power module 100A.

The connecting relationship between the U-phase positive-side power terminal PU and the U-phase negative-side power terminal NU is similarly applied to other V and W phases. Accordingly, the power terminals of the respective phases are led from one long side of the insulating substrate 8 towards the outside, in order of the U-phase negative-side power terminal NU, the U-phase positive-side power terminal PU, the V-phase negative-side power terminal NV, the V-phase positive-side power terminal PV, the W-phase negative-side power terminal NW, and the W-phase positive-side power terminal PW.

The output terminals U, V, W of the respective phases are connected to the output electrode patterns 2₁, 2₂, 2₃ of the respective phases and are led to the opposite side of the respective power terminals NU to PW.

The 6-in-1 module is composed by connecting three 2-in-1 modules in parallel to one another. Accordingly, the U-phase positive-side power terminal PU, V-phase positive-side power terminal PV, and the W-phase positive-side power terminal PW are connected to one another with a bus bar BP. Moreover, the U-phase negative-side power terminal NU, the V-phase negative-side power terminal NV, and the W-phase negative-side power terminal NW are connected to one another with a bus bar BN.

The bus bars BP and BN are different in polarity and therefore should be insulated from each other. Accordingly, a plane size of the power module becomes larger due to the bus bars BP and BN in the comparative example 2.

Moreover, it is more preferable that an inductance component becomes smaller, in the power modules configured to switch a large current. However, since a current path becomes longer due to the bus bars BP, BN, the inductance component also becomes larger. Moreover, since a shape of the power module becomes longer in one direction, a warpage also becomes larger. The warpage is proportional to the square of the length, for example.

### Basic Configuration of First to Third Embodiments

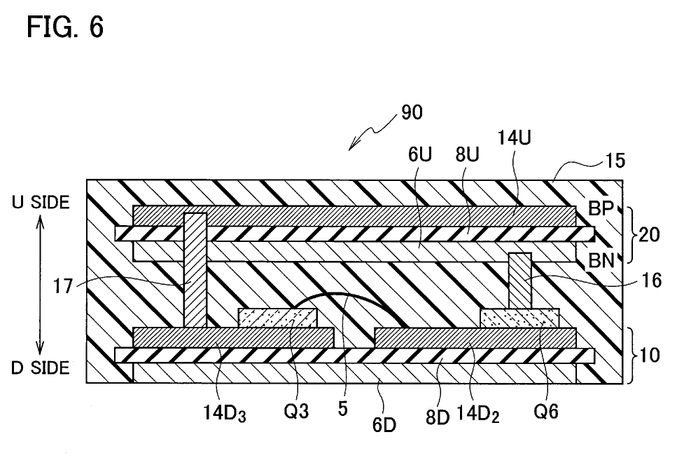

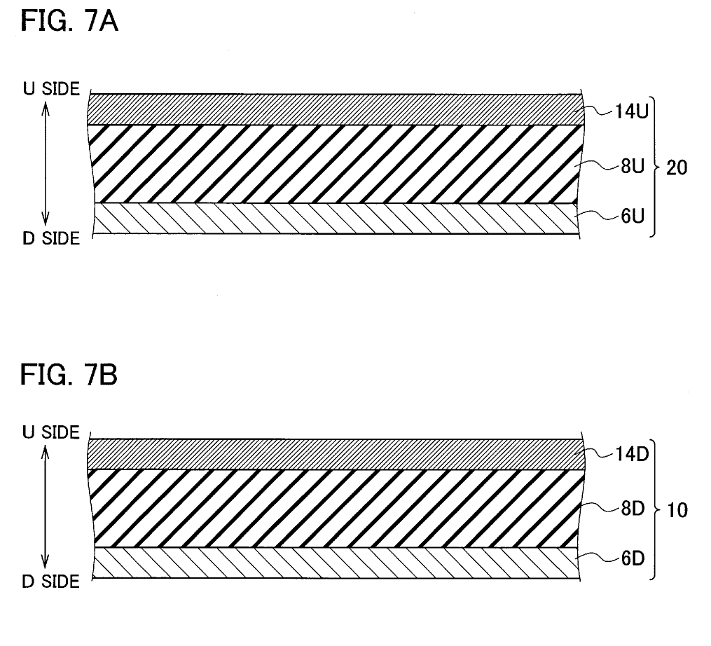

FIG. 6 shows a schematic cross-sectional structure diagram of a basic configuration of a power module 90 according to first to third embodiments. Moreover, FIGS. 7A and 7B show schematic cross-sectional structure diagrams of a first insulating substrate 10 and a second insulating substrate 20 included in the power module 90.

Although an arrangement example of the semiconductor devices Q3, Q6 constituting the W phase shown in FIG. 5 is shown in FIG. 6, the semiconductor devices Q1, Q4 which compose the U phase and the semiconductor devices Q2, Q5 which compose the V phase can similarly be arranged. An illustration of a top view diagram thereof is omitted.

As shown in FIG. 6, the power module 90 includes: a first insulating substrate 10 including conductive layers 14D₃, 14D₂; semiconductor devices Q3, Q6 respectively disposed on the conductive layers 14D₃, 14D₂; a second insulating substrate 20 disposed so as to be opposite to the semiconductor devices Q3, Q6, the second insulating substrate 20 including conductive layers 14U, 6U; pillar electrodes 17, 16 respectively connect between the conductive layer 14D₃ and the conductive layer 14U and between a source electrode of the semiconductor device Q6 and the conductive layer 6U.

In FIG. 6, the second insulating substrate 20 side is defined as a U side, and the first insulating substrate 10 side is defined as a D side, in the embodiments. This definition is also applied to all of the drawings shown hereinafter.

As the first insulating substrate 10 and the second insulating substrate 20, an Active Metal Brazed, Active Metal Bond (AMB) substrate etc. can be applied thereto, for example. The first insulating substrate 10 includes the conductive layer 14D at the upside (U side) of the insulating substrate 8D, and the conductive layer 6D at the downside (D side) thereof (FIG. 7B). The second insulating substrate 20 includes the conductive layer 14U at the U side of the insulating substrate 8U, and the conductive layer 6U at the D side thereof (FIG. 7A). Hereinafter, the upside and downside of the first insulating substrate 10 and the upside and downside of the second insulating substrate 20 are described in the same manner. In following embodiments, representation of the conductive layer 14D, the conductive layer 6D, the conductive layer 14U, and the conductive layer 6U is fixed.

The conductive layer 14U at the U side of the second insulating substrate 20 corresponds to the bus bar BP, for example. The conductive layer 14U which is a positive electrode pattern is connected via the pillar electrode 17 to the conductive layer 14D₃ formed at the U side of the first insulating substrate 10 on which the semiconductor device Q3 is disposed.

Fundamentally, the semiconductor device Q3 is disposed so that the U side is a side of the source electrode and the D side is a side of a drain electrode. The similar disposition is applied to other semiconductor devices Q1, Q2, Q4, Q5, Q6. In addition, each semiconductor device may be disposed in flip chip configuration on the first insulating substrate 10. In such a case, a connecting configuration with the power terminal and the bus bars BP, BN also become reversed.

The pillar electrode 17 connects between the bus bar BP shown in FIG. 5 and the drain electrode (14D₃) of the semiconductor device Q3. The pillar electrode 16 connects between the bus bar BN shown in FIG. 5 and the source electrode of the semiconductor device Q6. The conductive layer 14D₃ corresponds to the drain electrode pattern 3₃ shown in FIG. 4.

A via hole (VIA) is used for the pillar electrode 17 to pass through the insulating substrate 8U of the second insulating substrate 20. An illustrative example of the via hole will be mentioned below.

A source electrode pad of the semiconductor device Q3 (surface at the U side of Q3) is connected through a bonding wire, a lead member 5, etc., to the conductive layer 14D₂ which is disposed so as to be separated from the conductive layer 14D₃ on which the semiconductor device Q3 is disposed. The configuration of such a portion corresponds to the connection between the source electrode S3 of the semiconductor device Q3 and the drain electrode (D6) of the semiconductor device Q6 (W-phase output), shown in FIG. 5. The conductive layer 14D₂ corresponds to the output electrode pattern 2₃ shown in FIG. 4.

A source electrode pad of the semiconductor device Q6 (surface at the U side of Q6) is connected to the conductive layer 6U at the D side of the second insulating substrate 20 via the pillar electrode 16. The conductive layer 6U corresponds to the bus bar BN, for example. The configuration of such a portion corresponds to the connection between the source electrode S6 of the semiconductor device Q6 and the bus bars BN, shown in FIG. 5.

In the same manner as the W phase explained above, since the V phase composed by including the semiconductor devices Q2 and Q5 and the U phase composed by including the semiconductor devices Q1 and Q4 are formed on the first insulating substrate 10, both of the bus bars BP and BN can be composed of the second insulating substrates 20. More specifically, the respective drain electrodes D1, D2, D3 of the respective semiconductor devices Q1, Q2, Q3 (upper arm) are commonly connected with the conductive layer 14U at the U side of the second insulating substrate 20. Moreover, the respective source electrodes S4, S5, S6 of the respective semiconductor devices Q4, Q5, Q6 (lower arm) are commonly connected with the conductive layer 6U at the D side of the second insulating substrate 20.

Thus, the conductive layers 14U, 6U of the second insulating substrate 20 respectively correspond to the positive electrode pattern and negative electrode pattern for supplying a power to the semiconductor devices Q1 to Q6. Consequently, according to the power module 90, the bus bars BP, BN are disposed on the second insulating substrate 20, the first insulating substrate 10 includes the output terminal O, and the second insulating substrate 20 includes the power terminals. Accordingly, a plane shape of the power module can be miniaturized.

Since the second insulating substrate 20 includes a positive electrode pattern and a negative electrode pattern respectively formed on the front side surface and the back side surface of the substrate, an electric current flows in a reverse direction and thereby a magnetic flux which occurs due to the electric current can be canceled. Consequently, an inductance component can be reduced. Moreover the inductance component can further be reduced by forming an area of the positive electrode pattern and an area of the negative electrode pattern so as to be substantially identical to each other. The term “substantially identical” means that the similar operation/working-effect can be obtained, even if both are not exactly identical to each other. Moreover, the shape of the positive electrode pattern may be different from the shape of the negative electrode pattern.

Moreover, since the power module is composed so that the first insulating substrate 10 and the second insulating substrate 20 are opposite to each other, a warpage due to the first insulating substrate 10 and the second insulating substrate 20 can be mutually canceled more than that of the power module composed of one insulating substrate 8 (in the comparative examples 1 and 2), and thereby the warpage can be reduced. In addition, such a warpage can more effectively be reduced by forming the first insulating substrate 10 and a second insulating substrate 20 by means of the same material(s). Moreover, such a warpage can further be reduced by forming thicknesses of the respective substrates to be substantially identical.

A possibility of delamination of the mold resin 15, an occurrence of cracks, an occurrence of an insulation failure, etc. can be reduced by reducing such a warpage, and thereby reliability of the power module can be improved.

Moreover, it is not always necessary to include the via hole (VIA) used for being connected to the conductive layer 14U at the U side of the second insulating substrate 20. If a conductor pattern conducted to the conductive layer 14U is selectively formed (pattern-formed) to the conductive layer 6U at the D side thereof, the conductive layer 14D of the first insulating substrate 10 can be conducted to the conductive layer 14U of the second insulating substrate 20. That is, such a via hole is not a necessary component.

Moreover, the first insulating substrate 10 and the second insulating substrate 20 may be ceramics, e.g. silicon nitride, aluminium nitride, and alumina, or an insulating sheet containing a resin. Moreover, a thickness of the ceramics, e.g. silicon nitride, aluminium nitride, or alumina, is approximately 200 μm to approximately 400 μm, for example, and a thickness of the insulating sheet is approximately 50 μm to approximately 300 μm, for example.

In the above-mentioned example, although it is explained that the conductive layer 14U at the U side of the second insulating substrate 20 corresponds to the positive electrode pattern and the conductive layer 6U at the D side thereof corresponds to the negative electrode pattern, the correspondence between the positive electrode pattern and the negative electrode pattern may become reversed. A reverse configuration will be explained in embodiments shown hereinafter.

### First Embodiment

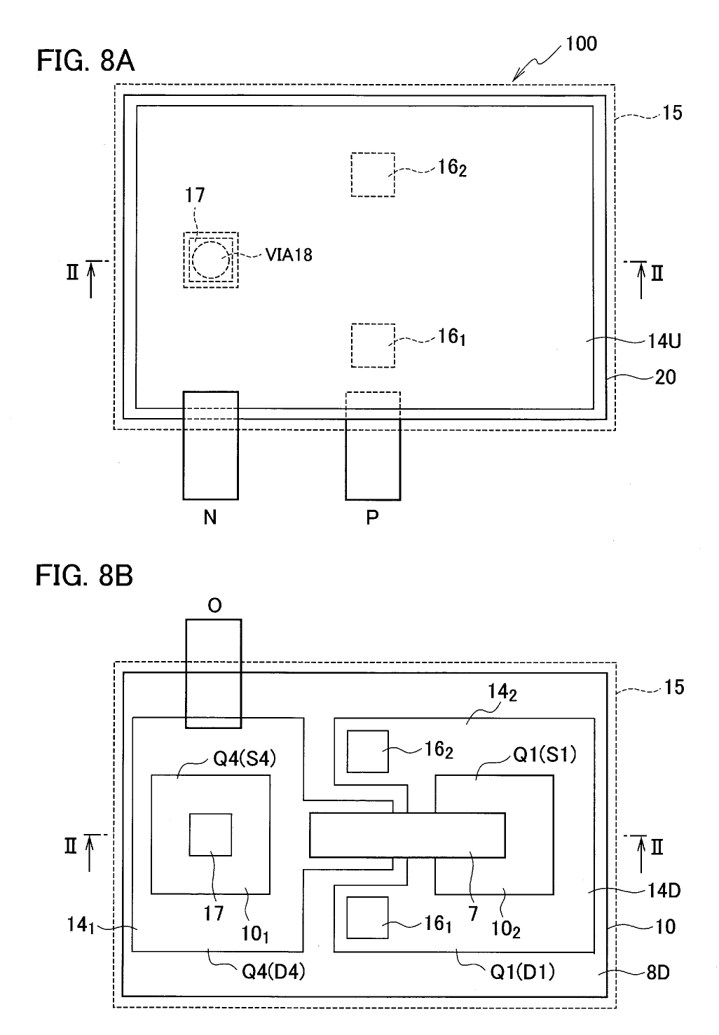

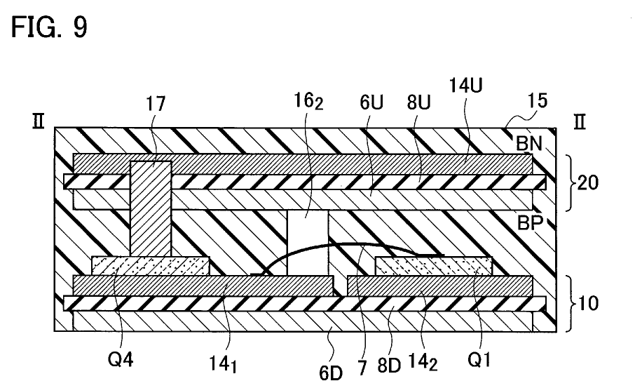

FIG. 8A shows a schematic plain diagram of a power module 100 according to the first embodiment, and FIG. 8B shows a schematic plain diagram of a first insulating substrate 10 which composes the power module 100 after mounting. Moreover, FIG. 9 shows a schematic cross-sectional structure taken in the line II-II of FIG. 8B.

As shown in FIGS. 8 and 9, the power module 100 according to the first embodiment includes: a first insulating substrate 10 including a first conductive layer 14D; a first semiconductor device Q4 disposed on the first conductive layer 14D, the first semiconductor device Q4 of which one side of a main electrode is connected to the first conductive layer 14D; a second insulating substrate 20 disposed on the first insulating substrate 10 so as to be opposite to the first semiconductor device Q4, the second insulating substrate 20 including a second conductive layer 6U formed on a front side surface thereof and a third conductive layer 14U formed on a back side surface thereof; a first pillar electrode 16 configured to connect between the first conductive layer 14D and the second conductive layer 6U; and a second pillar electrode 17 configured to connect between another side of the main electrode of the first semiconductor device Q4 and the third conductive layer 14U. The second conductive layer 6U is connected to any one of the positive electrode pattern or the negative electrode pattern for supplying power to the first semiconductor device Q4, and the third conductive layer 14U is connected to another electrode pattern.

The power module 100 realizes a 2-in-1 module having a configuration of laminating the first insulating substrate 10 and the second insulating substrate 20. The power module 100 includes a first insulating substrate 10, a second insulating substrate 20, semiconductor devices Q1, Q4, pillar electrodes 16, 17, a lead member 7, a positive-side power terminal P, a negative-side power terminal N, and an output terminal O.

The second insulating substrate 20 is disposed at the U side, and the first insulating substrate 10 is disposed at the D side. The first insulating substrate 10 and the second insulating substrate 20 are connected to each other with the pillar electrodes 16, 17.

A first drain electrode pattern 14₁ and a second drain electrode pattern 14₂ are formed as the conductive layer 14D at the U side of the first insulating substrate 10. A shape of the first drain electrode pattern 14₁ is a convex-shaped pattern formed so as to be extended in a one direction, for example, and a shape of the second drain electrode pattern 14₂ is concave shape formed so as to surround the convex-shaped pattern of the first drain electrode pattern 14₁, and both are insulated from each other.

The output terminal O is connected to the first drain electrode pattern 14₁. The output terminal O is led from the first drain electrode pattern 14₁ towards the outside of the mold resin 15.

The negative-side power terminal N is connected to the conductive layer 14U at the U side of the second insulating substrate 20, and the positive-side power terminal P is connected to the conductive layer 6U at the D side thereof. Consequently, the conductive layer 14U constitutes a negative electrode pattern, and the conductive layer 6U constitutes a positive electrode pattern. The positive-side power terminal P and the negative-side power terminal N are led in a direction of the opposite side of the output terminal O.

A negative power supply to which the electric power is supplied to the negative electrode pattern is connected to the main electrode on the surface at the U side of the semiconductor device Q4 via the via hole 18 and the pillar electrode 17. The main electrode on the surface at the U side of the semiconductor device Q4 in this example corresponds to a source electrode. The quadrangle 17 shown in FIG. 8A with the dashed line is a portion where an edge part at the U side of the pillar electrode 17 connects to an end surface at the D side of the via hole 18. The square shown with the dashed line of an outer frame of the quadrangle 17 corresponds to an edge portion of the conductive layer 6U, and the pillar electrode 17 to which the negative power supply is supplied and the conductive layer 6U (positive electrode pattern) are insulated from each other.

The first drain electrode pattern 14₁ on which the semiconductor device Q4 is disposed is connected via the lead member 7 to a source electrode at the U side of the semiconductor device Q1 disposed on the second drain electrode pattern 14₂. The drain electrode at the D side of the semiconductor device Q1 is connected to the conductive layer 6U at the D side of the second insulating substrate 20 via the pillar electrodes 16₁, 16₂.

Although FIG. 8B shows an example of supplying the positive power supply to the semiconductor device Q4 through the two pillar electrodes 16₁, 16₂, the number of the pillar electrodes 16 may be one or two or more. The similar configuration may be applied to the pillar electrode 17.

FIG. 9 shows the pillar electrode 16₂ which is fundamentally not appeared in the cross section along the line II-II, in order to easily understand. Moreover, the cross-sectional structure of the portion of the via hole 18 is simply written therein.

The power module 100 has a structure of supplying the power from the second insulating substrate 20 to the first insulating substrate 10 on which the semiconductor devices Q1, Q4 are disposed. Consequently, since the output terminal O can be led in the different height from the set of the positive-side power terminal P and negative-side power terminal N, the plane shape of the power module can be miniaturized.

### Second Embodiment

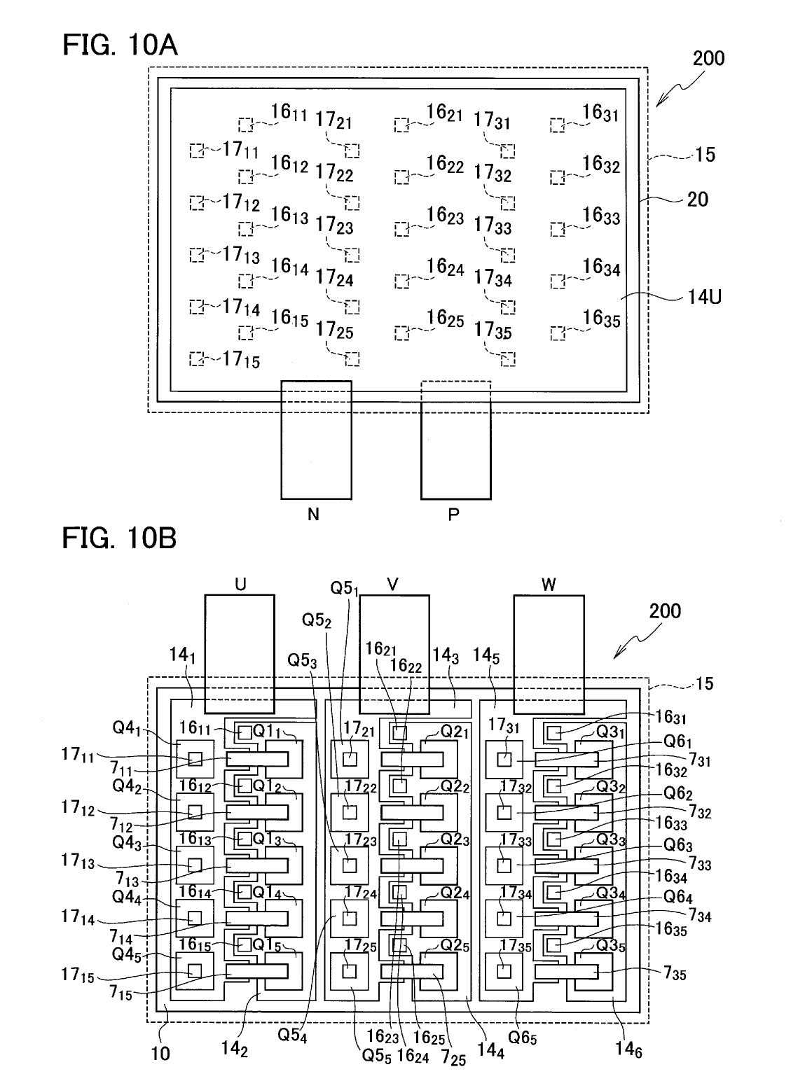

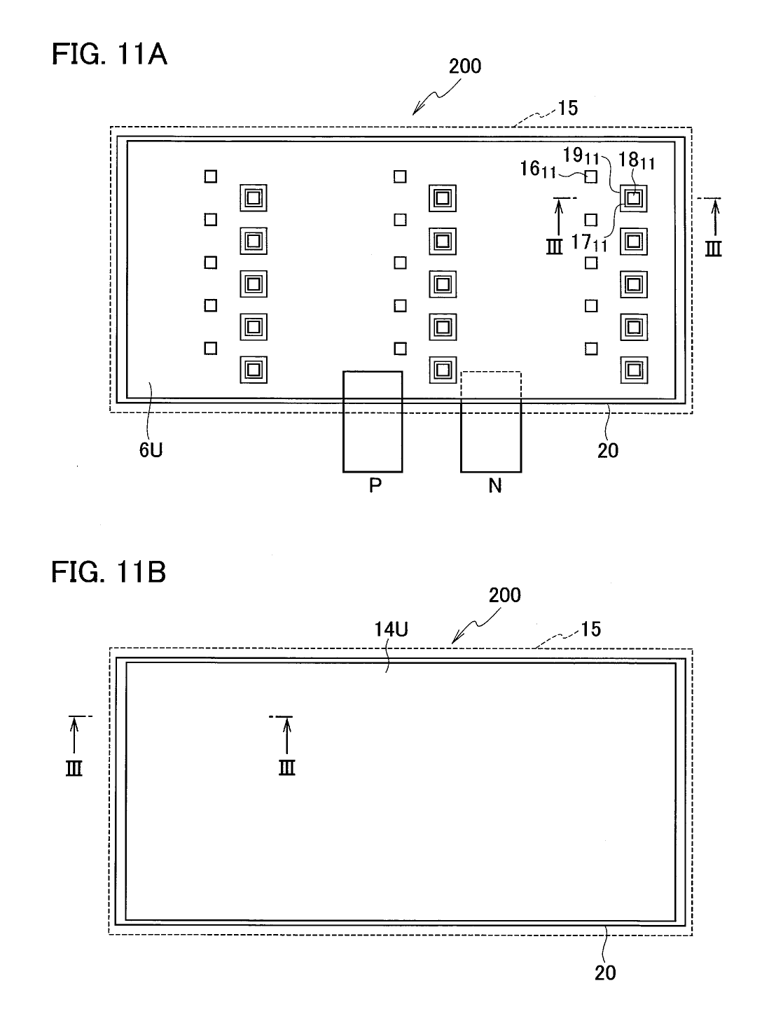

FIG. 10A shows a schematic plain diagram of a first insulating substrate 20 which constitutes a power module according to the second embodiment 200, and FIG. 10B shows a schematic plain diagram of a first insulating substrate 10 which composes the power module 200 after mounting. Moreover, FIG. 11A shows a surface at the D side of the second insulating substrate 20 of the power module 200, and FIG. 11B shows a surface at the U side thereof.

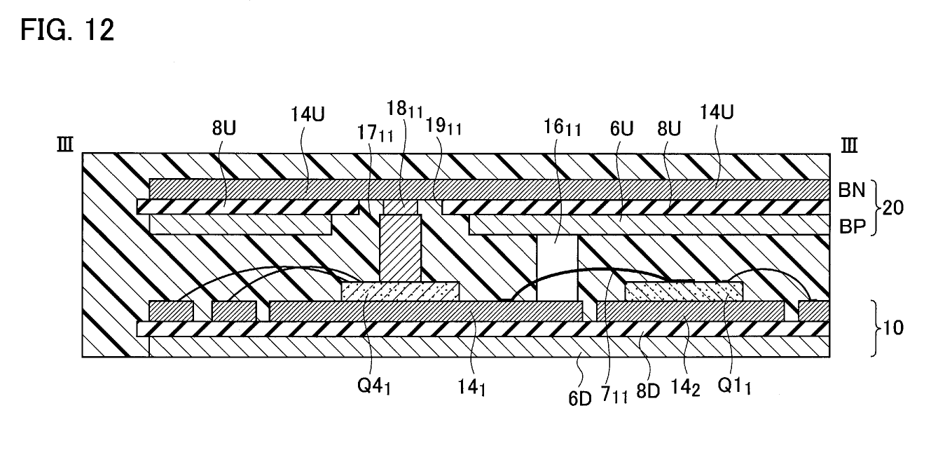

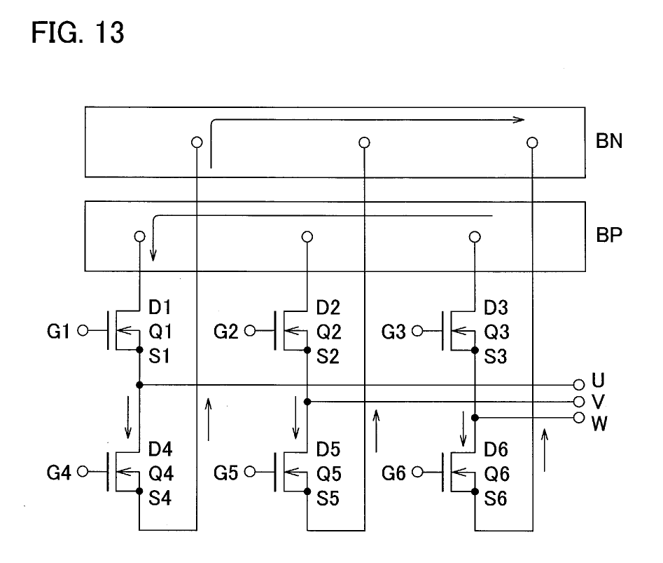

Moreover, FIG. 12 shows a schematic cross-sectional structure taken in the line of FIG. 11B. In FIG. 11B, a representation of the positive-side power terminal P and the negative-side power terminal N is omitted. Moreover, FIG. 13 shows a schematic circuit configuration of the power module 200 in which a current path is added by means of the arrows.

As shown in FIG. 10B, a first conductive layer 14D of a first insulating substrate 10 includes first common electrode patterns 14₁, 14₃, 14₅ connected to the same type of main electrodes of a plurality of first semiconductor devices Q4, Q5, Q6. Moreover, the first conductive layer 14D includes second common electrode patterns 14₂, 14₃, 14₆ different from the first common electrode patterns 14₁, 14₃, 14₅, and second semiconductor devices Q1, Q2, Q3 respectively disposed on the second common electrode patterns 14₂, 14₃, 14₆.

The power module 200 is a module which constitutes a 6-in-1 module by arranging three pieces of the power modules 100.

The power module 200 includes a first insulating substrate 10, a second insulating substrate 20, semiconductor devices Q4, Q1, Q5, Q2, Q6, Q3, pillar electrodes 16, 17, a lead member 7, a positive-side power terminal P, a negative-side power terminal N, and output terminals U, V, W.

In the same manner as the power module 100, the second insulating substrate 20 is disposed at the U side, and the first insulating substrate 10 is disposed at the D side. Similarly, the first insulating substrate 10 and the second insulating substrate 20 are connected to each other with the pillar electrodes 16, 17.

Three power modules 100 arranged in the power module 200 respectively constitute U phase, V phase, and W phase, and respectively include the output terminal U, the output terminal V, and the output terminal W. 5-chip semiconductor devices Q1 to Q6 respectively are disposed in parallel to one another, for example.

A plane shape of the first insulating substrate 10 is a rectangle, for example. In the case of the rectangle, the number (five pieces) of the semiconductor devices arranged in a long side direction of the first insulating substrate 10 is larger than the number (six pieces) of the semiconductor devices arranged in a short side direction of the first insulating substrate 10.

In the conductive layer 14D at the U side of the first insulating substrate 10, a first drain electrode pattern 14₁, a second drain electrode pattern 14₂, a third drain electrode pattern 14₃, a fourth drain electrode pattern 14₄, a fifth drain electrode pattern 14₅, and a sixth drain electrode pattern 14₆ are disposed so as to be separated from one another. A pattern shape of a portion where the first drain electrode pattern 14₁ and the second drain electrode pattern 14₂ are adjacent to each other is a comb-tooth shape, for example, and the comb teeth are engaged with each other. A pattern shape of a portion where the third drain electrode pattern 14₃ and the fourth drain electrode pattern 14₄ are adjacent to each other and a portion where the fifth drain electrode pattern 14₅ and a pattern shape of the sixth drain electrode pattern 14₆ are adjacent to each other are also the comb-tooth shape, for example.

Five semiconductor devices are disposed in a direction which is orthogonal in a direction where the first drain electrode pattern 14₁ to the sixth drain electrode pattern 14₆ are disposed. Semiconductor devices Q4₁, Q4₂, Q4₃, Q4₄, Q4₅ are disposed on the first drain electrode pattern 14₁, semiconductor devices Q1₁, Q1₂, Q1₃, Q1₄, Q1₅ are disposed on the second drain electrode pattern 14₂, and semiconductor devices Q5₁, Q5₂, Q5₃, Q5₄, Q5₅ are disposed on the third drain electrode pattern 14₃.

Furthermore, semiconductor devices Q2₁, Q2₂, Q2₃, Q2₄, Q2₅ are disposed on the fourth drain electrode pattern 14₄, semiconductor devices Q6₁, Q6₂, Q6₃, Q6₄, Q6₅ are disposed on the fifth drain electrode pattern 14₅, and semiconductor devices Q3₁, Q3₂, Q3₃, Q34, Q3₅ are disposed on the sixth drain electrode pattern 14₆.

Thus, the conductive layer 14D of the first insulating substrate 10 includes a common electrode pattern (first drain electrode pattern 14₁) connected to the same type of the main electrode of a plurality of the semiconductor devices, e.g., Q4₁, Q4₂, Q4₃, Q4₄, Q4₅. The same type of the main electrode in this example corresponds to the drain electrode. In the case of a flip chip configuration, the same type of the main electrode may correspond to the source electrode.

The output terminal U is connected to the first drain electrode pattern 14₁, the output terminal V is connected to the third drain electrode pattern 14₃, and the output terminal W is connected to the fifth drain electrode pattern 14₅. Each of the output terminals U, V, W is led to an opposite side of the semiconductor devices Q1 to Q6.

In the similar manner to the power module 100, the negative-side power terminal N is connected to the conductive layer 14U at the U side of the second insulating substrate 20, and the positive-side power terminal P is connected to the conductive layer 6U at the D side; and the conductive layer 14U constitutes the negative electrode pattern, and the conductive layer 6U constitutes the positive electrode pattern. The positive-side power terminal P and the negative-side power terminal N are led in a direction of the opposite side of the output terminals U, V, W.

### (U Phase)

A negative power supply to which the electric power is supplied to the negative electrode pattern is connected to the main electrode on the surface at the U side of the semiconductor device Q4 through the via hole 18₁₁ and the pillar electrode 17₁₁. The main electrode on the surface at the U side of the semiconductor device Q4 in this example corresponds to a source electrode.

In FIG. 10A, a representation of the via hole 18 is omitted, and a portion where an edge part at the U side of the pillar electrode 17 is connected to the conductive layer 6U at the D side of the second insulating substrate 20 is written by means of the quadrangle 17 with the dashed line.

The via hole 18 omitted in FIG. 10A is written by means of the quadrangle 18 in FIG. 11A. For example, the pillar electrode 17₁₁ is connected to the conductive layer 14U at the U side of the second insulating substrate 20 via the via hole 18₁₁.

In FIG. 11A, a framework 19₁₁ of the outside of the quadrangle 17₁₁ where the edge part at the U side of the pillar electrode 17₁₁ is connected to the conductive layer 6U at the D side of the second insulating substrate 20 indicates an area without the conductive layer 6U. The pillar electrode 17₁₁ and the conductive layer 6U are insulated from each other by means of the framework 19₁₁ (FIG. 12).

In FIG. 12, patterns of both outsides of the semiconductor devices Q4₁, Q1₁ are the source signal electrode pattern or gate signal pattern. Further details will be described later.

The drain electrode which is the main electrode at the D side of the semiconductor device Q1₁ is connected via the first drain electrode pattern 14₁ and the lead member 7₁₁ to the source electrode of the semiconductor device Q1₁ disposed on the second drain electrode pattern 14₂. The lead member 7 is configured to connect between one of a plurality of the common electrode patterns (e.g., first drain electrode pattern 14₁) and a main electrode of the semiconductor device (e.g., semiconductor device Q1₁) disposed on a common electrode pattern (e.g., second drain electrode pattern 14₂) different therefrom.

The drain electrode at the D side of the semiconductor device Q1₁ is connected via the second drain electrode pattern 14₂ and the pillar electrode 16₁₁ to the conductive layer 6U at the D side of the second insulating substrate 20.

In FIG. 11A, the quadrangle 16₁₁ indicates a portion where the pillar electrode 16₁₁ is connected to the conductive layer 6U. FIG. 12 shows the pillar electrode 16₁₁ which is fundamentally not appeared in the cross section along the line III-III, in order to easily understand.

Thus, any one of the main electrode of the semiconductor device or the common electrode patterns (e.g., first drain electrode pattern 14₁) are connected via the pillar electrode (e.g., pillar electrode 16₁₁) to the conductive layer 6U on the surface opposite to the semiconductor device of the second insulating substrate 20, and another pattern is connected to conductive layer 14U via the via hole (e.g., 18₁₁) and the pillar electrode (e.g., 17₁₁) on a surface which is different therefrom.

The positive power supply and the negative power supply are supplied to the semiconductor devices Q1₁, Q4₁ from the second insulating substrate 20 by means of the above-explained configuration. The similar configuration is also applied to the semiconductor devices Q1₁ to Q1₅ and the semiconductor devices Q4₁ to Q4₅ respectively connected in parallel. The similar configuration is also applied to the other V and W phases. Therefore, the other V and W phases will be briefly explained.

### (V Phase)

The negative power supply is supplied to the source electrode of the semiconductor device Q5₁ (surface at the U side of Q5₁), which constitutes a lower arm of the V phase, via the via hole 18₂₁ and the pillar electrode 17₂₁ from the conductive layer 14U at the second insulating substrate 20.

The drain electrode of the semiconductor device Q5₁ (surface at the D side of the semiconductor device Q5₁) is connected to the source electrode of the semiconductor device Q2₁ via the third drain electrode pattern 14₃ and the lead member 7₂₁.

The drain electrode of the semiconductor device Q2₁ (surface at the D side of the semiconductor device Q2₁) is connected to the conductive layer 6U (positive electrode pattern) at the D side of the second insulating substrate 20 via the fourth drain electrode pattern 14₄ and the pillar electrode 16₂₁. A portion where the pillar electrode 16₂₁ is connected to the conductive layer 6U is shown by the quadrangle 16₂₁ in FIG. 10A.

The above-mentioned configuration of the V phase is similarly also applied to the semiconductor devices Q2₁ to Q2₅ and the semiconductor devices Q5₁ to Q5₅ respectively connected in parallel.

### (W Phase)

The negative power supply is supplied to the source electrode of the semiconductor device Q6₁ (surface at the U side of Q6₁), which constitutes a lower arm of the W phase, via the via hole 18₃₁ and the pillar electrode 17₃₁ from the conductive layer 14U at the second insulating substrate 20.

The drain electrode of the semiconductor device Q6₁ (surface at the D side of the semiconductor device Q6₁) is connected to the source electrode of the semiconductor device Q3₁ via the fifth drain electrode pattern 14₅ and the lead member 7₃₁.

The drain electrode of the semiconductor device Q3₁ (surface at the D side of the semiconductor device Q3₁) is connected to the conductive layer 6U (positive electrode pattern) at the D side of the second insulating substrate 20 via the sixth drain electrode pattern 14₆ and the pillar electrode 16₃₁. A portion where the pillar electrode 16₃₁ is connected to the conductive layer 6U is shown by the quadrangle 13₃₁ in FIG. 10A.

The above-mentioned configuration of the W phase is similarly also applied to the semiconductor devices Q3₁ to Q3₅ and the semiconductor devices Q6₁ to Q6₅ respectively connected in parallel.

The power module 200 has a structure for supplying the power to each layer of the U layer, the V layer, and the W layer from the second insulating substrate 20. More specifically, the bus bars BP, BN explained in the comparative example 2 are composed of the second insulating substrates 20. Accordingly, the bus bars BP, BN disposed in the planar direction are needless, and thereby the plane shape of the 6-in-1 module can significantly be reduced as compared with conventional modules.

Moreover, the directions of the electric current which flows into the source electrode pattern of each of the U, V, and W phases are reversed between the conductive layer 14U and the conductive layer 6U (refer to FIG. 13), a magnetic flux which occurs due to the electric current is canceled, and thereby an inductance can be reduced. Moreover, the effect of reducing the warpage can be obtained similarly to the above-mentioned basic configuration.

### Modified Example

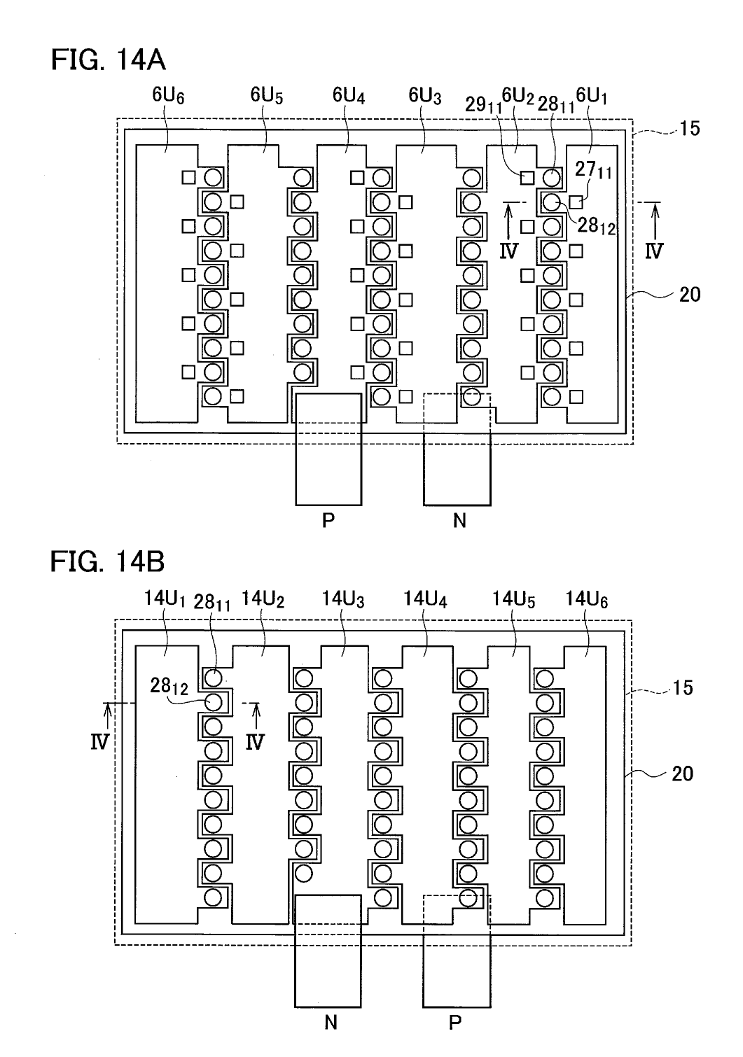

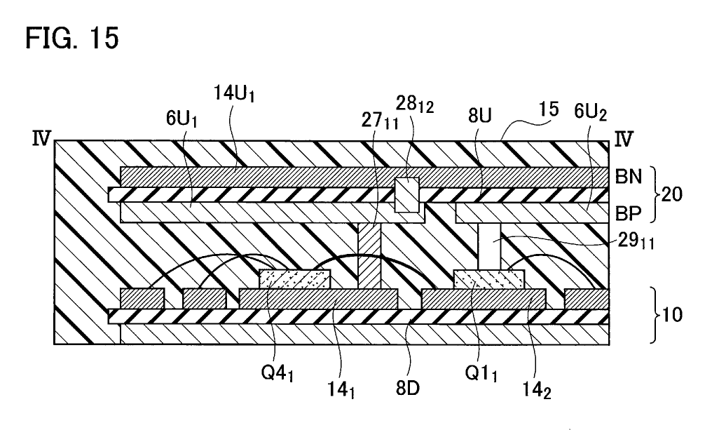

FIG. 14A shows a surface at the D side of the second insulating substrate 20 of the power module 210 which is a modified example of the power module 200, and FIG. 14B shows a surface at the U side thereof. Moreover, FIG. 15 shows a schematic cross-sectional structure taken in the line IV-IV of FIG. 14A.

The power module 210 is different from the power module 200 in that a second insulating substrate 20 of which the configuration of the electrode pattern of conductive layers 14U and 6U of the second insulating substrate 20 is deformed is provided. This modified example illustrates that the conductive layers 14U, 6U of the second insulating substrate 20 respectively do not need to be one (individual) positive electrode pattern and one (individual) negative electrode pattern. Therefore, illustration of a plane shape of the first insulating substrate 10 used in combination with the second insulating substrate 20 is omitted.

The conductive layer 6U at the D side of the second insulating substrate 20 includes: a plurality of conductor patterns 6U₁ to 6U₆ disposed so as to be long in one direction and to be adjacent to one another in a direction orthogonal to an extending direction, for example; and via holes 28. The respective conductor patterns 6U₁ to 6U₆ are disposed at an interval, and are insulated with one another. A shape of the conductor patterns adjacent to one another is a comb-tooth shape, and the comb teeth are engaged with each other. Moreover, the via holes 28 are disposed in the comb teeth portions so as to form a row.

The conductive layer 14U at the U side of the second insulating substrate 20 includes a plurality of conductor patterns 14U₁ to 14U₆ respectively connected to the conductor patterns 6U₁ to 6U₆ at the D side via the via holes 28. A shape of the conductor patterns 14U₁ to 14U₆ of a portion being adjacent to one another is the same comb-tooth shape as that of the D side.

The conductor pattern 14U₁ is connected to the conductor pattern 6U₁ at the D side via the via hole 28₁₂. The conductor pattern 6U₁ is connected via the pillar electrode 27₁₁ to a first drain electrode pattern 14₁ formed in the conductive layer 14D at the U side of the first insulating substrate 10. The quadrangle 27₁₁ illustrated in the conductor pattern 6U₁ indicates a portion to which an edge part of the pillar electrode 27₁₁ is connected.

The main electrode at the U side of the semiconductor device Q4₁ disposed on the first drain electrode pattern 14₁ is connected via the lead member 26₁₁ to the second drain electrode 14₂ which is adjacent thereto.

The main electrode at the U side of the semiconductor device Q1₁ disposed on the conductor pattern 6U₂ at the D side of the second insulating substrate 20 is connected to the second drain electrode 14₂ via the pillar electrode 29₁₁. In this case, the output terminal U of U phase is led from one side of the second drain electrode 14₂ to the outside thereof.

In the case of this example, the conductor pattern 14U₁ corresponds to the negative electrode, and the conductor pattern 14U₂ corresponds to the positive electrode. Moreover, the conductor pattern 14U₃ and the conductor pattern 14U₅ correspond to the negative electrode, and the conductor pattern 14U₄ and the conductor pattern 14U₆ correspond to the positive electrode.

Similarly regarding the conductor patterns 6U₁ to 6U₆ at the D side, the conductor pattern 6U₁ corresponds to the negative electrode, the conductor pattern 6U₂ corresponds to the positive electrode, the conductor pattern 6U₃ corresponds to the negative electrode, the conductor pattern 6U₄ corresponds to the positive electrode, the conductor pattern 6U₅ corresponds to the negative electrode, and the conductor pattern 6U₆ corresponds to the positive electrode.

Thus, the conductive layers 14U, 6U of the second insulating substrate 20 may include the plurality of the electrode patterns, and the positive electrode pattern and the negative electrode pattern may be disposed alternately respectively on both surfaces of the second insulating substrate 20.

Moreover, the via holes 28 are disposed in series on the second insulating substrate 20, and the pillar electrodes 27 are disposed in parallel to the row of the via holes 28. Regarding the row of the via holes 28, the via hole of the positive electrode (e.g., reference sign 28₁₂) and the via hole of the negative electrode (e.g., reference sign 28₁₁) may be disposed alternately.

By alternately disposing the via hole of the positive electrode and the via hole of the negative electrode, a length of the second insulating substrate 20 in an arrangement direction of the conductor patterns 6U, 14U can be shortened. Moreover, a longitudinal distance of the second insulating substrate 20 illustrated by the rectangular shape in FIG. 14 can be shortened.

### Third Embodiment

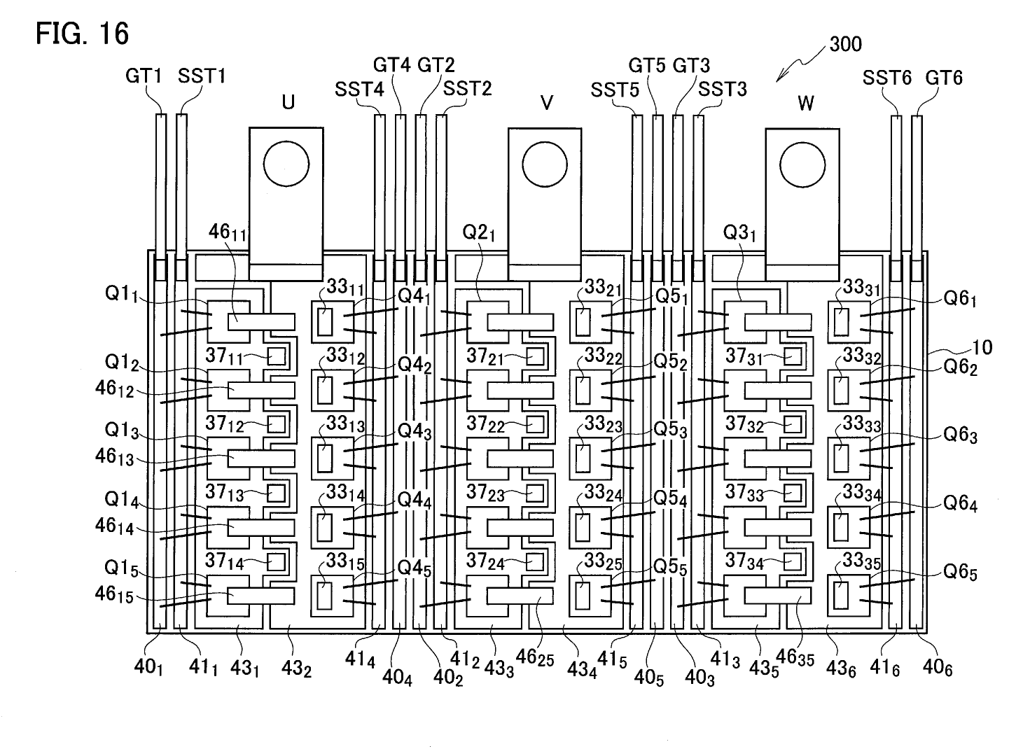

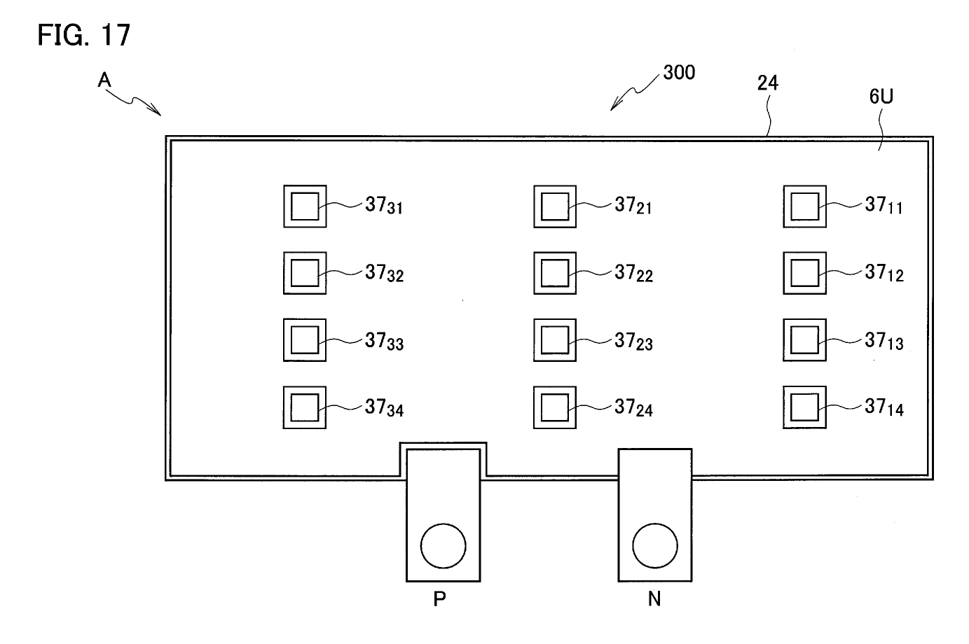

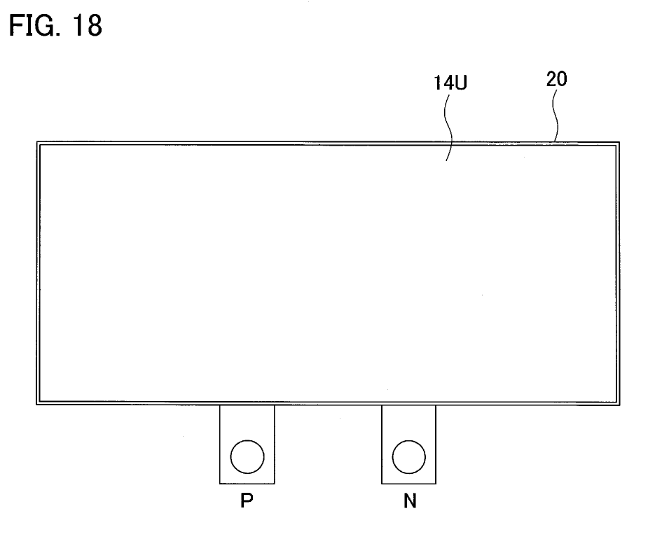

FIG. 16 shows a schematic plain diagram of a first insulating substrate 10 which composes the power module 300 according to a third embodiment after mounting. Moreover, FIG. 17 shows a surface at the D side of the second insulating substrate 20 of the power module 300. Moreover, FIG. 18 shows a surface at the U side of the second insulating substrate 20 of the power module 300.

The power module 300 is a 6-in-1 module similar to the power module 200. The power module 300 is different from those of the first and second embodiments in points that the positive-side power terminal P is connected to the surface at the U side of the second insulating substrate 20 and the negative-side power terminal N is connected to the surface at the D side thereof.

FIG. 16 shows: a gate signal electrode pattern 40 and a source sense signal electrode 41 which are not shown in the above-mentioned embodiments; and gate terminals GT1 to GT6 and source sense terminals SST1 to SST6 which are respectively connected to the signal electrodes. The power module 300 is different from the power module 200 in points that: the aforementioned elements are shown therein; and the surface at the U side of the second insulating substrate 20 corresponds to the positive electrode pattern and the surface at the D side thereof corresponds to the negative electrode pattern.

The other configurations are similar to that of the power module 200. In the similar manner to the power module 200, the semiconductor devices Q1, Q4 composes the U phase, the semiconductor devices Q2, Q5 composes the V phase, the semiconductor devices Q3, Q6 composes the W phase, and 5-chip semiconductor devices Q1 to Q6 respectively are disposed in parallel to one another.

However, since the positive power supply is supplied to the conductive layer 14D of the first insulating substrate 10 via the pillar electrode 37₁₁ from the conductive layer 14U at the U side of the second insulating substrate 20, an arrangement sequence of the semiconductor devices Q1-Q6 is different from the power module 200. In the power module 200, the semiconductor devices are arranged in order of Q4, Q1, Q5, Q2, Q6, and Q3. On the other hand, in the power module 300, the semiconductor devices are arranged in order of Q1, Q4, Q2, Q5, Q3, and Q6.

The conductive layer 14D at the U side of the first insulating substrate 10 includes agate signal electrode pattern 40₁, a source sense signal electrode pattern 41₁, a first drain electrode pattern 43₁, a second drain electrode pattern 43₂, a source sense signal electrode pattern 41₄, and a gate signal electrode pattern 40₄, for the U phase.

The conductive layer 14D at the U side of the first insulating substrate 10 includes agate signal electrode pattern 40₂, a source sense signal electrode pattern 41₂, a third drain electrode pattern 43₃, a fourth drain electrode pattern 43₄, a source sense signal electrode pattern 41₅, and a gate signal electrode pattern 40₅, for the V phase.

The conductive layer 14D at the U side of the first insulating substrate 10 includes agate signal electrode pattern 40₃, a source sense signal electrode pattern 41₃, a fifth drain electrode pattern 43₅, a sixth drain electrode pattern 43₆, a source sense signal electrode pattern 41₆, and a gate signal electrode pattern 40₆, for the W phase.

The gate signal electrode pattern 40₁ and a gate signal electrode pad (not shown) of the surface at the U side of the semiconductor device Q1 are connected to each other by means of a bonding wire. Moreover, the source sense signal electrode pattern 41₁ and a source signal electrode pad (not shown) of the surface at the U side of the semiconductor device Q1 are connected to each other by means of a bonding wire. The bonding wires are shown by thick solid lines and reference signs thereof are omitted.

A gate terminal GT1 and a source sense terminal SST1 for external extraction are respectively connected to the gate signal electrode pattern 40₁ and the source sense signal electrode pattern 41₁ by means of soldering etc. The similar configuration is also applied to the other V and W phases.

A current path in the power module 300 is the following order: the positive-side power terminal P;

the positive electrode pattern at the U side of the second insulating substrate 20 (6U); the pillar electrode 37₁₁ configured to connect the first drain electrode pattern 43₁ on which the semiconductor device Q1₁ is disposed, and the positive electrode pattern to each other; the flat plate-shaped lead member 46₁₁ configured to connect the source electrode of the semiconductor device Q1₁ and the second drain electrode pattern 43₂ on which the semiconductor device Q4₁ is disposed to each other; the pillar electrode 33₁₁ configured to connect the conductive layer 6U at the D side of the first insulating substrate 24 and the main electrode at the U side of the semiconductor device Q4₁ to each other; the negative electrode pattern (14U); and the negative-side power terminal N.

An edge part at the U side of the pillar electrode 37₁₁ is connected to a portion of the surface at the D side of the second insulating substrate 20 shown by the quadrangle 37₁₁. The edge part at the U side of the pillar electrode 33₁₁ may be connected to any one portion of the surfaces at the D side of the second insulating substrate 20. Therefore, representation of the portion thereof is omitted in FIG. 17.

Current paths of the other 4 chips connected in parallel are similar thereto except for the number of subscripts of the semiconductor devices Q1, Q4 and the pillar electrodes 33, 37.

An explanation of the current paths of the V and W phases is omitted by showing the reference signs on FIGS. 16 and 17.

As explained above, the same operation/working-effect as that of the second embodiment is obtained also in the third embodiment in which the conductive layer 14U at the U side of the second insulating substrate 20 corresponds to the positive electrode pattern and the conductive layer 6U at the D side thereof corresponds to the negative electrode pattern.

### (Fabrication Method)

A fabrication method of the power module 300 according to the third embodiment will now be explained.

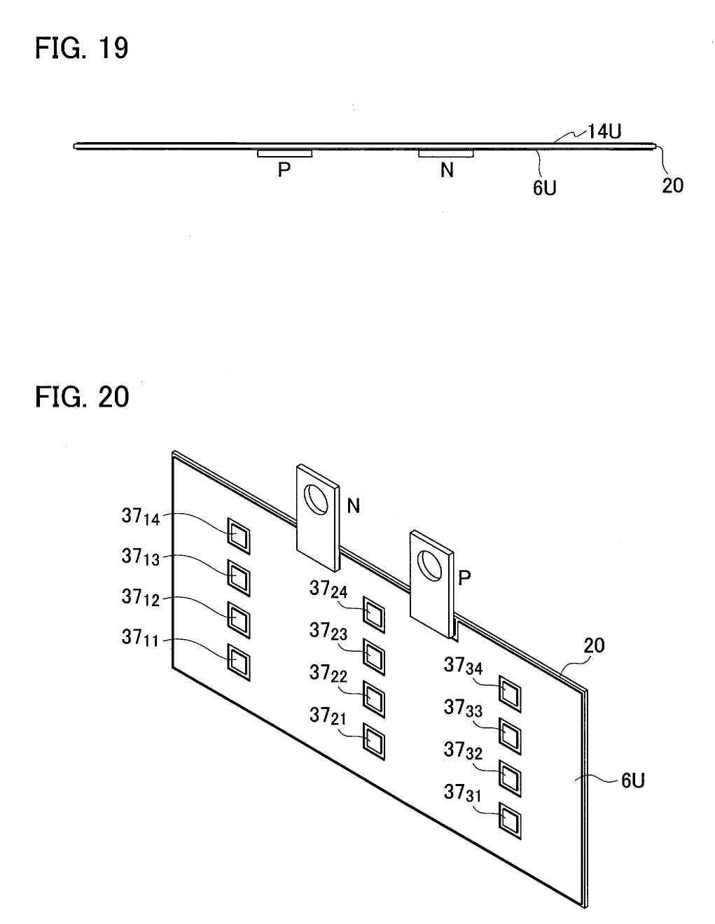

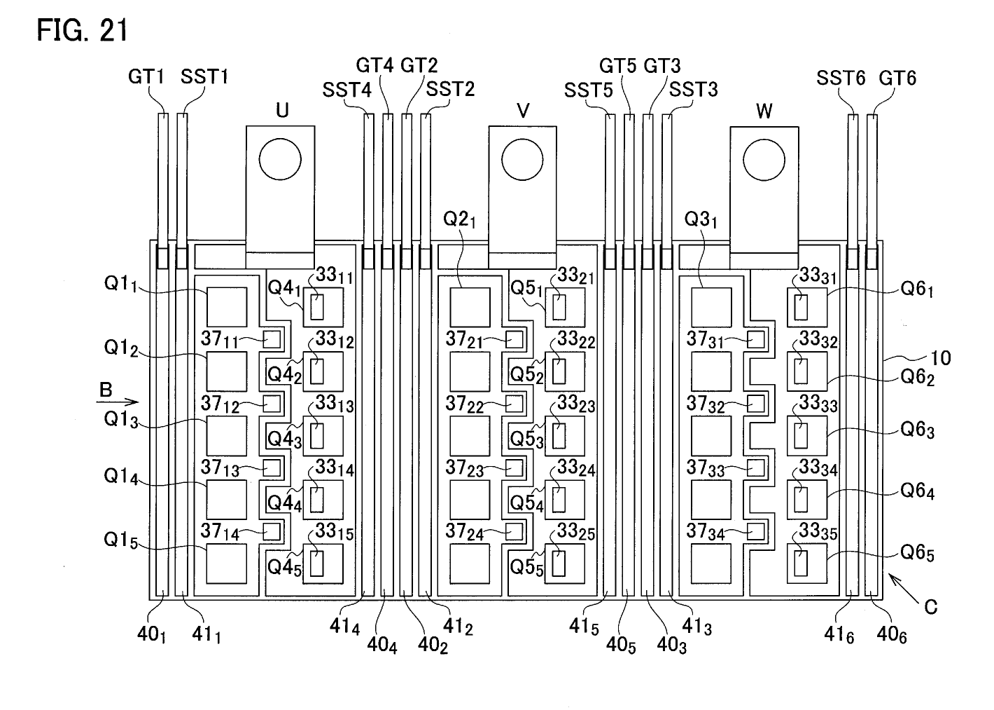

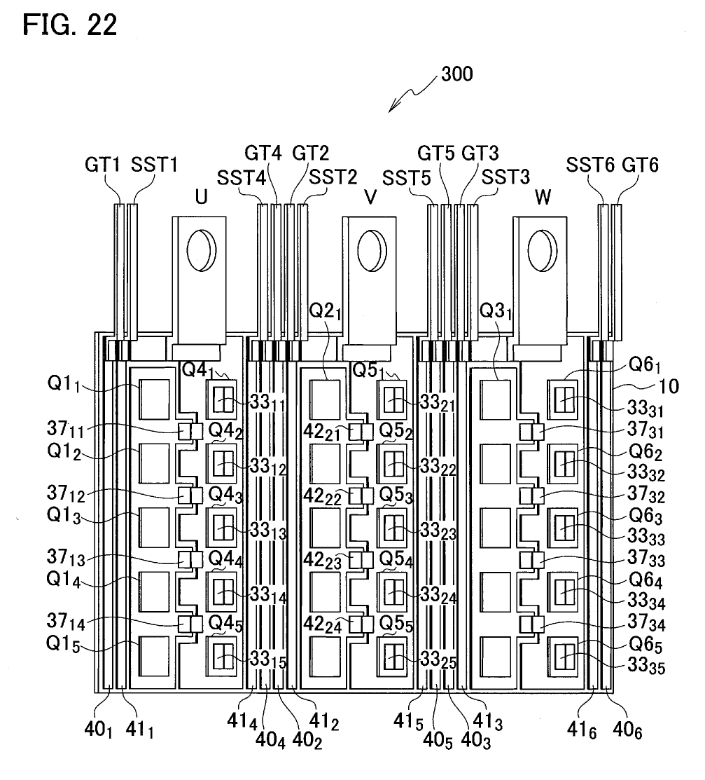

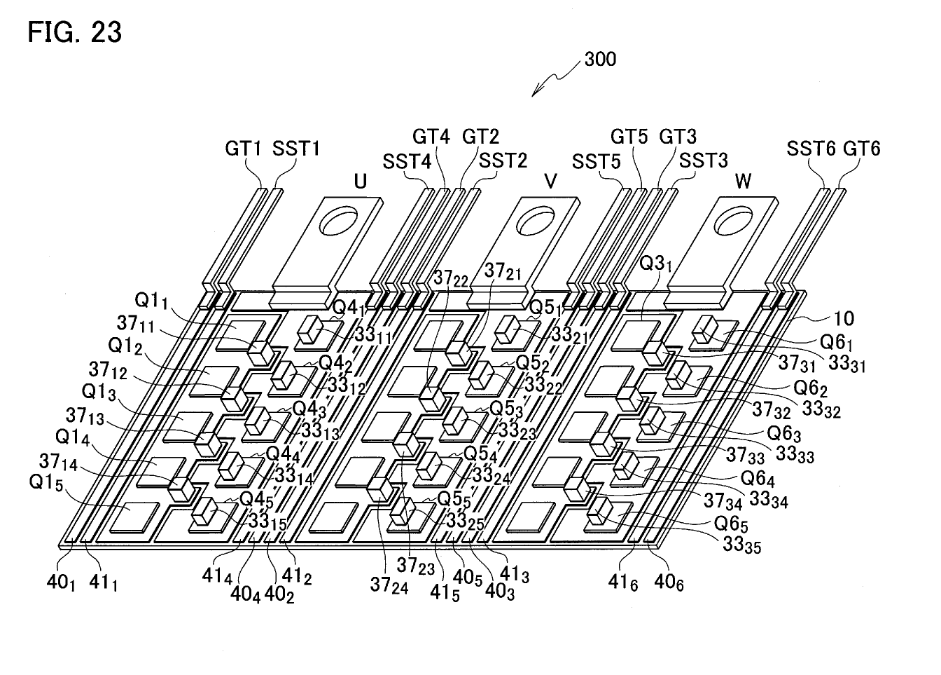

FIG. 19 shows a side view diagram of the second insulating substrate 24 of the power module 300 which is observed from the positive-side power terminal P and the negative-side power terminal N side. Moreover, FIG. 20 shows a schematic bird's-eye view configuration diagram of the same D side of the second insulating substrate 20 observed from the arrow A of FIG. 17. Moreover, FIG. 21 shows a schematic plain diagram of the first insulating substrate 10 of the power module 300 before mounting. FIG. 22 shows a schematic bird's-eye view configuration diagram after mounting the semiconductor devices Q1-Q6 and the pillar electrodes 33, 37 on the aforementioned first insulating substrate 10 observed from the arrow B of FIG. 21. Moreover, FIG. 23 shows a schematic bird's-eye view configuration diagram observed from the arrow C of FIG. 21.

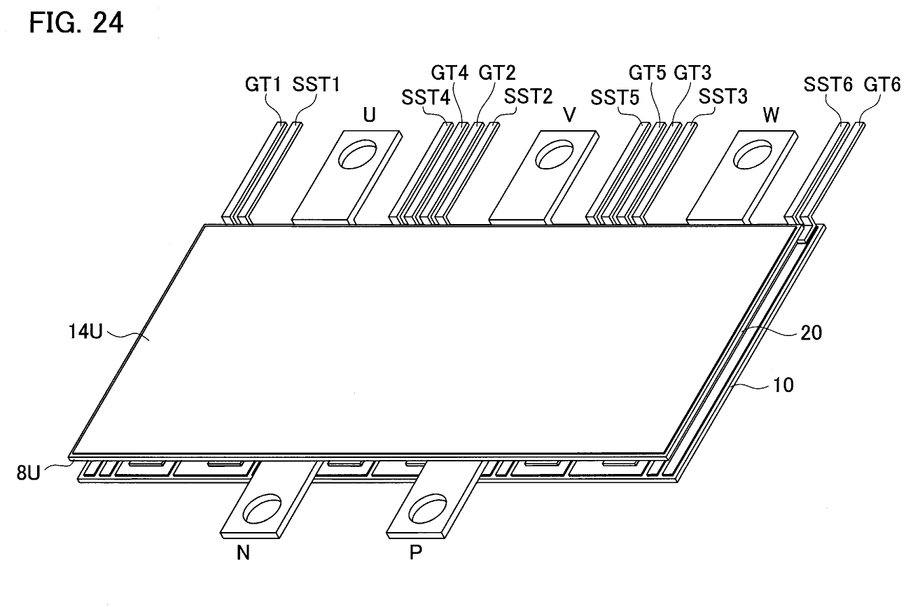

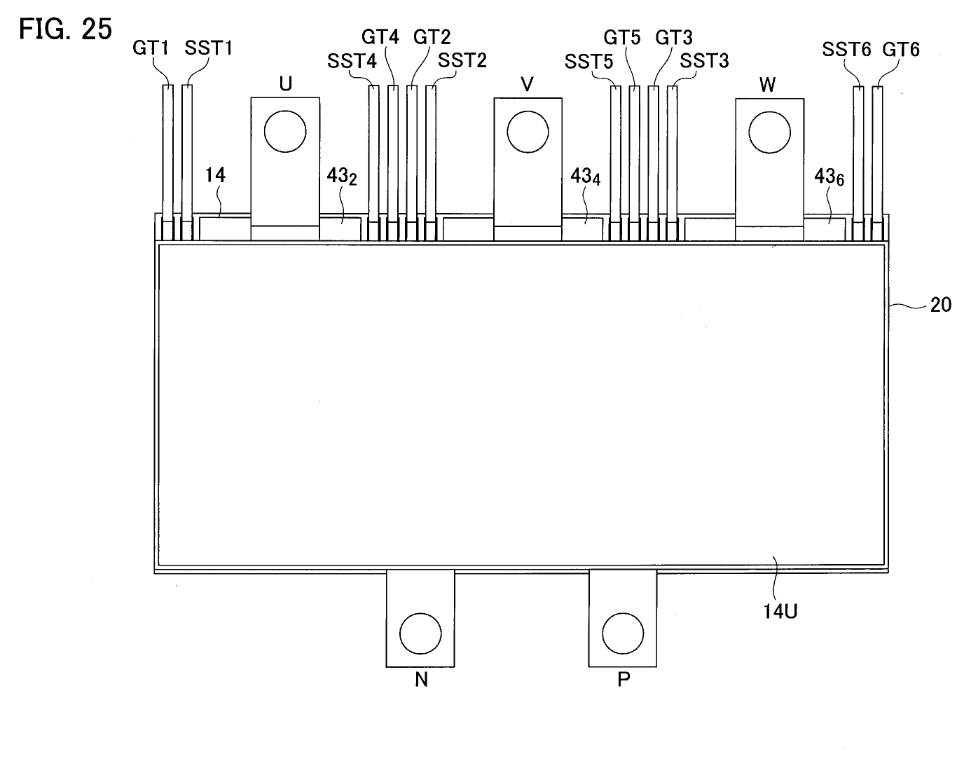

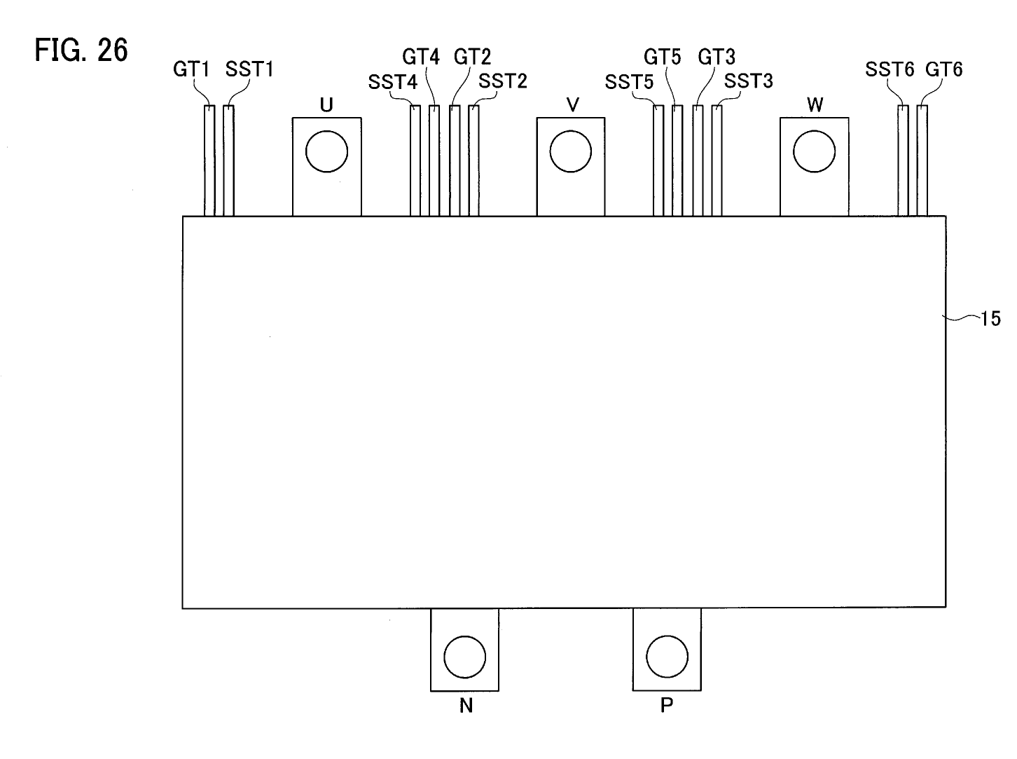

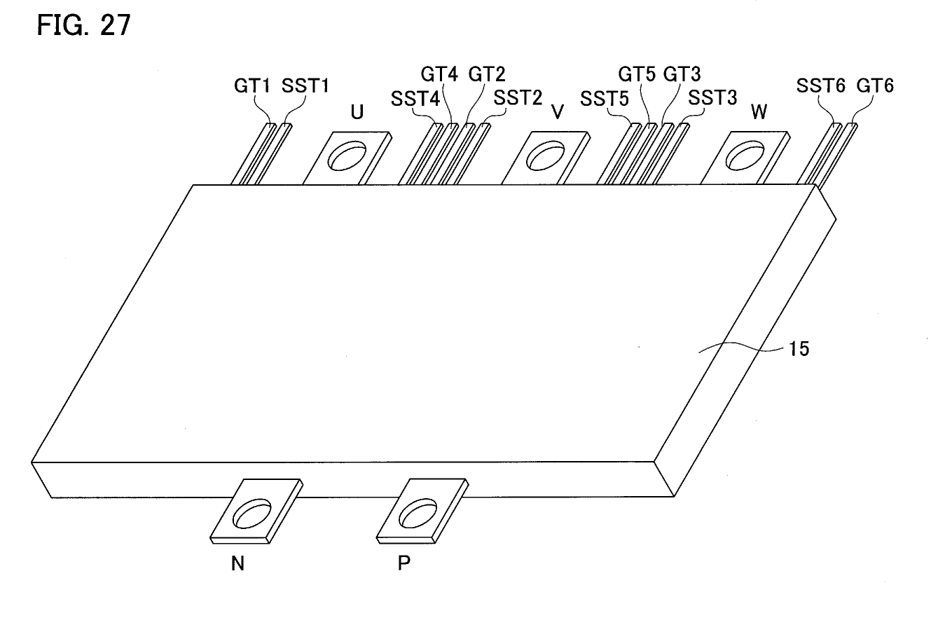

Moreover, FIG. 24 shows a schematic bird's-eye view configuration diagram of an aspect immediately before bonding the first insulating substrate 10 to the second insulating substrate 20 of the power module 300 observed from the arrow C of FIG. 21. Moreover, FIG. 25 shows a schematic plain diagram after bonding the aforementioned first insulating substrate 10 to the second insulating substrate 20. Moreover, FIG. 26 shows a schematic plain diagram of the power module 300 after resin sealing. Moreover, FIG. 27 shows a schematic bird's-eye view configuration diagram of an outer appearance after the resin sealing observed from the arrow C.

(a) Firstly, as shown in FIG. 20, the conductive layer 6U at the D side of the second insulating substrate 20 is patterned so as to be not short-circuited to the via hole. As the second insulating substrate 20 and the first insulating substrate 10, an AMB substrate, a Direct Bonding Copper (DBC) substrate, a Direct Brazed Aluminum (DBA) substrate, etc. can be applied, for example. The positive-side power terminal P and the negative-side power terminal N are connected thereto by means of soldering etc. after the patterning. In FIG. 19, representation of via holes is omitted and portions to which the pillar electrodes 37₁₁ to 37₃₄ are connected are shown by the quadrangles 37₁₁ to 37₃₄.
(b) Next, the conductive layer 14D at the U side of the first insulating substrate 10 is patterned. As consequently of the patterning process, there are formed gate signal electrode patterns 40₁ to 40₆, source sense signal electrode patterns 41₁ to 41₆, a first drain electrode pattern 43₁, a second drain electrode pattern 43₂, a third drain electrode pattern 43₃, a fourth drain electrode pattern 43₄, a fifth drain electrode pattern 43₅, and a sixth drain electrode pattern 43₆. The output terminals U, V, W, gate signal terminals GT1 to GT4, and source sense signal terminals SST1 to SST6 are connected thereto by means of soldering etc., after the patterning.
(c) Next, the semiconductor devices Q1 to Q6 are respectively mounted on the electrode patterns of the first insulating substrate 10. Moreover, the pillar electrodes 37₁, 37₂, 37₃ are respectively formed on the surfaces at the U side of the first drain electrode pattern 43₁, the third drain electrode pattern 43₃, and the fifth drain electrode pattern 43₅, and the pillar electrodes 33₁, 33₂, 33₃ are respectively formed on the main electrodes (in this case, source electrodes) at the U side of the semiconductor devices Q4, Q5, Q6. More specifically, at least one pillar electrode is formed on each of the main electrode of the semiconductor device and the surface of the conductive layer (refer to FIGS. 22 and 23).
(d) Next, each of portions shown by the quadrangles 37₁₁ to 37₃₄ is connected to an edge part at the U side of each of the pillar electrodes 37₁, 37₂, 37₃ and the conductive layer 6U at the D side of the second insulating substrate 20, and simultaneously an edge part at the U side of each of the pillar electrodes 33₁, 33₂, 33₃ and the conductive layer 6U of the second insulating substrate D side are connected to each other. More specifically, any one of the edge parts of the pillar electrodes 33, 37 is connected to the conductive layer of one surface of the second insulating substrate 20 disposed to be opposite to the first insulating substrate 10, and another edge part of the pillar electrodes 33 and 37 is connected to the conductive layer on another surface of the second insulating substrate 20.
(e) Next, the first insulating substrate 10 and the second insulating substrate 20 are sealed with the mold resin 15. Furthermore, a cooling apparatus may be mounted on any one or both of the lower side back side surface of the first insulating substrate 10, on which the semiconductor devices Q1 to Q6 are disposed, and the front side surface of the second insulating substrate 20.

### Examples of Power Module

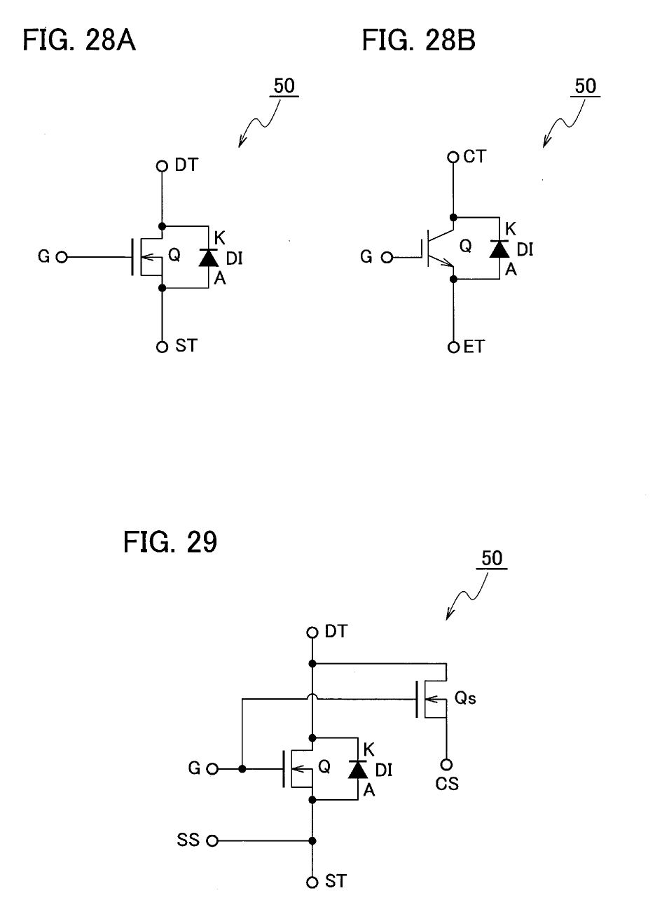

FIG. 28A shows a schematic circuit representative of an SiC MOSFET of the 1-in-1 module, which is the power module 50 according to the first to third embodiments, and FIG. 28B shows a schematic circuit representation of the IGBT of the 1-in-1 module.

A diode DI connected in reversely parallel to the MOSFET Q is shown in FIG. 28A. A main electrode of the MOSFET Q is expressed with a drain terminal DT and a source terminal ST. Similarly, a diode DI connected in reversely parallel to the IGBT Q is shown in FIG. 28B. A main electrode of the IGBT Q is expressed with a collector terminal CT and an emitter terminal ET.

Moreover, FIG. 29 shows a detailed circuit representative of the SiC MOSFET of the 1-in-1 module, which is the power module 50 according to the embodiments.

The power module 50 according to the first to third embodiments includes a configuration of 1-in-1 module, for example. More specifically, one piece of the MOSFET Q is included in one module. As an example, five chips (MOSFET×5) can be mounted thereon, and a maximum of five pieces of the MOSFETs Q respectively can be connected to one another in parallel. Note that it is also possible to mount a part of five pieces of the chips for the diode DI thereon.

More particularly, as shown in FIG. 29, a sense MOSFET Qs is connected to the MOSFETQ in parallel. The sense MOSFET Qs is formed as a minuteness transistor in the same chip as the MOSFET Q. In FIG. 29, reference sign SS denotes a source sense terminal, reference sign CS denotes a current sense terminal, and reference sign G denotes a gate signal terminal. Note that, also in the semiconductor device Q according to the embodiments, the sense MOSFET Qs is formed as a minuteness transistor in the same chip.

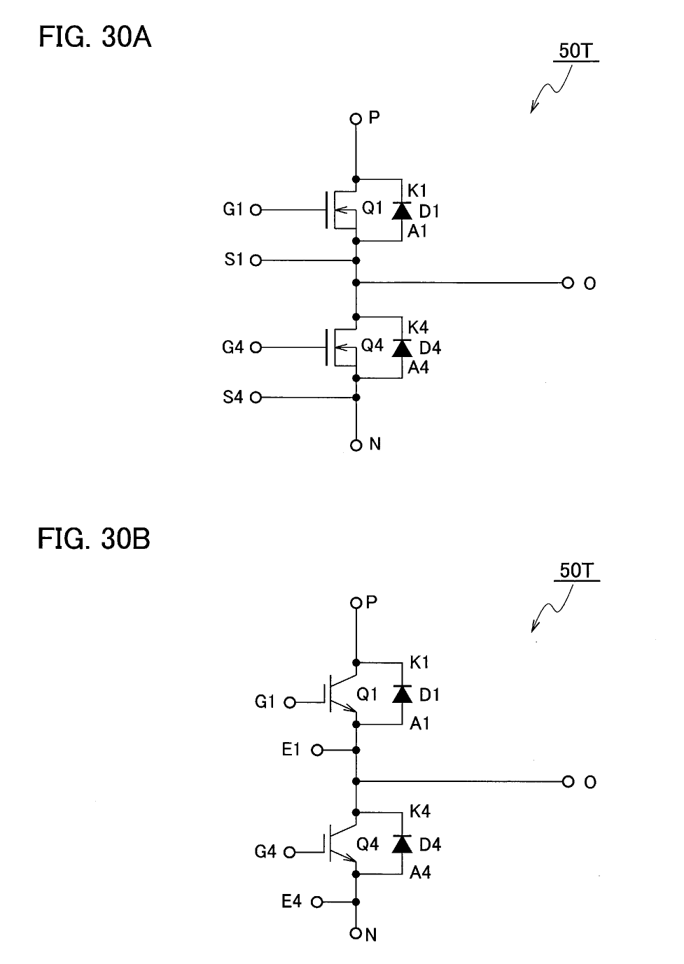

Moreover, FIG. 30A shows a schematic circuit representative of the SiC MOSFET of the 1-in-1 module, which is the power module 50T according to the embodiments.

As shown in FIG. 30A, two MOSFETs Q1, Q4, and diodes D1, D4 connected in reversely parallel to the MOSFETs Q1, Q4 are built in one module. Reference sign G1 denotes a gate signal terminal of the MOSFET Q1, and reference sign S1 denotes a source terminal of the MOSFET Q1. Reference sign G4 denotes a gate signal terminal of the MOSFET Q4, and reference sign S4 denotes a source terminal of the MOSFET Q4. Reference sign P denotes a positive side power input terminal, reference sign N denotes a negative side power input terminal, and reference sign O denotes an output terminal.

Moreover, FIG. 30B shows a schematic circuit representative of the 2-in-1 module, which is the power module 50T according to the embodiments. As shown in FIG. 30B, two IGBTs Q1, Q4, and diodes D1, D4 connected in reversely parallel to the IGBTs Q1, Q4 are built in one module. Reference sign G1 denotes a gate signal terminal of the IGBT Q1, and reference sign E1 denotes an emitter terminal of the IGBT Q1. Reference sign G4 denotes a gate signal terminal of the IGBT Q4, and reference sign E4 denotes an emitter terminal of the IGBT Q4. Reference sign P denotes a positive side power input terminal, reference sign N denotes a negative side power input terminal, and reference sign O denotes an output terminal.

### Configuration Example of Semiconductor Device

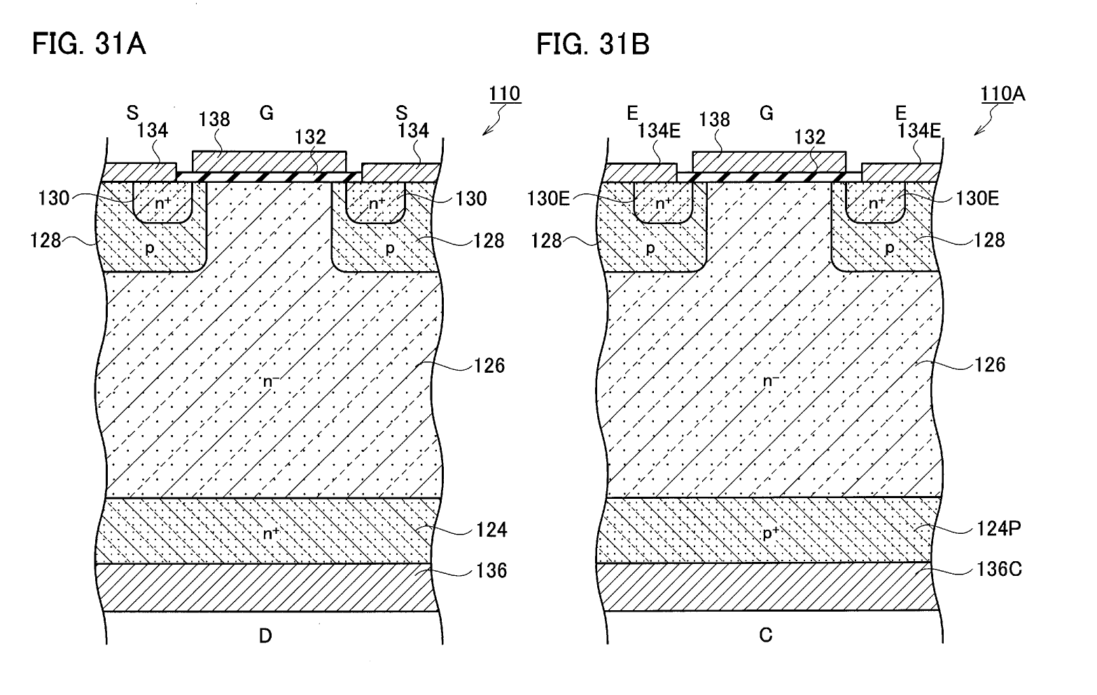

FIG. 31A shows a schematic cross-sectional structure of an SiC MOSFET, which is an example of a semiconductor device which can be applied to the power module according to the first to third embodiments, and FIG. 31B shows a schematic cross-sectional structure of the IGBT.

As shown in FIG. 31A, a schematic cross-sectional structure of the SiC MOSFET as an example of the semiconductor device 110 (Q) which can be applied to the first to third embodiments includes: a semiconductor substrate 126 composed by including an n⁻ type high resistivity layer; a p body region 128 formed on a front surface side of the semiconductor substrate 126; a source region 130 formed on a front side surface of the p body region 128; a gate insulating film 132 disposed on a front side surface of the semiconductor substrate 126 between the p body regions 128; a gate electrode 138 disposed on the gate insulating film 132; a source electrode 134 connected to the source region 130 and the p body region 128; an n⁺ drain region 124 disposed on a back side surface opposite to the surface of the semiconductor substrate 126; and a drain electrode 136 connected to the n⁺ type drain area 124.

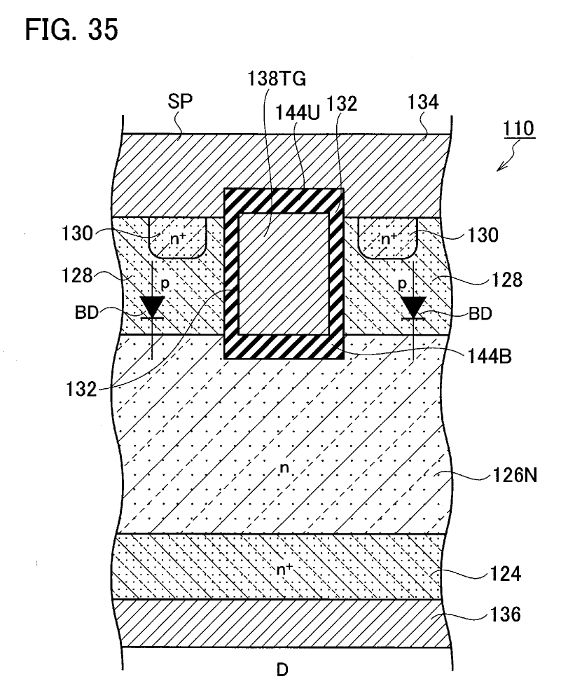

Although the semiconductor device 110 is composed by including a planar-gate-type n channel vertical SiC-MOSFET in FIG. 31A, the semiconductor device 110 may be composed by including an n channel vertical SiC-TMOSFET, etc., shown in FIG. 35 mentioned below.

Moreover, a GaN based FET etc. instead of SiC MOSFET can also be adopted to the semiconductor device 110 (Q) which can be applied to the first to third embodiments.

Any one of an SiC based power device or GaN based power device can be adopted to the semiconductor device 110 applicable to the first to third embodiments.

Furthermore, a semiconductor of which the bandgap energy is within a range from 1.1 eV to 8 eV, for example, can be used for the semiconductor device 110 applicable to the embodiments.

Similarly, as shown in FIG. 31B, the IGBT as an example of the semiconductor device 110A (Q) applicable to the first to third embodiments includes: a semiconductor substrate 126 composed by including an n⁻ type high resistivity layer; a p body region 128 formed on a front surface side of the semiconductor substrate 126; an emitter region 130E formed on a front side surface of the p body region 128; a gate insulating film 132 disposed on a front side surface of the semiconductor substrate 126 between the p body regions 128; a gate electrode 138 disposed on the gate insulating film 132; an emitter electrode 134E connected to the emitter region 130E and the p body region 128; a p⁺ collector region 124P disposed on a back side surface opposite to the surface of the semiconductor substrate 126; and a collector electrode 136C connected to the p⁺ collector region 124P.

In FIG. 31B, although the semiconductor device 110A is composed by including a planar-gate-type n channel vertical IGBT, the semiconductor device 110A may be composed by including a trench-gate-type n channel vertical IGBT, etc.

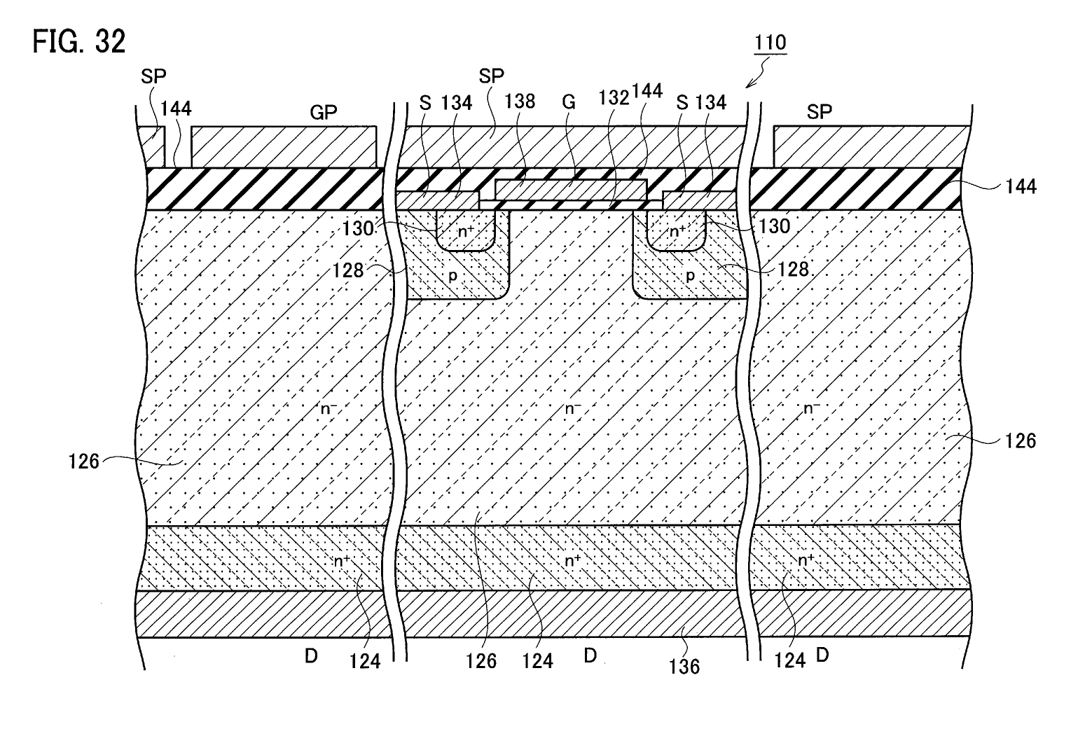

FIG. 32 shows a schematic cross-sectional structure of an SiC MOSFET including a source pad electrode SP and a gate pad electrode GP, which is an example of the semiconductor device 110 applicable to the first to third embodiments. The gate pad electrode GP is connected to the gate electrode 138 disposed on the gate insulating film 132, and the source pad electrode SP is connected to the source electrode 134 connected to the source region 130 and the p body region 128.

Moreover, as shown in FIG. 32, the gate pad electrode GP and the source pad electrode SP are disposed on an interlayer insulating film 144 for passivation which covers the surface of the semiconductor device 110. Microstructural transistor structure may be formed in the semiconductor substrate 126 below the gate pad electrode GP and the source pad electrode SP in the same manner as the center portion shown in FIG. 31A or 32.

Furthermore, as shown in FIG. 32, the source pad electrode SP may be disposed to be extended onto the interlayer insulating film 144 for passivation, also in the transistor structure of the center portion.

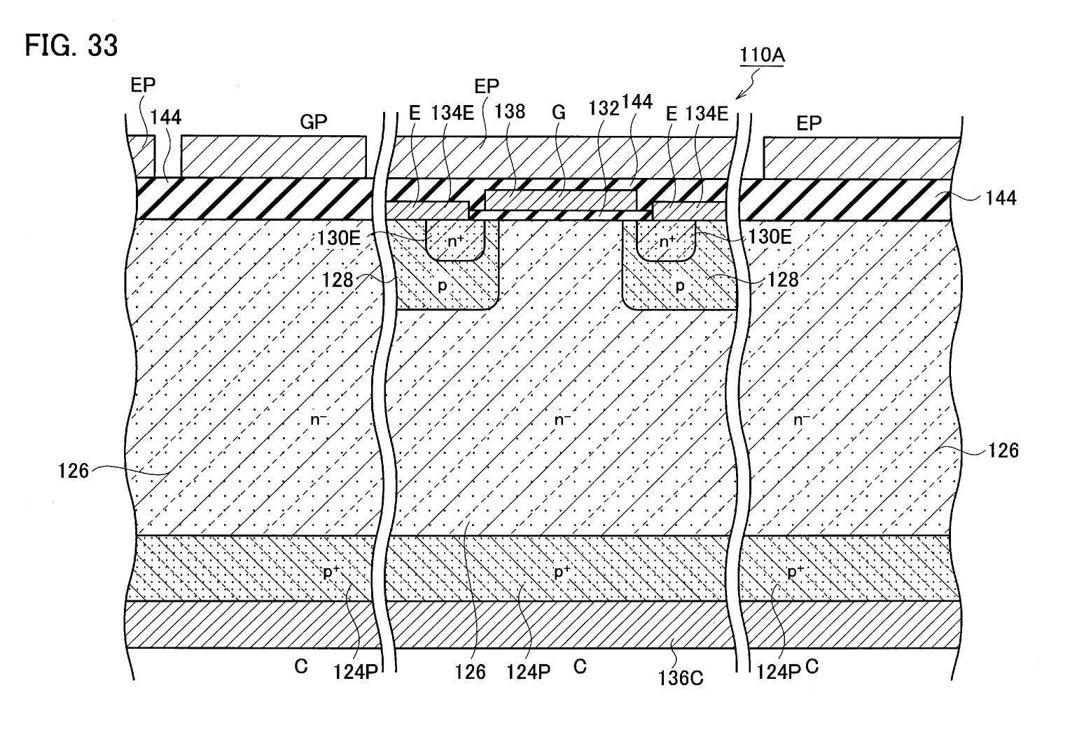

FIG. 33 shows a schematic cross-sectional structure of an IGBT including a source pad electrode SP and a gate pad electrode GP, which is an example of the semiconductor device 110A to be applied to the first to third embodiments. The gate pad electrode GP is connected to the gate electrode 138 disposed on the gate insulating film 132, and the emitter pad electrode EP is connected to the emitter electrode 134E connected to the emitter region 130E and the p body region 128.

Moreover, as shown in FIG. 33, the gate pad electrode GP and the emitter pad electrode EP are disposed on an interlayer insulating film 144 for passivation which covers the surface of the semiconductor device 110A. Microstructural IGBT structure may be formed in the semiconductor substrate 126 below the gate pad electrode GP and the emitter pad electrode EP in the same manner as the center portion shown in FIG. 31B or 33.

Furthermore, as shown in FIG. 33, the emitter pad electrode EP may be disposed to be extended onto the interlayer insulating film 144 for passivation, also in the IGBT structure of the center portion.

### —SiC DIMOSFET—

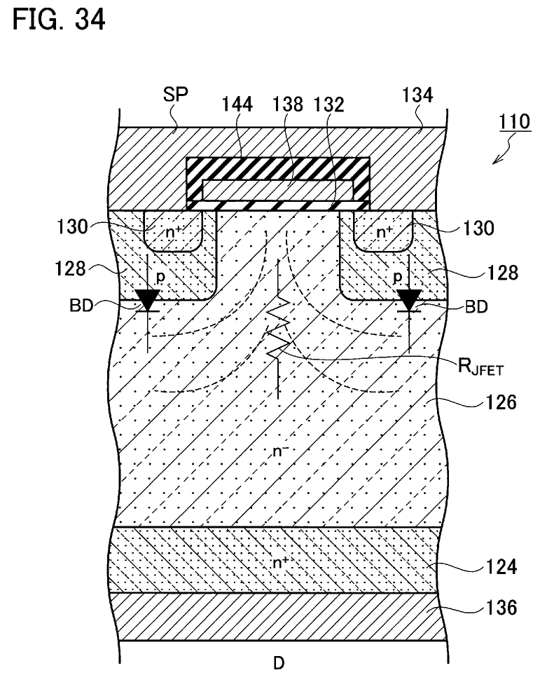

FIG. 34 shows a schematic cross-sectional structure of an SiC DIMOSFET, which is an example of the semiconductor device 110 which can be applied to the first to third embodiments.

As shown in FIG. 34, the SiC DIMOSFET includes: a semiconductor substrate 126 composed of an n⁻ type high resistivity layer; a p body region 128 formed on a front surface side of the semiconductor substrate 126; an n⁺ source region 130 formed on a front side surface of the p body region 128; a gate insulating film 132 disposed on a front side surface of the semiconductor substrate 126 between the p body regions 128; a gate electrode 138 disposed on the gate insulating film 132; a source electrode 134 connected to the source region 130 and the p body region 128; an n⁺ drain region 124 disposed on a back side surface opposite to the surface of the semiconductor substrate 126; and a drain electrode 136 connected to the n⁺ type drain area 124.

In the semiconductor device 110 shown in FIG. 34, the p body region 128 and the n⁺ source region 130 formed on the front side surface of the p body region 128 are formed with double ion implantation (DI), and the source pad electrode SP is connected to the source region 130 and the source electrode 134 connected to the p body region 128. A gate pad electrode GP (not shown) is connected to the gate electrode 138 disposed on the gate insulating film 132. Moreover, as shown in FIG. 34, the source pad electrode SP and the gate pad electrode GP (not shown) are disposed on an interlayer insulating film 144 for passivation configured to cover the front side surface of the semiconductor device 110.

As shown in FIG. 34, in the SiC DIMOSFET, since a depletion layer as shown with the dashed lines is formed in the semiconductor substrate 126 composed of a n⁻ type high resistivity layer inserted into the p body regions 128, channel resistance R_{JFET} accompanying the junction type FET (JFET) effect is formed. Moreover, as shown in FIG. 34, body diodes BD are respectively formed between the p body regions 128 and the semiconductor substrates 126.

### —SiC TMOSFET—

FIG. 35 shows a schematic cross-sectional structure of an SiC TMOSFET, which is an example of the semiconductor device 110 which can be applied to the first to third embodiments.

As shown in FIG. 35, the SiC TMOSFET includes: a semiconductor substrate 126N composed of an n− type high resistivity layer; a p body region 128 formed on a front surface side of the semiconductor substrate 126N; an n⁺ source region 130 formed on a front side surface of the p body region 128; a trench gate electrode 138TG passing through the p body region 128, the trench gate electrode 138TG formed in the trench formed up to the semiconductor substrate 126N via the gate insulating layer 132 and the interlayer insulating films 144U, 144B; a source electrode 134 connected to the source region 130 and the p body region 128; an n⁺ type drain area 124 disposed on a back side surface of the semiconductor substrate 126N opposite to the front side surface thereof; and a drain electrode 136 connected to the n⁺ type drain area 124.

In the semiconductor device 110 shown in FIG. 35, a trench gate electrode 138TG passes through the p body region 128, and the trench gate electrode 138TG formed in the trench formed up to the semiconductor substrate 126N is formed via the gate insulating layer 132 and the interlayer insulating films 144U, 144B, and the source pad electrode SP is connected to the source region 130 and the source electrode 134 connected to the p body region 128. A gate pad electrode GP (not shown) is connected to the gate electrode 138 disposed on the gate insulating film 132. Moreover, as shown in FIG. 35, the source pad electrode SP and the gate pad electrode GP (not shown) are disposed on an interlayer insulating film 144U for passivation configured to cover the front side surface of the semiconductor device 110. In the SiC TMOSFET, channel resistance R_{JFET} accompanying the junction type FET (JFET) effect as the SiC DIMOSFET is not formed. Moreover, body diodes BD are respectively formed between the p body regions 128 and the semiconductor substrates 126N.

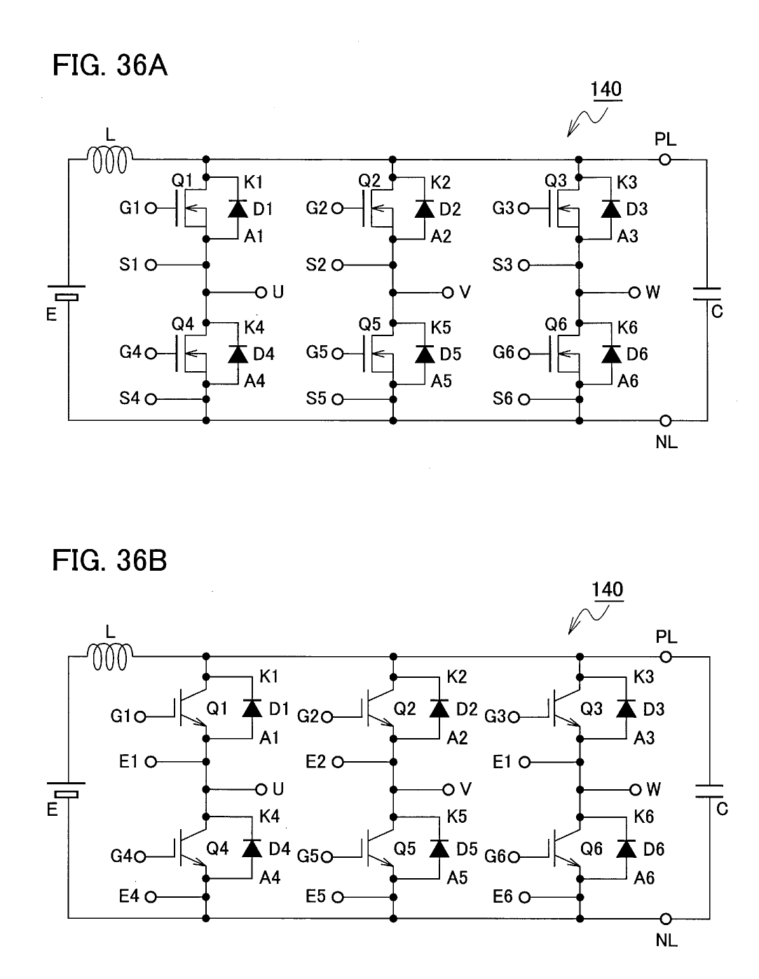

FIG. 36A shows an example of a circuit configuration in which the SiC MOSFET is applied as a semiconductor device, and a snubber capacitor C is connected between the power terminal PL and the earth terminal (ground terminal) NL, in a schematic circuit configuration of a three-phase AC inverter 140. Similarly, FIG. 36B shows an example of a circuit configuration in which the IGBT is applied as a semiconductor device, and a snubber capacitor C is connected between the power terminal PL and the earth terminal (ground terminal) NL, in a schematic circuit configuration of a three-phase AC inverter 140A.

When connecting the SiC MOSFET or IGBT to the power source E, large surge voltage Ldi/dt is produced by an inductance L included in a connection line due to a high switching speed of the SiC MOSFET or IGBT. For example, the surge voltage Ldi/dt is expressed as follows: di/dt=3×10⁹ (A/s), where a current change di=300 A, and a time variation accompanying switching di/dt=100 ns. Although a value of the surge voltage Ldi/dt changes dependent on a value of the inductance L, the surge voltage Ldi/dt is superimposed on the power source V. Such a surge voltage Ldi/dt can be absorbed by the snubber capacitor C connected between the power terminal PL and the earth terminal (ground terminal) NL.

### Application Examples for Applying Power Module

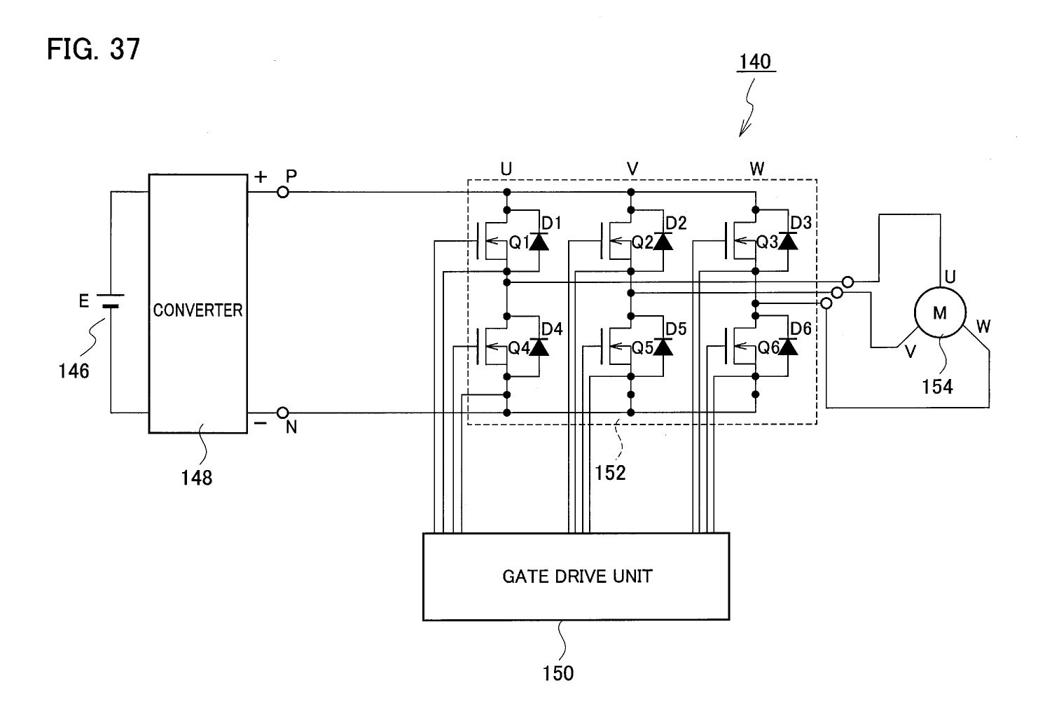

Next, there will now be explained the three-phase AC inverter 140 composed using the power module according to the first to third embodiments to which the SiC MOSFET is applied as the semiconductor device, with reference to FIG. 37.

As shown in FIG. 37, the three-phase AC inverter 140 includes a gate drive unit 150, a semiconductor device unit 152 connected to the gate drive unit 150, and a three-phase AC motor unit 154. U-phase, V-phase, and W-phase inverters are respectively connected to the three-phase AC motor unit 154 so as to correspond to U phase, V phase, and W phase of the three-phase AC motor unit 154, in the semiconductor device unit 152. In the embodiments, the gate drive unit 150 is connected to the SiC MOSFETs Q1, Q4, SiC MOSFETs Q2, Q5, and the SiC MOSFETs Q3, Q6.

The semiconductor device unit 152 includes the SiC MOSFETs Q1, Q4, and Q2, Q5, and Q3, Q6 having inverter configurations connected between a positive terminal (+) and a negative terminal (−) of the converter 148 to which a storage battery (E) 146 is connected. Moreover, flywheel diodes D1 to D6 are respectively connected reversely in parallel between the source and the drain of the SiC MOSFETs Q1 to Q6.

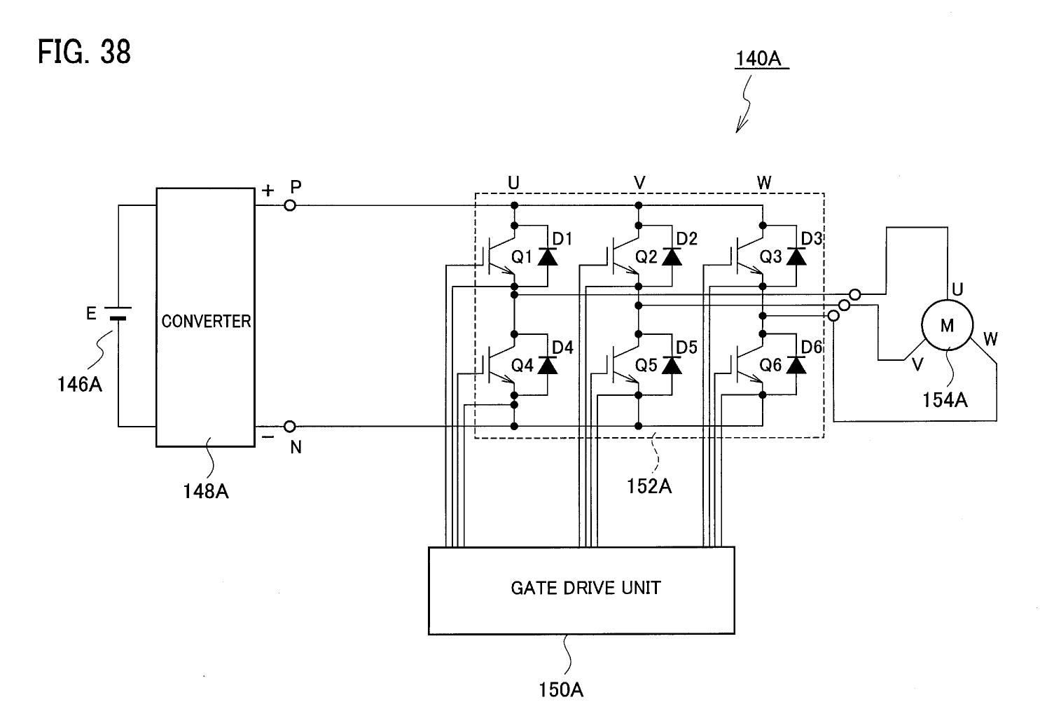

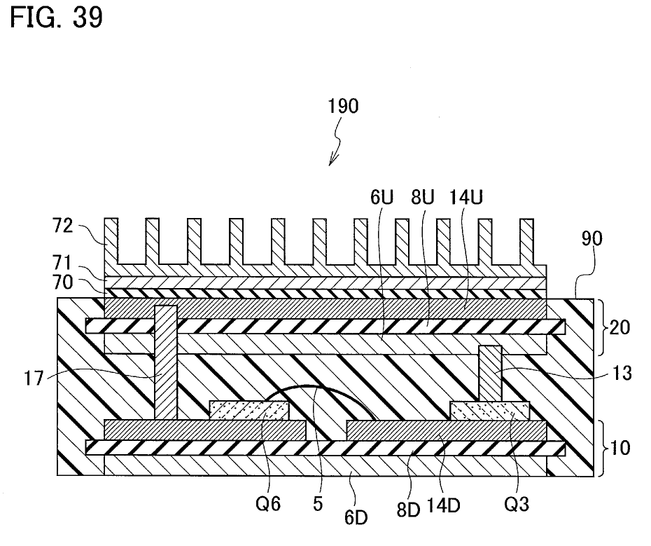

Next, there will now be explained the three-phase AC inverter 140A composed using the power module 20T according to the first to third embodiments to which the IGBT is applied as the semiconductor device, with reference to FIG. 38.

As shown in FIG. 38, the three-phase AC inverter 140A includes: a gate drive unit 150A; a semiconductor device unit 152A connected to the gate drive unit 150A; and a three-phase AC motor unit 154A. U-phase, V-phase, and W-phase inverters are respectively connected to the three-phase AC motor unit 154A so as to correspond to U phase, V phase, and W phase of the three-phase AC motor unit 154A, in the semiconductor device unit 152A. In this case, the gate drive unit 150A is connected to the IGBTs Q1, Q4, IGBTs Q2, Q5, and the IGBTs Q3, Q6.

The semiconductor device unit 152A includes the IGBTs Q1, Q4, and Q2, Q5, and Q3, Q6 having inverter configurations connected between a positive terminal (+) and a negative terminal (−) of the converter 148A to which a storage battery (E) 146A is connected. Furthermore, flywheel diodes D1-D6 are respectively connected reversely in parallel between the emitter and the collector of the IGBTs Q1-Q6.

The power modules according to the first to third embodiments can be formed as any one selected from the group consist of 1-in-1 module, 2-in-1 module, 4-in-1 module, and 6-in-1 module.

### Configuration Example of Power Module Including Cooling Apparatus

FIG. 39 shows a schematic tectonic profile of a power module 190 according to the first to third embodiments including a cooling apparatus 72. The power module 190 corresponds to the power module 90 having the above-mentioned basic configuration in the first to third embodiments on which the cooling apparatus 72 is mounted.

The power module 190 includes a power module 90, an insulating plate 70, a heat exchanger plate 71, and a cooling apparatus 72.

The insulating plate 70 is disposed so as to be contacted with a surface at the U side of the second insulating substrate 20 which constitutes the power module 90. The insulating plate 70 is configured to insulate the conductive layer 14U at the U side of the second insulating substrate 20 which is a bus bar BP in this example, from the cooling apparatus 72.

The heat exchanger plate 71 is disposed on a surface at the U side of the insulating plate 70, and the cooling apparatus 72 is also disposed at the U side thereof. The cooling apparatus 72 is an air-cooling fin in this example. Alternatively, a water-cooling apparatus may be applied thereto. It is not necessary to always provide such a heat exchanger plate 71. According to the power module 190, thermal dissipation from the second insulating substrate 20 can be efficiently realized.

Alternatively or additionally, the cooling apparatus 72 may be contacted with a surface at the D side of the first insulating substrate 10 which constitutes the power module 90. More specifically, the cooling apparatus 72 may be disposed on any one or both of the surface (back side surface at the lower surface side of the first insulating substrate) different from the surface on which the semiconductor devices Q1, Q4 are disposed, or the surface of the second insulating substrate 20 (front side surface at the upper surface side of the second insulating substrate) which is not opposite to the first insulating substrate 10.

As explained above, according to the first to third embodiments, since it is not necessary to dispose the bus bars BP, BN on the same plane, the plane size of the power module can be miniaturized. Moreover, since the direction of the electric current which flows into the source electrode pattern in each of U, V and W phases becomes reversed, the magnetic flux which occurs due to the electric current can be canceled, and thereby the inductance can be reduced. Moreover, since the warpage of the power module is reduced, the reliability thereof can be improved.

### Basic Technology of Fourth to Sixth Embodiments

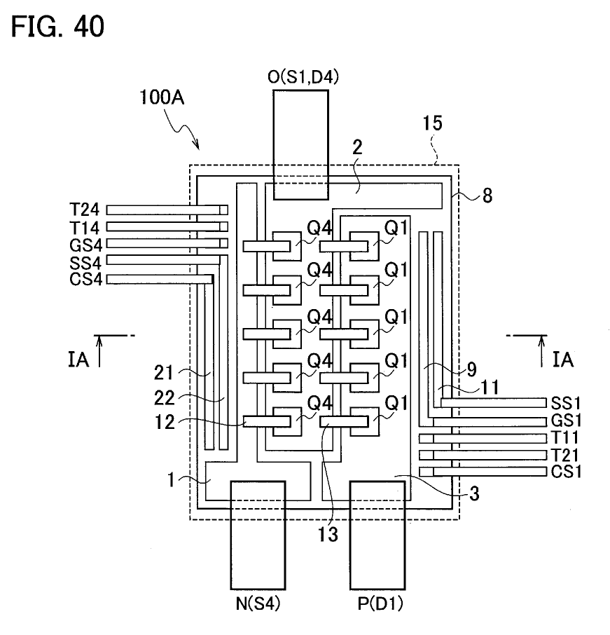

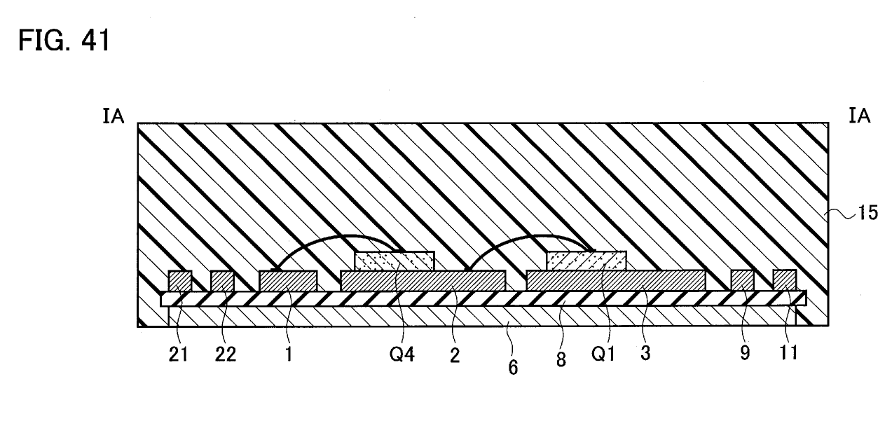

FIG. 40 shows a schematic plain diagram of a principal portion of a power module 100A according to a basic technology of fourth to sixth embodiments, and FIG. 2 shows a circuit configuration of a 2-in-1 module corresponding to FIG. 40 to which SiC MOSFETs are applied, as a semiconductor device (chip). Moreover, FIG. 41 shows a schematic cross-sectional structure taken in the line IA-IA of FIG. 40.

The power module 100A includes: an insulating substrate 8; a current sense pattern 21, a source sense pattern 22, a source electrode pattern 1, an output electrode pattern 2, a drain electrode pattern 3, a gate electrode pattern 9, and a source sense pattern 11, each disposed on the insulating substrate 8; a plurality of semiconductor devices Q4 disposed on the output electrode pattern 2; a lead member 12 connected to between a source electrode of each semiconductor device Q4 and the source electrode patterns 1; a plurality of semiconductor devices Q1 disposed on the drain electrode pattern 3; a lead member 13 connected to between a source electrode (S1) of each semiconductor device Q1 and the output electrode patterns 2; a negative-side power terminal N configured to extract the source electrode pattern 1 to the outside; a positive-side power terminal P configured to extract the drain electrode pattern 3 to the outside; and an output terminal O configured to extract the output electrode pattern 2 to the outside. Moreover, terminals T24 to CS4 and terminals CS1 to SS1 are control terminals configured to control an operation of each semiconductor devices Q1, Q4. The detailed representation is omitted in FIGS. 40 and 2.

Each of the semiconductor devices Q1, Q4 of the basic technology is an SiC MOSFET, for example. FIG. 40 shows an example of 5-chip semiconductor devices Q1 arranged in parallel to one another and 5-chip semiconductor devices Q4 arranged in parallel.

A principal portion of the power module 100A is sealed with a mold resin 15. The insulating substrate 8 is a substrate having conductive layers on both surfaces thereof, and the conductive layer 6 formed on a surface at an opposite side where the semiconductor devices Q1, Q4 are mounted is exposed to the outside thereof, for example (refer to FIG. 41).

Between the positive-side power terminal P and the drain electrode pattern 3, between the negative-side power terminal N and the source electrode pattern 1, and between the output terminal O and the output electrode pattern 2 are respectively connected by means of soldering etc., for example. Similarly, between the source electrode pattern 1 and the source electrode (S4) of the semiconductor device Q4, and between the output electrode pattern 2 and the source electrode (S1) of the semiconductor device Q1 are respectively connected by means of the lead members 12, 13. Since mounting space is required for the soldering, the connection in particular by means of the lead members 12, 13 upsizes the plane shape of the power module 100A. In this example, a plane shape in a direction which is orthogonal to an arrangement direction of the plurality of the semiconductor devices Q1, Q4 due to the lead members 12, 13 becomes larger, and therefore it is difficult to miniaturize the power module.

### Fourth Embodiment

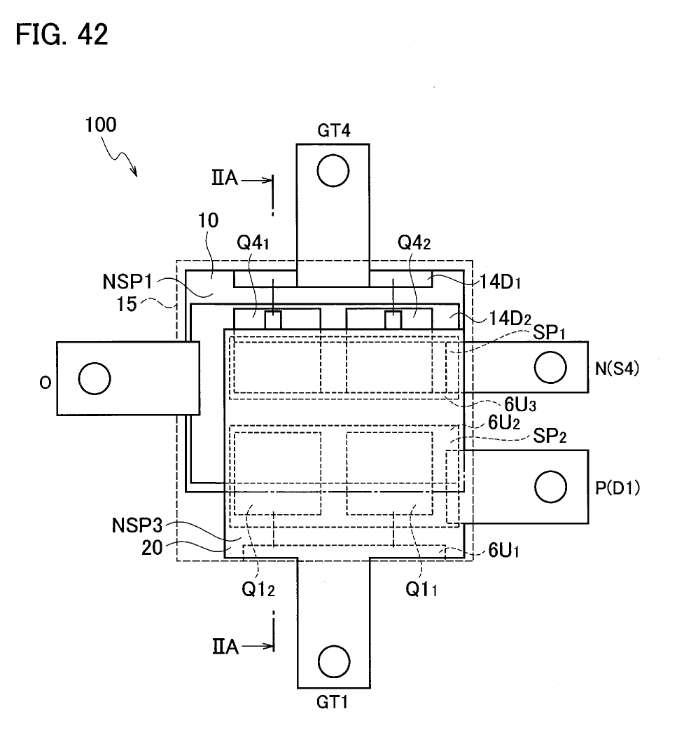

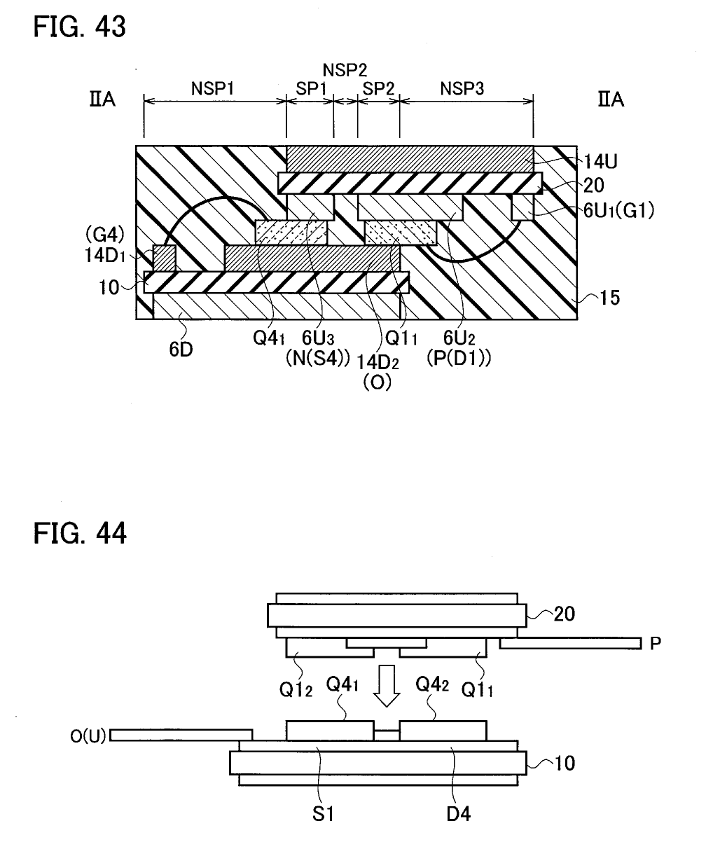

FIG. 42 shows a schematic plain diagram showing a principal portion of a power module 100 according to the fourth embodiment. A schematic cross-sectional structure diagram of a first insulating substrate 10 and a second insulating substrate 20 which constitute the power module 100 is as similarly shown in FIGS. 7A and 7B. Moreover, FIG. 43 shows a schematic cross-sectional structure diagram taken in the line IIA-IIA of FIG. 42. A circuit configuration of the power module 100 to which an SiC MOSFET is applied as a semiconductor device (chip) is similar to the basic technology of the first to third embodiments (FIG. 2).

The power module 100 includes: a first insulating substrate 10; a second insulating substrate 20 disposed at an upper side of the first insulating substrate 10; and first semiconductor devices Q4₁, Q4₂ disposed on the first insulating substrate 10, each of the first semiconductor devices Q4₁, Q4₂ including a first main electrode and a first control electrode on a front side surface thereof, wherein the first main electrodes are disposed at superimposed portions SP1, SP2 between the first insulating substrate 10 and the second insulating substrate 20, and the first control electrodes of the first semiconductor devices Q4₁, Q4₂ are disposed non-superimposed portion NSP1 between the first insulating substrate 10 and the second insulating substrate 20.

The power module 100 realizes a 2-in-1 module having a configuration of laminating the first insulating substrate 10 and the second insulating substrate 20. At least a portion of the second insulating substrate 20 is superimposed on the first insulating substrate 10, and the remaining portion of the second insulating substrate 20 is not superimposed on the first insulating substrate 10 (non-superimposed). The main electrodes described herein is a source electrode and/or drain electrode. The control electrode described herein is a gate electrode.

The power module 100 shown in FIG. 42 includes: a first insulating substrate 10; a first semiconductor devices Q4₁, Q4₂; an output terminal O; a gate terminal GT4; a second insulating substrate 20; second semiconductor devices Q1₁, Q1₂; a positive-side power terminal P; a negative-side power terminal N; and a gate terminal GT1. The first semiconductor devices Q4₁, Q4₂ are disposed on the first insulating substrate 10, and the output terminal O and the gate terminal GT4 are connected to the first insulating substrate 10. The second semiconductor devices Q1₁, Q1₂ are disposed on the second insulating substrate 20, and the positive-side power terminal P, the negative-side power terminal N, and the gate terminal GT1 are connected to the second insulating substrate 20.

Shapes of the first insulating substrate 10 and the second insulating substrate 20 shown in FIG. 42 are respectively quadrangles, for example. It is not necessary to limit the shapes of the substrates to the quadrangles.

In FIG. 43, the second insulating substrate 20 side is defined as a U (UP) side, and the first insulating substrate 10 side is defined as a D (DOWN) side, in the embodiments. This definition is also applied to all of the drawings shown hereinafter.

As the first insulating substrate 10 and the second insulating substrate 20, an Active Metal Brazed, Active Metal Bond (AMB) substrate etc. can be applied thereto, for example. The first insulating substrate 10 includes the conductive layer 14D at the upside (U side) of the insulating substrate 8D, and the conductive layer 6D at the downside (D side) thereof (FIG. 7B). The second insulating substrate 20 includes the conductive layer 14U at the U side of the insulating substrate 8U, and the conductive layer 6U at the D side thereof (FIG. 7A). Hereinafter, the upside and downside of the first insulating substrate 10 and the upside and downside of the second insulating substrate 20 are described in the same manner. In following embodiments, representation of the conductive layer 14D, the conductive layer 6D, the conductive layer 14U, and the conductive layer 6U is fixed, and wiring patterns composed by including Cu or Al are provided.

The conductive layer 14D includes a first gate electrode pattern 14D₁ and an output electrode pattern 14D₂, in the example shown in FIGS. 42 and 43. The first gate electrode pattern 14D₁ is disposed in a long and slender rectangular shape along one side of the first insulating substrate 10. The output electrode pattern 14D₂ is separated from (insulated from) the first gate electrode pattern 14D₁, and is disposed on the substantially whole surface of the first insulating substrate 10.

Moreover, the conductive layer 6U at the D side of the second insulating substrate 20 disposed to be opposite to the first insulating substrate 10 includes: a second gate electrode pattern 6U₁, a drain electrode pattern 6U₂, and a negative electrode pattern 6U₃, wherein the respective patterns are separated from one another and constitute the whole of the conductive layer 6U. The second gate electrode pattern 6U₁ is disposed in a long and slender rectangular shape along one side opposite to the first gate electrode pattern 14D₁, in a planar view of the power module 100. The drain electrode pattern 6U₂ has a width larger than a width of the positive-side power terminal P, and is disposed in parallel to the second gate electrode pattern 6U₁. Furthermore, the negative electrode pattern 6U₃ has a width somewhat thicker than that of the negative-side power terminal N, and is disposed so as to be adjacent to the drain electrode pattern 6U₂.

The gate terminal GT4 for leading a gate electrode of the first semiconductor device Q4 to the outside thereof is connected to the first gate electrode pattern 14D₁ of the first insulating substrate 10 by means of soldering etc. FIG. 42 shows an example of using two first semiconductor devices Q4 and two second semiconductor devices Q1.

The first semiconductor devices Q4₁, Q4₂ are disposed at an edge portion at the side of the first gate electrode pattern 14D₁ of the output electrode pattern 14D₂ so that the gate electrode of each of the first semiconductor devices is directed toward to the gate signal pattern 14D₁ side.

On the other hand, on the drain electrode pattern 6U₂ of the second insulating substrate 20 disposed to be opposite to the first insulating substrate 10, the gate electrodes of the second semiconductor devices Q1₁, Q1₂ are disposed in a direction opposite to the gate electrode of the first semiconductor devices Q4₁, Q4₂.

More specifically, the power module 100 has a first non-superimposed portion NSP1 and a second non-superimposed portion NSP3. In a planar view, the first control electrode is disposed at the first non-superimposed portion NSP1, and the second control electrode is disposed at the second non-superimposed portion NSP3. Hereinafter, the first non-superimposed portion NSP1 and the second non-superimposed portion NSP3 are abbreviated to non-superimposed portion NSP1 and non-superimposed portion NSP3. Specifically, in a planar view, the first insulating substrate 10 and the second insulating substrate 20 are connected to each other at a position where the gate electrodes of the first semiconductor devices Q4₁, Q4₂ are not overlapped with the second insulating substrate 20 and the gate electrodes of the second semiconductor devices Q1₁, Q1₂ are not overlapped with the first insulating substrate 10. The non-superimposed portion is a portion which may be called a gate relief portion.

Furthermore, in the above-mentioned disposition where the first insulating substrate 10 and the second insulating substrate 20 are connected to each other, the source electrodes which are main electrodes at the U side of the first semiconductor devices Q4₁, Q4₂ are overlapped with the negative power electrode pattern 6U₃ of the second insulating substrate 20, and the source electrodes which are main electrodes at the D side of second semiconductor devices Q1₁, Q1₂ are overlapped with the output electrode pattern 14D₂ of the first insulating substrate 10.

The main electrodes (source electrode and drain electrode) of the first semiconductor devices Q4₁, Q4₂ are disposed at the superimposed portion SP1 in which the first conductive layer 14D and the second conductive layer 6U are opposite to each other, and the main electrodes of the second semiconductor devices Q1₁, Q1₂ are disposed the superimposed portion SP2 in which the first conductive layer 14D and the second conductive layer 6U are opposite to each other. Moreover, the control electrodes of the first semiconductor devices Q4₁, Q4₂ are disposed at the non-superimposed portion NSP1 in which the first conductive layer 14D is not opposite to the second conductive layer 6U, and the gate electrodes of the second semiconductor devices Q1₁, Q1₂ are disposed at the non-superimposed portion NSP3 in which the second conductive layer 6U is not opposite to the first conductive layer 14D.

For example, bonding wires respectively connect between the gate electrodes of the first semiconductor devices Q4₁, Q4₂, and the gate signal pattern 14D₁, and between the gate electrodes of the second semiconductor devices Q1₁, Q1₂, and the gate signal pattern 6U₁. The bonding wires are shown by the thick solid lines and the reference signs thereof are omitted.

The power module 100 includes: an output pattern 14D₂ patterning the first conductive layer 14D at the U side of the first insulating substrate 10; and a positive electrode pattern 6U₂ and a negative electrode pattern 6U₃ formed by patterning the second conductive layer 6U at the D side of the second insulating substrate 20, wherein the first main electrodes of the first semiconductor devices Q4₁, Q4₂ are connected to the output pattern 14D₂, the second main electrodes of the first semiconductor devices Q4₁, Q4₂ are connected to the negative electrode pattern 6U₃, the first main electrodes of the second semiconductor devices Q1₁, Q1₂ are connected to the positive electrode pattern 6U₂, and the second main electrodes of the second semiconductor devices Q1₁, Q1₂ are connected to the output pattern 14D₂.

The connecting relationship thereof is explained with reference to FIG. 43 showing a cross-sectional diagram of a portion where the first semiconductor device Q4₁ and the second semiconductor device Q1₂ are disposed. A connecting relationship between the first semiconductor devices Q4₂ and the second semiconductor devices Q1₁ which are disposed so as to be adjacent thereto is similar to that shown in FIG. 43.

The main electrode of the first semiconductor device Q4₁ is disposed at the superimposed portion SP1, and the main electrode of the second semiconductor device Q1₂ is disposed at the superimposed portion SP2. Moreover, the control electrode of the first semiconductor device Q4₁ is disposed at the non-superimposed portion NSP1, and the control electrode of the second semiconductor device Q1₂ is disposed at the non-superimposed portion NSP3. Moreover, a non-superimposed portion NSP2 is formed between the first semiconductor device Q4₁ and the second semiconductor device Q1₂. The non-superimposed portion NSP2 is formed by patterning.

The drain electrode which is a main electrode at the U side of the second semiconductor device Q1₁ is connected to the drain electrode pattern 6U₂ to which the positive-side power terminal P is connected. Moreover, the source electrode which is a main electrode at the D side of the second semiconductor device Q1₁ is connected to the output electrode pattern 14D₂.

The source electrode at the U side of the first semiconductor device Q4₁ for connecting the drain electrode to the output electrode pattern 14D₂ is connected to the negative power electrode pattern 6U₃ of the second insulating substrate 20. The negative power electrode pattern 6U₃ is led to the outside thereof via the negative-side power terminal N.

Assuming that the first semiconductor device Q4₁ and the second semiconductor device Q1₁ are simultaneously conducted, an electric current flows in order of the positive-side power terminal P→the drain electrode pattern 6U₂→the second semiconductor device Q1₁→the output electrode pattern 14D₂→the first semiconductor device Q4₁→the negative power electrode pattern 6U₃→the negative-side power terminal N.

FIG. 44 shows a schematic side view diagram of the first insulating substrate 10 after mounting the first semiconductor devices Q4₁, Q4₂, and the second insulating substrate 20 after mounting the second semiconductor devices Q1₁, Q1₂, observed from the terminal GT1 direction of FIG. 42. In FIG. 44, the representation of the positional relationship between the superimposed portions SP1, SP2 and the non-superimposed portions NSP1, NSP2 is omitted.

As shown in FIGS. 41 to 43, in a planar view, the superimposed portions SP1, SP2 and the non-superimposed portions NSP1, NSP3 are disposed so as to displace a position of the second insulating substrate 20 with respect to a position of the first insulating substrate 10.

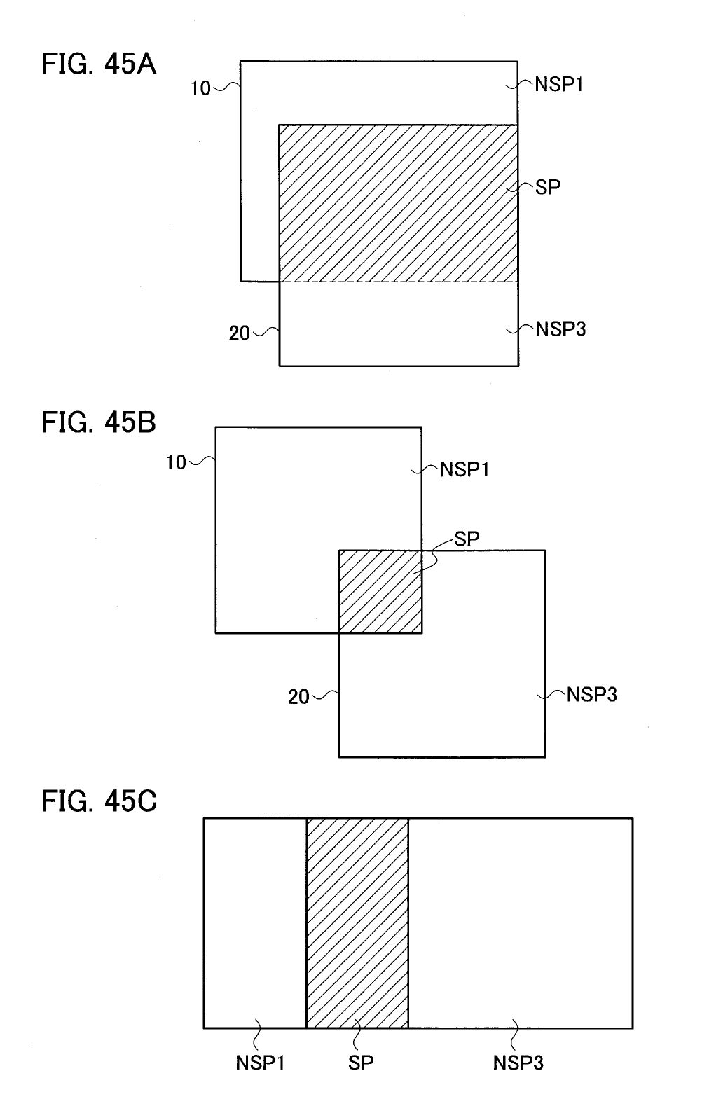

As shown in FIG. 45, various forms can be considered to how to displace the position of the second insulating substrate 20 with respect to the position of the first insulating substrate 10. FIG. 45A shows an example of relatively widely superimposing the first insulating substrate 10 on the second insulating substrate 20, both having the substantially same size. FIG. 45B shows an example of superimposing a part of the first insulating substrate 10 on a part of the second insulating substrate 20, both having the substantially same size. FIG. 45C shows an example of superimposing a part of the first insulating substrate 10 on a part of the second insulating substrate 20, each having a different size. Note that shapes of the first insulating substrate 10 and the second insulating substrate 20 is not limited to a quadrangle. Therefore, if the substrate shape is taken into consideration, the ways of superimposing the first and second insulating substrates 10, 20 are various.

Parts for wiring, e.g. lead members 12, 13, are not used for the power module 100 explained above. The distance between the first semiconductor devices Q4₁, Q4₂ and the second semiconductor devices Q1₁, Q1₂ can be shortened by using the bonding wires, instead of using the lead members 12, 13. That is, according to the configuration of the fourth embodiment, the plane shape of the power module can be miniaturized. Moreover, since the first insulating substrate 10 and the second insulating substrate 20 are disposed to be opposite to each other so that a portion corresponding to the thickness of the chip of the semiconductor device may be shared, an amount of the thickness corresponding to the thickness of the chip for the power module can be reduced, and an amount of the size of the superimposed portion SP can be reduced. Moreover, reliability of the power module can also be improved by reducing the number of the parts. Furthermore, since it can dispose so that the terminals exposed from the resin molding may not be overlapped with one another, the thickness of the terminals can be made as thick as possible and thereby the inductance thereof can be reduced.

Although the example of providing two non-superimposed portions has been explained, the number of the non-superimposed portions may be one. Subsequently, the power module 100B of a modified example provided with one non-superimposed portion will be explained.

### Modified Example

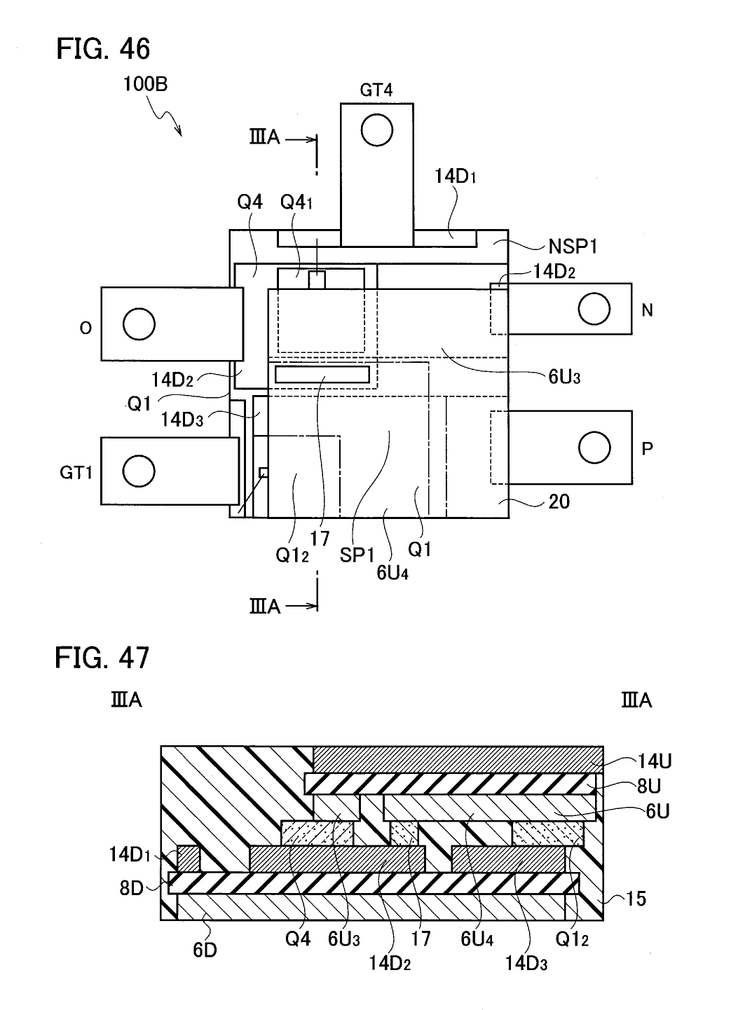

FIG. 46 shows a schematic plain diagram of a power module 100B of a modified example. Moreover, FIG. 47 shows a schematic cross-sectional structure taken in the line IIIA-IIIA of FIG. 46.

The power module 100B is different from the power module 100 in the following points: the second semiconductor device Q1₂ is disposed facedown, and the pillar electrode 17 is provided and the number of the non-superimposed portion NSP1 is one. An example of the power module 100B including two semiconductor devices (Q4₁, Q1₂) will now be explained hereinafter.

The power module 100B includes the second semiconductor device Q1₂ disposed on the second insulating substrate 20, and the second control electrode of the second semiconductor device Q1₂ is disposed at the non-superimposed portion NSP1.

The second semiconductor device Q1₂ is disposed facedown on the conductive layer 6U at the D side of the first insulating substrate 10. More specifically, the source electrode of the second semiconductor device Q1₂ is connected to the source electrode pattern 6U₄ formed in the conductive layer 6U at the D side of the second insulating substrate 20.

The drain electrode of the second semiconductor device Q1₂ is connected to the drain electrode pattern 14D₃ formed in the conductive layer 14D at the U side of the first insulating substrate 10. The drain electrode pattern 14D₃ is led to the outside thereof via the positive-side power terminal P.

The source electrode of the second semiconductor device Q1₂ is connected to the output electrode pattern 14D₂ formed in the conductive layer 14D at the U side of the first insulating substrate 10 via the source electrode pattern 6U₄ and the pillar electrode 17. The output electrode pattern 14D₂ is led to the outside thereof via the output terminal O.

The drain electrode of the first semiconductor device Q4₁ for connecting the source electrode to the output electrode pattern 14D₂ is connected to the negative power electrode pattern 6U₃ formed at the D side of the second insulating substrate 20. The negative power electrode pattern 6U₃ is led to the outside thereof via the negative electrode power terminal N.

Thus, at least one non-superimposed portion can constitute the power module.

### Fifth Embodiment

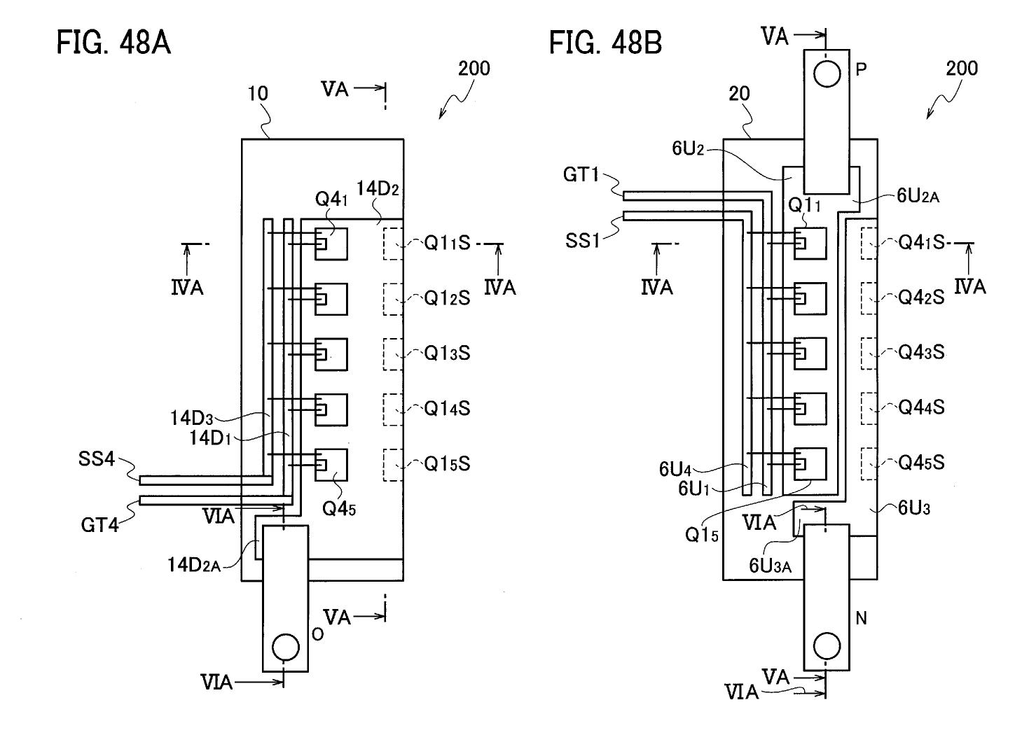

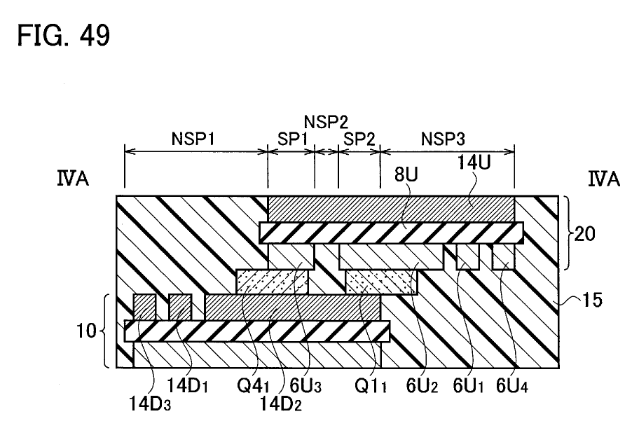

FIG. 48A shows a schematic plain diagram after mounting of a first insulating substrate 10 which composes the power module 200 according to a fifth embodiment. Moreover, FIG. 48B shows a schematic plain diagram of the second insulating substrate 20 of the power module 200 after mounting. Moreover, FIG. 49 shows a schematic cross-sectional structure taken in the line IVA-IVA, wherein the first insulating substrate 10 is superimposed on the second insulating substrate 20 shown in FIG. 48 so that an edge portion of each insulating substrate is overlapped with the semiconductor device which is mounted on the opposite insulating substrate.

The power module 200 is a 2-in-1 module formed by respectively disposing five first semiconductor devices Q4 and five second semiconductor devices Q1 in parallel. The power module 200 is similar as the power module 100 in a point of realizing the 2-in-1 module having a configuration of laminating the first insulating substrate 10 and the second insulating substrate 20.

The power module 200 includes: a first insulating substrate 10; first semiconductor devices Q4₁ to Q4₅; an output terminal O; a gate terminal GT4; a source sense terminal SS4; a second insulating substrate 20; second semiconductor devices Q1₁ to Q1₅; a positive-side power terminal P; a negative-side power terminal N; a gate terminal GT1; and a source sense terminal SS1.

The first conductive layer 14D includes the first common electrode pattern 14D₂ connected to the same type of the main electrodes (drain electrodes) of a plurality of the first semiconductor devices Q4₁ to Q4₅, and the second conductive layer 6U includes the second common electrode pattern 6U₂ connected to the same type of the main electrodes (drain electrodes) of a plurality of the second semiconductor devices Q1₁ to Q1₅. The first common electrode pattern 14D₂ and the second common electrode pattern 6U₂ are connected to each other via the second semiconductor devices Q1₁ to Q1₅.

The fifth embodiment shows an example of a shape of the first insulating substrate 10 being a rectangle. In the conductive layer 14D at the U side of the first insulating substrate 10, the first gate electrode pattern 14D₁, the output electrode pattern 14D₂, and the source sense pattern 14D₃ are disposed so as to be separated from one another.

The output electrode pattern 14D₂ has a long shape along a long side of the first insulating substrate 10 and is bent along one short side, for example. The output terminal O is led from a bent portion 14D_{2A} of the output electrode pattern 14D₂ to the outside thereof in a long side direction of the first insulating substrate 10.

The first semiconductor devices Q4₁ to Q4₅ are disposed in a row in a direction so as to direct the gate electrodes to the bent portion 14D_{2A} side to an edge side of the long side of the output pattern 14D₂.

The first gate electrode pattern 14D₁ is disposed in a long slender shape so as to be parallel to a row of the gate electrodes of the first semiconductor devices Q4₁ to Q4₅. The source sense pattern 14D₃ has the same shape as the first gate electrode pattern 14D₁, and is disposed in parallel to the first gate electrode pattern 14D₁.

The gate terminal GT4 is led to the outside thereof in a direction opposite to the first semiconductor device Q4₅ from an edge portion at the side of the output terminal O of the first gate electrode pattern 14D₁. The source sense terminal SS4 is led to the outside thereof in a direction opposite to the first semiconductor device Q4₅ from an edge portion at the side of the output terminal O of the source sense pattern 14D₃.

The quadrangles Q1₁S to Q1₅S shown by the dashed lines at an edge side opposite to one side where the first semiconductor devices Q4₁ to Q4₅ are aligned in a row are portions to which the source electrodes of the second semiconductor devices Q1₁ to Q1₅ disposed on the second insulating substrate 20 is connected.

In the fifth embodiment, a shape of the second insulating substrate 20 is a rectangle of the substantially same size as that of the first insulating substrate 10. In the conductive layer 6U at the D side of the second insulating substrate 20, the second gate electrode pattern 6U₁, the positive electrode pattern 6U₂, the negative electrode pattern 6U₃, and the source sense pattern 6U₄ are disposed so as to be separated from one another.

The second insulating substrate 20 is connected facedown to the first insulating substrate 10. The negative electrode pattern 6U₃ is a pattern connected to the source electrodes of the first semiconductor devices Q4₁ to Q4₅. The quadrangles Q4₁S to Q4₅S shown by the dashed lines in the negative electrode pattern 6U₃ are portions to which the source electrodes of the first semiconductor devices Q4₁ to Q4₅ disposed on the first insulating substrate 10 is connected.

Therefore, the negative electrode pattern 6U₃ in a face-down condition has a long shape in a long side direction which is one side of the first semiconductor devices Q4₁ to Q4₅, and has the bent portion 6U_{3A} bent in a reverse direction to the output electrode pattern 14D₂ near a short side thereof. The negative-side power terminal N is led from the bent portion 6U_{3A} of the negative electrode pattern 6U₃ to the outside thereof in a long side direction of the second insulating substrate 20.

The positive electrode pattern 6U₂ has a shape of being adjacent to the negative electrode pattern 6U₃, and includes the bent portion 6U_{2A} which engages with the negative electrode pattern 6U₃. More specifically, the positive electrode pattern 6U₂ has a shape of being bent in a reverse direction to the negative electrode pattern 6U₃ near the short side opposite to the negative-side power terminal N, and the pattern width thereof is slightly larger than that of the negative electrode pattern 6U₃. The positive-side power terminal P is led from the bent portion 6U_{2A} of the positive electrode pattern 6U₂ to the outside thereof in a direction opposite to the negative-side power terminal N.

The second semiconductor devices Q1₁ to Q1₅ are disposed in a row so as to direct the gate electrodes to a side opposite to the negative electrode pattern 6U₃ and direct the source electrodes to the D side. The negative electrode pattern 6U₃ is a common electrode pattern (second common electrode pattern) connected to the same type of the main electrodes of the first semiconductor devices Q4₁ to Q4₅.

The second gate electrode pattern 6U₁ is disposed in a long slender shape so as to be parallel to a row of the gate electrodes of the second semiconductor devices Q1₁ to Q1₅. The source sense pattern 6U₄ has the same shape as the second gate electrode pattern 6U₁, and is disposed in parallel to the second gate electrode pattern 6U₁.

The gate terminal GT1 is led to the outside thereof in a direction opposite to the first semiconductor device Q1₁ from an edge portion at the side of the positive-side power terminal P of the second gate electrode pattern 6U₁. The source sense terminal SS1 is led to the outside thereof in a direction opposite to the first semiconductor device Q1₁ from an edge portion at the side of the positive-side power terminal P of the source sense pattern 6U₄.

The connecting relationship between the first semiconductor devices Q4₁ to Q4₅ and the second semiconductor devices Q1₁ to Q1₅ which constitute the power module 200 is different from that of the power module 100 only in the following point: five semiconductor devices are connected in parallel.

Focusing on each semiconductor device, the connecting relationship between the first semiconductor device Q4₁ and the second semiconductor device Q1₁ is similar to that of the power module 100, for example, and the output pattern 14D₂ (first common electrode pattern) and the negative electrode pattern 6U₃ (second common electrode pattern) are connected to each other via the first semiconductor devices Q4₁ to Q4₅.

FIG. 49 shows a schematic cross-sectional structure of a connecting portion between the first semiconductor device Q4₁ and the second semiconductor device Q1₁. Detailed explanation is omitted by showing the superimposed portions SP1, SP2 and the non-superimposed portions NP1, NP2, NP3, and each reference sign in FIG. 49.

Although the example of the output electrode pattern 14D₂, the negative electrode pattern 6U₃ and the positive electrode pattern 6U₂ respectively including the bent portion 14D_{2A}, the bent portion 6U_{3A}, and the bent portion 6U_{2A} is shown, each bent portion is for adjusting the space with other terminals which mainly are adjacent to one another, and therefore it is not necessary to always include such bent portions. Moreover, although the example of including the terminals for connecting to the outside thereof, such as the positive-side power terminal P, the negative-side power terminal N, the gate terminal GT1, and the source sense terminal SS1, is shown, it is not necessary to also always include such terminals.

Subsequently, the power module 200A in which these terminals are deformed will be explained.

### Modified Example of Each Terminal

The power module 200A is different from the power module 200 in that other parts for external connection are not included therein. The other configurations are similar to that of the power module 200.

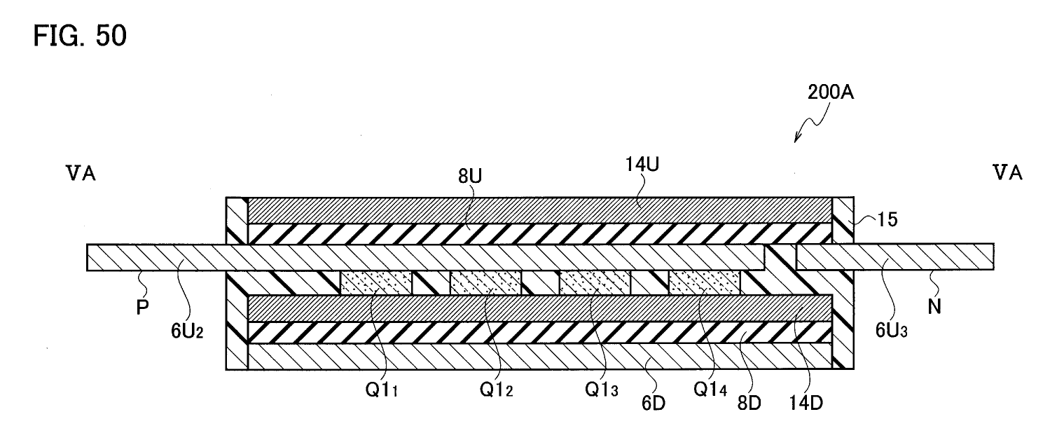

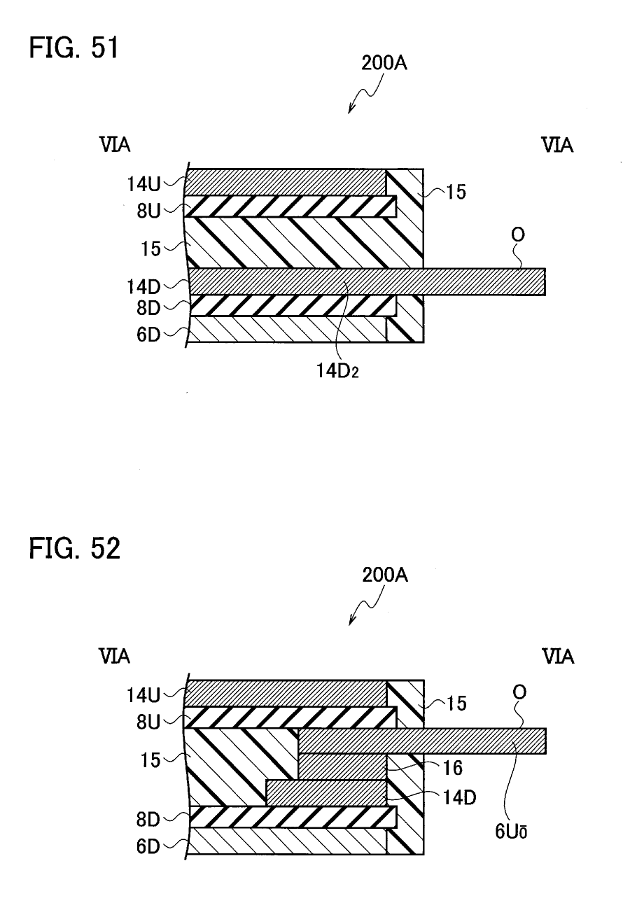

FIG. 50 shows a schematic cross-sectional structure of the power module 200A taken in the line VA-VA of FIG. 48. Moreover, FIG. 51 shows a schematic cross-sectional structure taken in the line VIA-VIA.

As shown in FIGS. 50 and 51, the output pattern 14D₂, the positive electrode pattern 6U₂, and the negative electrode pattern 6U₃ of the power module 200A are disposed so as to be extended to the outside of the first insulating substrate 10 and second insulating substrate 20, on which the respective patterns are formed, in a planar view.

More specifically, the conductive layer 14D at the U side of the first insulating substrate 10 and the conductive layer 6U at the D side of the second insulating substrate 20 are extended directly so as to be connected to the outside thereof. The extended conductive layer 6U may be fabricated in a suitable shape, instead of using the bent portion 14D_{2A}.

In this example, the output pattern 14D₂ is led from the conductive layer 14D while the positive electrode pattern 6U₂ and the negative electrode pattern 6U₃ are led from the same conductive layer 6U. Therefore, a height of the output pattern 14D₂ is different from those of other terminals.

In order to align the height of the output pattern to heights of other terminals, the configuration as shown in FIG. 52 may be adopted. FIG. 52 shows a schematic cross-sectional structure of the power module 200A taken in the line VIA-VIA of FIG. 48.

The second insulating substrate 20 includes an output terminal 6Uo, and the output pattern 14D₂ is connected to the output terminal 6Uo via the pillar electrode 16.

The heights of all terminals can be aligned by adopting such a configuration.

Other modified examples can be supposed. The conductive layer 14D and the conductive layer 6U are copper foils formed on a surface of an AMB substrate, for example. Accordingly, for flowing a large current, it is necessary to enlarge an area. However, it is also supposed that a large area cannot be obtained.

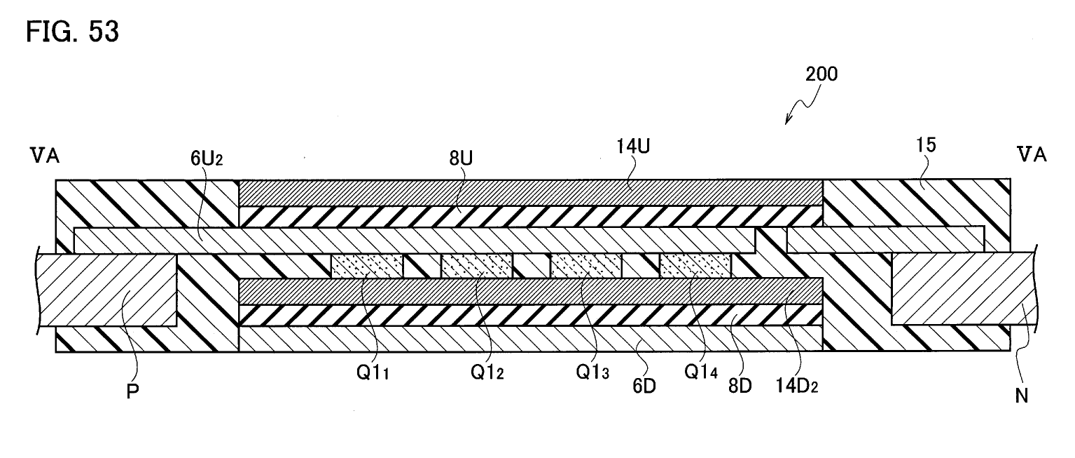

Therefore, if such a large area cannot be obtained, a configuration as shown in FIG. 53 can be supposed. FIG. 53 shows a schematic cross-sectional structure of another modified example taken in the line VA-VA. The structure shown in FIG. 53 includes the positive-side power terminal P and negative-side power terminal N of which the thicknesses are respectively thicker than those of the structure shown in FIG. 50. Since portion of the output terminal O is similar as that of the positive-side power terminal P, illustration of the portion of the output terminal O is omitted.

The power module 200 includes an output terminal O connected to an output pattern 14D₂, an anode terminal P connected to a positive electrode pattern 6U₂; and a cathode terminal N connected to a negative electrode pattern 6U₃, wherein the respective thicknesses of the output terminal O, the anode terminal P, and the cathode terminal N are thicker than the respective thicknesses of the output pattern 14D₂, the positive electrode pattern 6U₂, and the negative electrode pattern 6U₃.

Conductive materials are metallic materials, e.g. Cu, Al, Ni, Fe, Ag, and Au, for example. A resin which has an electrical conductivity containing metallic particles, e.g. Ag, W, and Mo, may be used therefor.

By being constituted in this way, the power module can be ultra-thinned and miniaturized.

### Sixth Embodiment

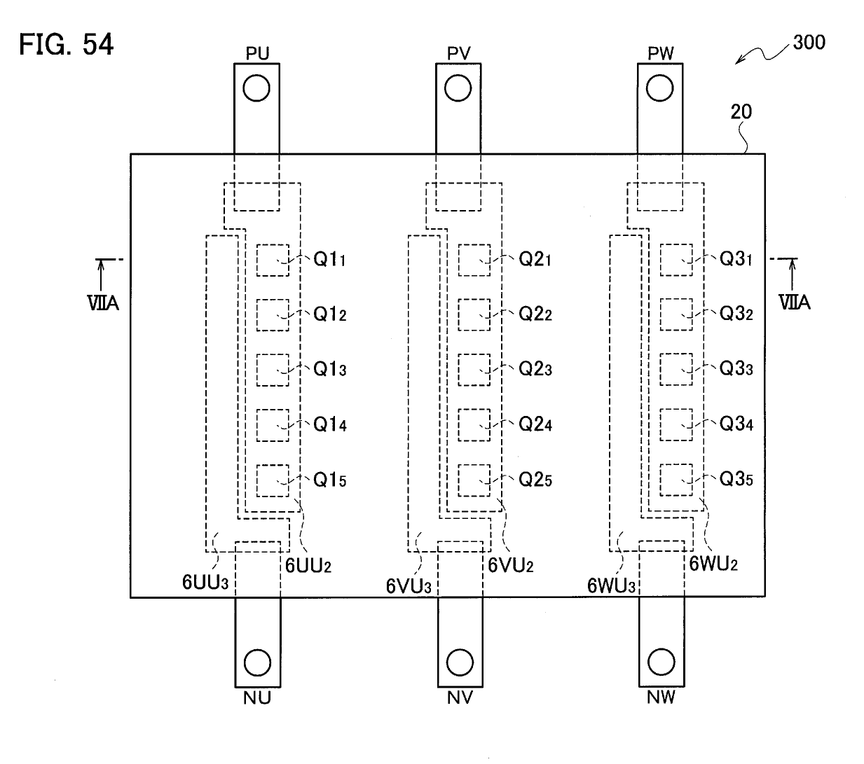

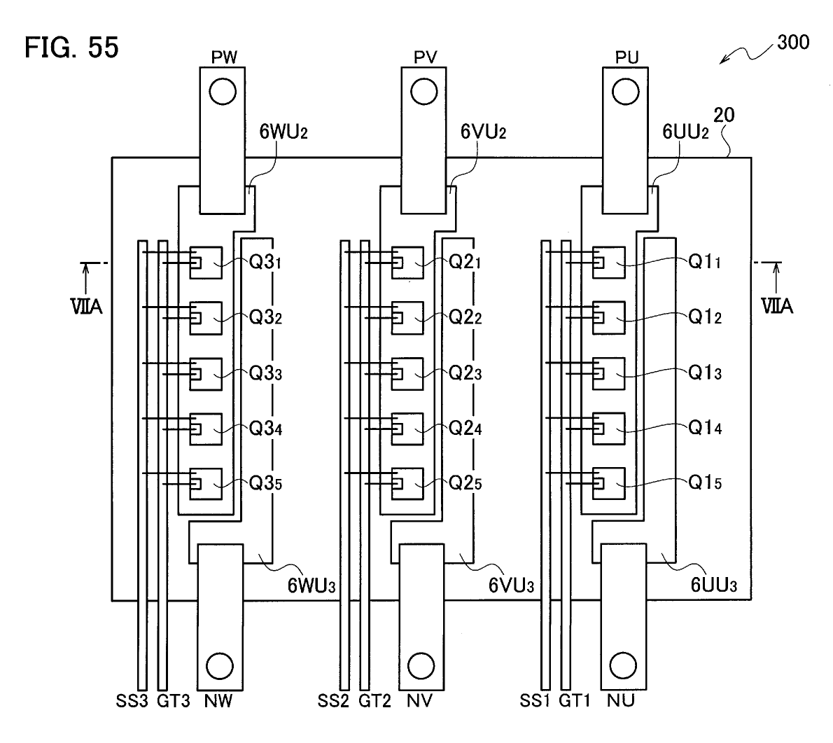

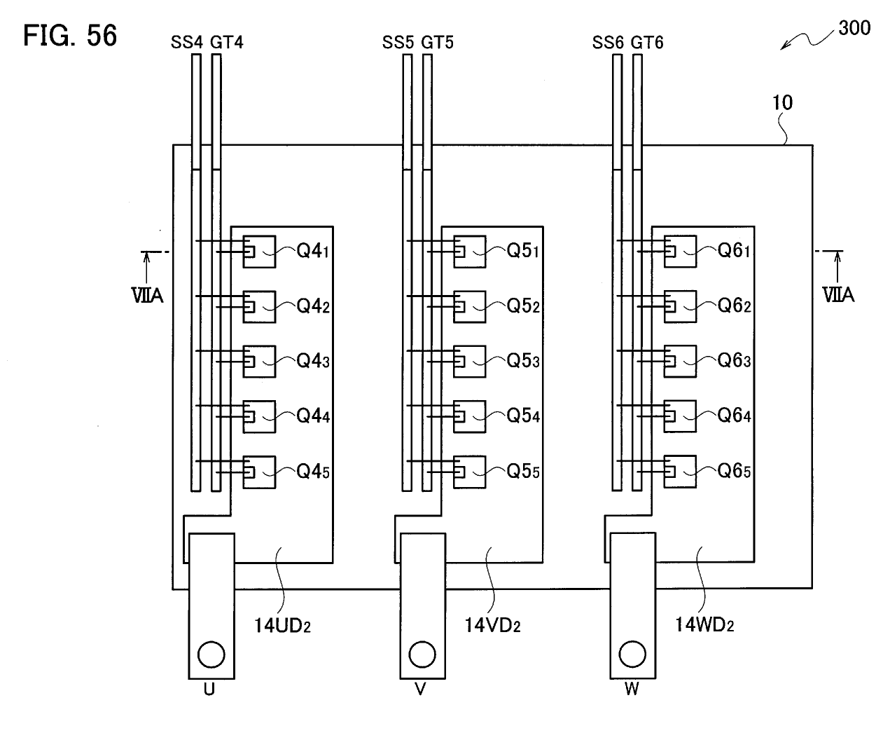

FIG. 54 shows a schematic plain diagram of a second insulating substrate 20 which constitutes a power module 300 according the sixth embodiment. Moreover, FIG. 55 shows a front side surface at a side of a mounting surface (D side) of the second insulating substrate 20 of the power module 300 after mounting. Moreover, FIG. 56 shows a front side surface at a side of a mounting surface (U side) of the first insulating substrate 10 of the power module 300 after mounting.

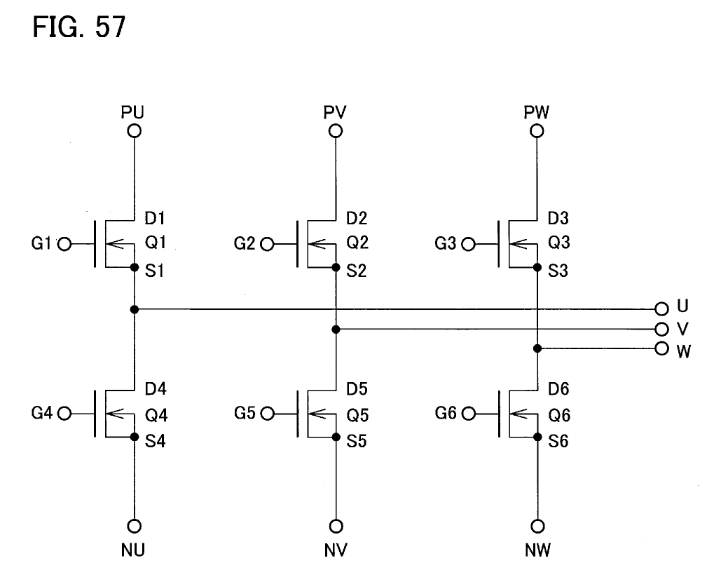

The power module 300 is a 6-in-1 module constituted by arranging three power modules 200. FIG. 57 shows a fundamental circuit configuration including no control terminal of the 6-in-1 module corresponding to FIGS. 54 to 56 to which an SiC MOSFET is applied as a semiconductor device (chip).

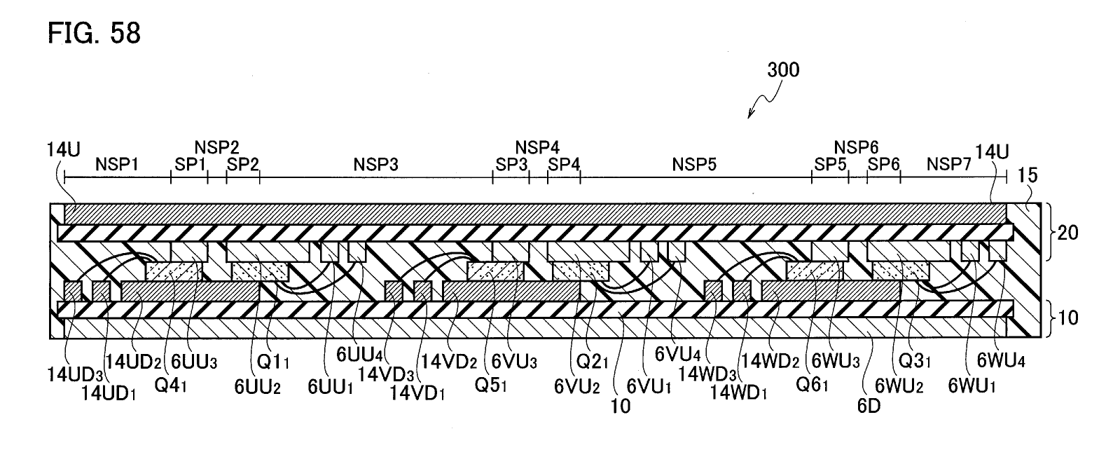

The power module 300 shown in FIG. 58 includes: a first insulating substrate 10 including a first conductive layer 14D; a second insulating substrate 20 disposed so as to be opposite to the first insulating substrate 10, second insulating substrate 20 including a second conductive layer 6U formed so as to be opposite to the first conductive layer 14D; a first semiconductor device Q4 of which a first main electrode is connected to the first conductive layer 14D; a second semiconductor device Q1 of which a first main electrode is connected to the second conductive layer 20; a non-superimposed portion NSP including only any one of the first conductive layer 14D and the second conductive layer 6U, in a planar view; and a superimposed portion SP including both of the first conductive layer 14D and the second conductive layer 6U, in a planar view, wherein the second main electrode and second conductive layer 6U of the first semiconductor device Q4, and the second main electrode and first conductive layer 14D of the second semiconductor device Q1 are disposed at the superimposed portion SP1, in a planar view, and the first control electrode of the first semiconductor device Q4 and the second control electrode of the second semiconductor device Q1 are disposed at the non-superimposed portion NSP, in a planar view.

The power module 300 includes a positive-side power terminal PU-PW and a negative-side power terminal NU-NW on a front side surface at the D side of the second insulating substrate 20 in the same manner as the power module 200, and includes output terminals U, V, W on a surface at the U side of the first insulating substrate 10. The U, V, W shows each phase of the three phase circuit. In FIG. 54, representation of the gate terminal and the source sense terminal is omitted.

The power module 300 is different from the power modules 100, 200 in the following point: all of the superimposed portions SP1, SP2 and non-superimposed portions NSP1 to NSP3 are pattern-formed by patterning.

FIG. 54 is a top view diagram of the second insulating substrate 20, and patterns on the front side surface at the D side of the second insulating substrate 20 are shown with the dashed lines. The negative electrode pattern 6UU₃ which constitutes the U phase is similar as the negative electrode pattern 6U₃ of the power module 200. Moreover, the positive electrode pattern 6UU₂ which constitutes the U phase is similar as the positive electrode pattern 6U₂ of the power module 200. The similar configuration is also applied to the other V and W phases.

It is obvious that the pattern shapes are similar by referring to FIG. 55. There are disposed the positive electrode patterns 6UU₂, 6VU₂, 6WU₂ and negative electrode patterns 6UU₃, 6VU₃, 6WU₃ having the same shape as the positive electrode pattern 6U₂ and negative electrode pattern 6U₃ shown in FIG. 48.

As shown in FIG. 56, the same configuration may be applied to the first insulating substrate 10. There are disposed three output patterns 14UD₂, 14VD₂, 14WD₂ having the same shape as the output pattern 14D₂ of the power module 200.

Thus, the power module 300 is a module formed by arranging three power modules 200 in parallel to one another. FIG. 58 shows a schematic cross-sectional structure of the power module 300 taken in the line VIIA-VIIA. Detailed explanation of the connecting relationship is omitted by showing the superimposed portions SP1 to SP6 and the non-superimposed portions NSP1 to NSP7, and each reference sign in FIG. 58.

As obvious from FIG. 58, the power module 300 includes a plurality of the superimposed portions SP1 to SP6 and a plurality of the non-superimposed portions NSP1 to NSP7. In the arrangement direction of the first semiconductor device Q4 and the second semiconductor device Q1, the non-superimposed portions NSP1 to NSP7 and the superimposed portions SP1 to SP6 are alternately formed.

The feature of the power module 300 is to form all of the superimposed portions SP1 to SP6 and non-superimposed portions NSP1 to NSP7 by patterning. Accordingly, as obvious also from FIG. 58, the first insulating substrate 10 and the second insulating substrate 20 are superimposed on each other so as to match the respective edge portions of the respective substrates to each other.

Moreover, the third conductive layer 14U may be formed at the U side of the second insulating substrate 20 so that the third conductive layer 14U may include a positive electrode pattern or a negative electrode pattern. In this case, in FIG. 58, the third conductive layer 14U and each of the positive electrode patterns 6WU₂, 6VU₂, 6UU₂ of the second conductive layer 613, for example, are connected to each other through a through hole (not illustrated). According to such a configuration, a bus bar (common electrode) of the positive electrode can be formed of the third conductive layer 14U.

By using the third conductive layer 14U as the bus bar, a current path can be shortened and thereby the inductance component can be reduced. Moreover, since there is no necessary to connect the power terminals to each other at the outside of the power module, the power module can also be ultra-thinned and miniaturized. The third conductive layer 14U is easy to use as a bus bar of the negative electrode by being connected to each of the negative electrode patterns 6UU₃, 6VU₃, 6WU₃ of the second conductive layer 6U through a through hole.

Moreover, since the first insulating substrate 10 and the second insulating substrate 20 are disposed so as to be superimposed on each other in this way, a warpage due to the first and second insulating substrates 10, 20 can be mutually cancelled, and such a warpage can be reduced. Moreover, the warpage can be further effectively reduced by forming substantially identical area of the first insulating substrate 10 and the second insulating substrate 20.

Moreover, the warpage can be more effectively reduced by forming substantially similar material(s) of the first insulating substrate 10 and the second insulating substrate 20. Moreover, such a warpage can further be reduced by forming thicknesses of the respective substrates to be substantially identical. The term “substantially identical” means that the similar operation/working-effect can be obtained, even if both are not exactly identical to each other.

A possibility of delamination of the mold resin 15, an occurrence of cracks, an occurrence of an insulation failure, etc. can be reduced by reducing such a warpage, and thereby reliability of the power module can be improved. Moreover, such an operation/working-effect of reducing the warpage can be produced also by the power modules 100, 200.

### (Fabrication Method)

A fabrication method of the power module 300 according to the sixth embodiment will now be explained.

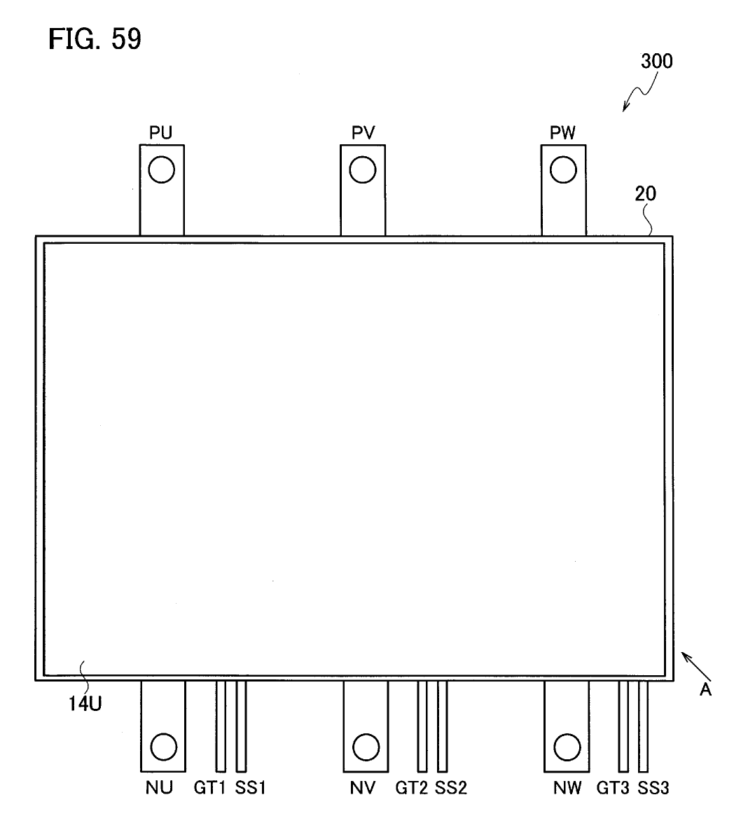

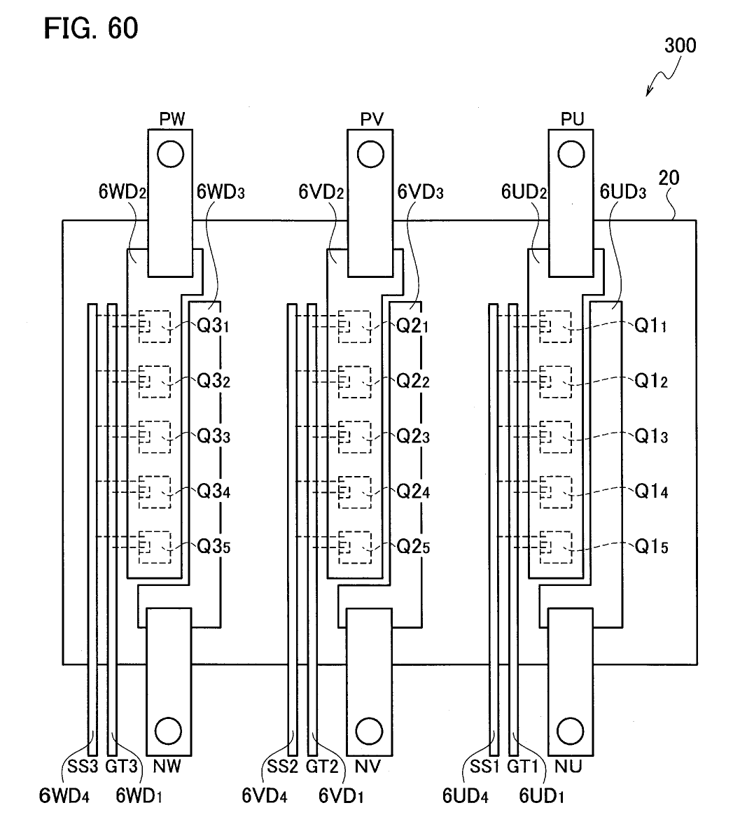

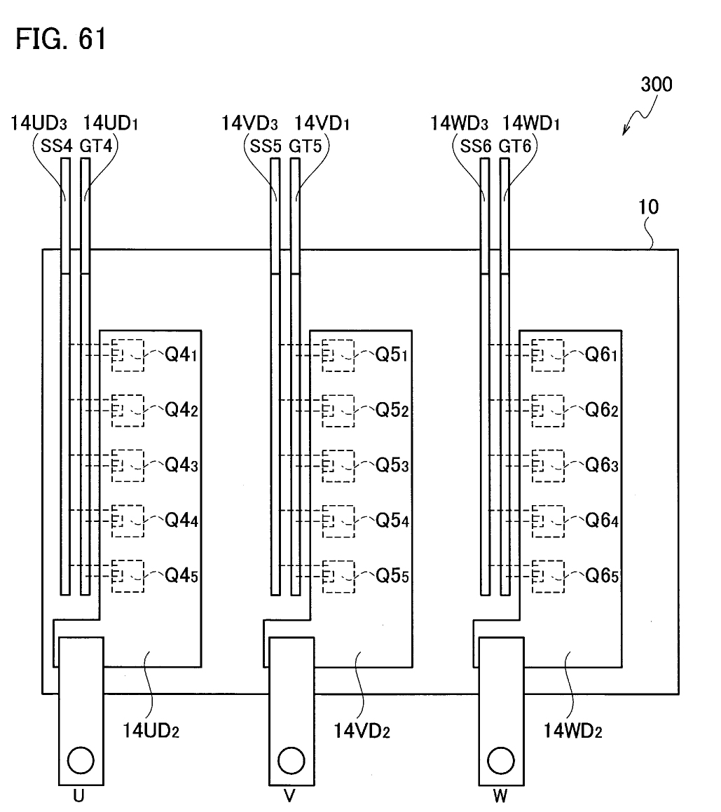

FIG. 59 shows a schematic plain diagram (of the side opposite to the D side) of the second insulating substrate 20 of the power module 300. Similarly, FIG. 60 shows a schematic plain diagram of the D side of the second insulating substrate 20 before mounting. Moreover, FIG. 61 shows a schematic plain diagram of the U side of the first insulating substrate 10 of the power module 300 before mounting.

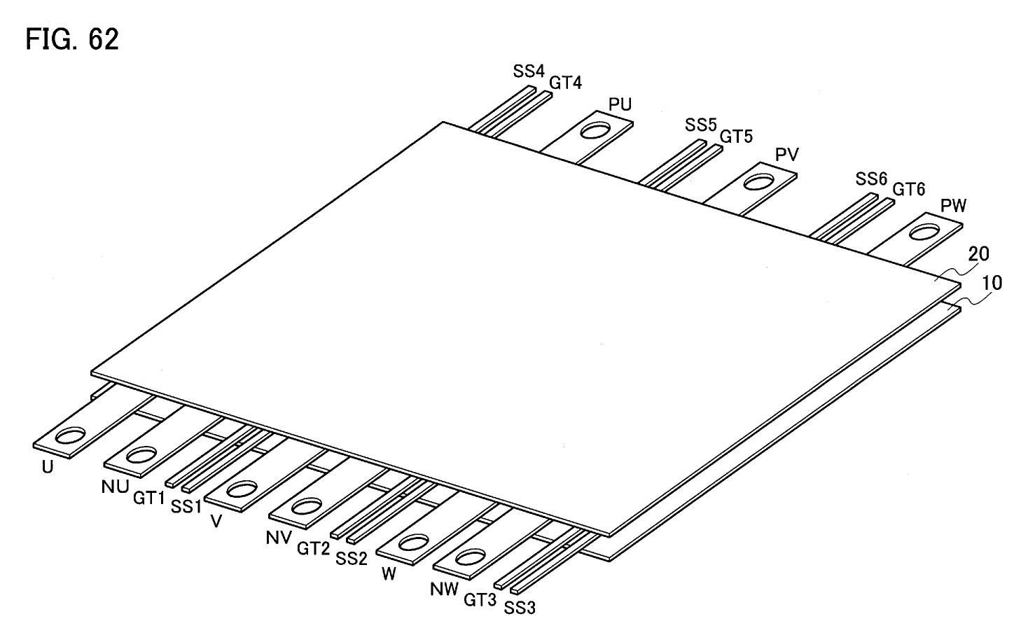

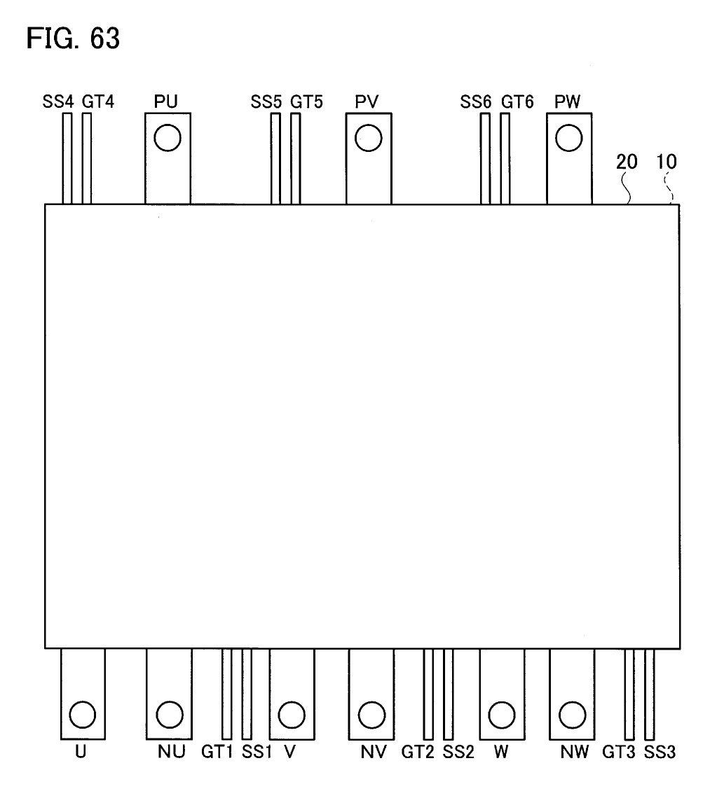

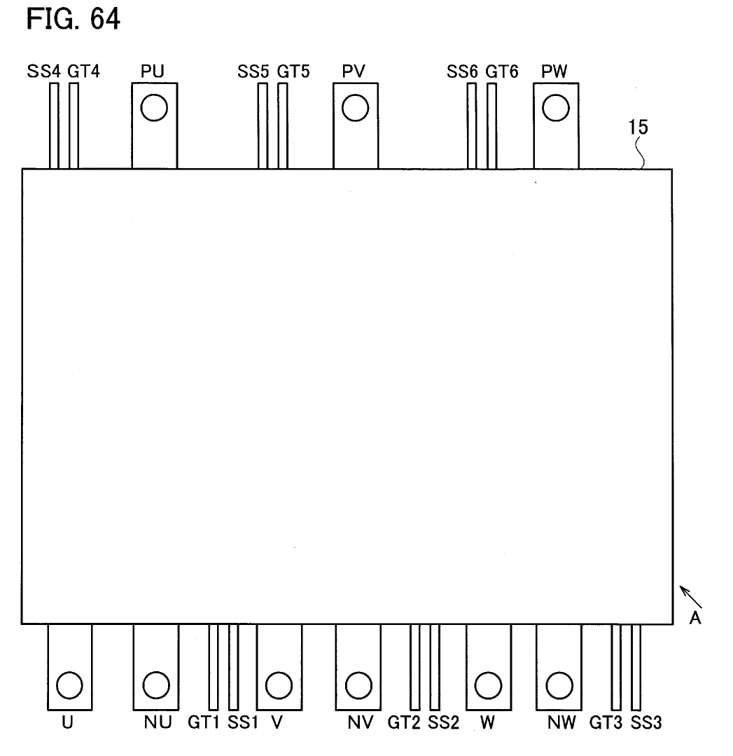

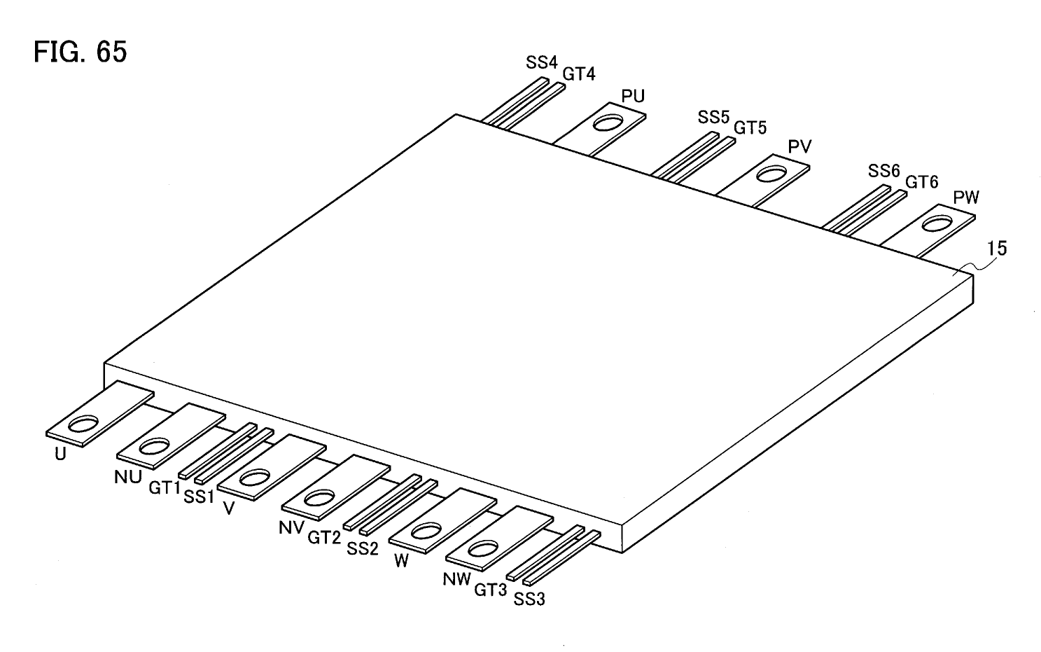

Moreover, FIG. 62 shows a schematic bird's-eye view configuration diagram of an aspect immediately before bonding the first insulating substrate 10 to the second insulating substrate 20 after mounting the power module 300, observed from the arrow A of FIG. 59. Moreover, FIG. 63 shows a schematic plain diagram (of the side opposite to the D side) after bonding the aforementioned second insulating substrate 20 to the first insulating substrate 10. Moreover, FIG. 64 shows a schematic plain diagram of the power module 300 after resin sealing. FIG. 65 shows a schematic bird's-eye view configuration diagram of an outer appearance after resin sealing, observed from the arrow A of FIG. 64.

The fabrication method of the power module 300 comprises: pattern-forming a non-superimposed portion NSP including only any one of a first conductive layer 14D and a second conductive layers 6U and a superimposed portion SP including both of the first conductive layer 14D and the second conductive layer 6U, in a planar view of a second insulating substrate 20 disposed so as to be opposite to a first insulating substrate 10 including the first conductive layer 14D, the second insulating substrate 20 including the second conductive layer 6U formed so as to be opposite to the first conductive layer 14D; connecting a first main electrode of the first semiconductor device Q4 to the superimposed portion SP of the first conductive layer 14D in a position where a first control electrode of the first semiconductor device Q4 is disposed at the non-superimposed portion NSP; connecting a first main electrode of the second semiconductor device Q1 to the superimposed portion SP of the second conductive layer 6U in a position where a second control electrode of the second semiconductor device Q1 is disposed at the non-superimposed portion NSP; and connecting a second main electrode of the first semiconductor device Q4 to the second conductive layer 6U, and connecting a second main electrode of the second semiconductor device Q1 to the first conductive layer 14D.

(a) Firstly, the first conductive layer 14D on a front side surface of the first insulating substrate 10 of a portion opposite to the second control electrode of the second semiconductor device Q1 is patterned. Each pattern is formed by etching the conductive layer 14D (FIG. 61). Similarly, the second conductive layer 6U on a front side surface of the second insulating substrate 20 of a portion opposite to the control signal terminal of the first semiconductor device Q4 is patterned (FIG. 60).
(b) Next, the first main electrode of the first semiconductor device Q4 is connected to the first conductive layer 14D, and the first main electrode of the second semiconductor device Q1 is connected to the second conductive layer 6U in a lower side surface of the second insulating substrate 20 disposed so as to be opposite to the first insulating substrate 10.
(c) Next, the first control electrode of the first semiconductor device Q4 is connected to a first gate signal pattern 14UD₁ (GT4) with a bonding wire, and the second control electrode of the second semiconductor device Q1 is connected to a second gate signal pattern 6UD₁ (GT1) with a bonding wire.
(d) Next, the second main electrode of the first semiconductor device Q4 and the second conductive layer 6U are connected to each other with a bonding wire, and the second main electrode of the second semiconductor device Q1 and the first conductive layer 14D are connected by a bonding wire.
(e) Next, at least a mounting surface of each semiconductor device of each of the first insulating substrate 10 and the second insulating substrate 20, an opposed portion of each substrate, and an end surface of each substrate are sealed with the mold resin 15. Furthermore, a cooling apparatus may be mounted on anyone or both of the lower side surface of the first insulating substrate 10, on which the semiconductor devices Q1 to Q6 are disposed, and the front side surface of the second insulating substrate 20.

Other methods are also supposed although the power modules 100, 200 can also be fabricated by means of the similar fabrication method as that of the power module 300.

The fabrication method of the power modules 100, 200 may include: connecting the first main electrode of the first semiconductor device Q4 to the first conductive layer 14D on the upper side surface of the first insulating substrate 10; connecting the first main electrode of the second semiconductor device Q1 to the second conductive layer 6U on the lower side surface of the second insulating substrate 20; connecting the first insulating substrate 10 and the second insulating substrate 20 in a disposition where the second main electrode of the first semiconductor device Q4 and the second conductive layer 6U are superimposed on each other, the second main electrode of the second semiconductor device Q1 and the first conductive layer 14D are superimposed on each other, the first control electrode of the first semiconductor device Q4 and the second conductive layer 6U are not superimposed on each other, and the second control electrode of the second semiconductor device Q1 and the first conductive layer 14D are not superimposed on each other.

That is, the power modules 100, 200 are formed so that the first insulating substrate 10 and the second insulating substrate after mounting are superimposed on each other so that the respective plane positions thereof are displaced from each other, and the control electrode of the semiconductor device is disposed at the non-superimposed portion. Accordingly, also after connecting the first and the second insulating substrates 10, 20, the control electrode of the semiconductor device can be connected to the control terminal.

### Illustrative Examples of Power Modules

Illustrative examples of the power modules according to the fourth to sixth embodiments respectively are similarly shown as FIGS. 28 to 30.

### Configuration Examples of Semiconductor Devices

Configuration examples of the semiconductor devices applicable to the fourth to sixth embodiments respectively are similarly shown as FIGS. 31 to 35.

A circuit configuration example of applying an SiC MOSFET as a semiconductor device and connecting a snubber capacitor C between a power terminal PL and a ground terminal NL is similarly shown as FIG. 36A, in a schematic circuit configuration of the three-phase AC inverter 140. Similarly, a circuit configuration example of applying an IGBT as a semiconductor device and connecting a snubber capacitor C between the power terminal PL and the ground terminal NL is similarly shown as FIG. 36, in a schematic circuit configuration of the three-phase AC inverter 140A.

### Application Examples for Applying Power Module

A schematic circuit configuration diagram showing a three-phase AC inverter 140 composed using the power module according to the fourth to sixth embodiments, to which the SiC MOSFET is applied as the semiconductor device, is similarly shown as FIG. 37.

A schematic circuit configuration diagram showing a three-phase AC inverter 140A composed using the power module 20T according to the fourth to sixth embodiments, to which the IGBT is applied as the semiconductor device, is similarly shown as FIG. 38.

The power modules according to the fourth to sixth embodiment can be formed as any one selected from the group consist of 1-in-1 module, 2-in-1 module, 4-in-1 module, and 6-in-1 module.

### Configuration Example of Power Module Including Cooling Apparatus

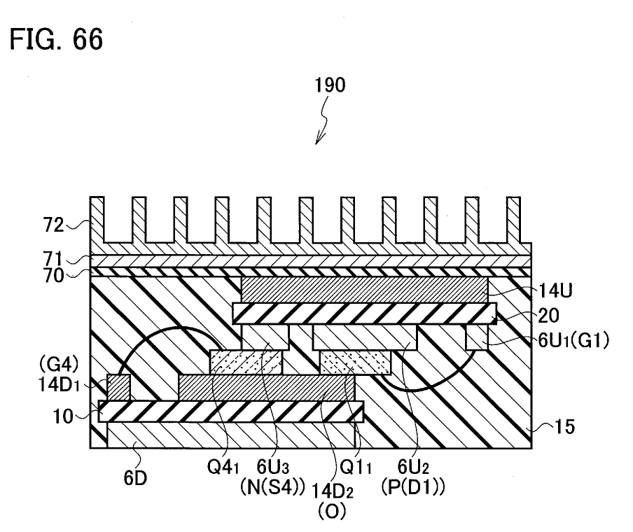

FIG. 66 shows a schematic tectonic profile of a power module 190 according to the fourth to sixth embodiments including a cooling apparatus 72. The power module 190 includes a cooling apparatus 72 disposed on any one of or both of the lower side surface of the first insulating substrate 10 and the upper side surface of the a second insulating substrate.

The power module 190 is a module on which the cooling apparatus 72 is mounted or attached on the power module 100 according to the fourth embodiment. The power module 190 further includes an insulating plate 70, a heat exchanger plate 71, and a cooling apparatus 72.

The insulating plate 70 is disposed so as to be contacted with a surface at the U side of the second insulating substrate 20 which constitutes the power module 100. The insulating plate 70 insulates the conductive layer 14U at the U side of the second insulating substrate 20 from the cooling apparatus 72.

The heat exchanger plate 71 is disposed on a surface at the U side of the insulating plate 70, and the cooling apparatus 72 is also disposed at the U side thereof. The cooling apparatus 72 is an air-cooling fin in this example. Alternatively, a water-cooling apparatus may be applied thereto. It is not necessary to always provide such a heat exchanger plate 71.

According to the power module 190, heat can be efficiently thermally dissipated from the second insulating substrate 20 since the distance between the first insulating substrate 10 and the second insulating substrate are short (thin). The heat can be thermally dissipated still more efficiently by providing the cooling apparatus 72 also on the surface at the D side of the first insulating substrate 10 which constitutes the power module 90, in particular, to cool both of the surfaces. The cooling apparatus 72 may be disposed on any one or both of the front side surface at the D side of the first insulating substrate 10, and the surface (front side surface at the side of the upper surface of the second insulating substrate) of the second insulating substrate 20 to not be opposite to the first insulating substrate 10.

As explained above according to the fourth to sixth embodiments, since the parts for wiring of the lead members 12, 13 etc. are not required therefor, the distance between the first semiconductor device Q4 and the second semiconductor device Q1 can be shortened. That is, according to the configurations of fourth to sixth embodiments, the plane size of the power module can be miniaturized. Since the first insulating substrate 10 and the second insulating substrate 20 can be disposed so as to be opposite to each other so as to share the amount of the thickness of the chip of the semiconductor device, the power module can be ultra-thinned and can be miniaturized.

Moreover, since the first and second insulating substrates are disposed so as to be opposite to each other, the warpage of the power module can be reduced and thereby reliability of the power module can be improved.

### Other Embodiments

As explained above, the first to sixth embodiments have been described, as a disclosure including associated description and drawings to be construed as illustrative, not restrictive. This disclosure makes clear a variety of alternative embodiments, working examples, and operational techniques for those skilled in the art.

Such being the case, the embodiments cover a variety of embodiments, whether described or not.

### INDUSTRIAL APPLICABILITY

The embodiments are applicable to power modules using power circuit elements, e.g. IGBTs, diodes, and (any one of Si based, a SiC based, a GaN based or an AiN based) MOSs, and can be use for wide applicable fields, e.g. inverters for Hybrid Electric Vehicles (HEVs)/Electric Vehicles (EVs), inverters or converters for industrial equipment.

What is claimed is:

1. A power module comprising:
a first insulating substrate comprising a first conductive layer;
a first semiconductor device disposed on the first conductive layer, the first semiconductor device of which one side of a main electrode is connected to the first conductive layer;
a second insulating substrate disposed on the first insulating substrate so as to be opposite to the first semiconductor device, the second insulating substrate including a second conductive layer formed on a front side surface thereof and a third conductive layer formed on a back side surface thereof;
a first pillar electrode configured to connect between the first conductive layer and the second conductive layer; and
a second pillar electrode configured to connect between another side of the main electrode of the first semiconductor device and the third conductive layer, wherein
the second conductive layer is connected to any one of a positive electrode pattern or a negative electrode pattern for supplying power to the first semiconductor device, and the third conductive layer is connected to another electrode pattern.

2. The power module according to claim 1, wherein,
the positive electrode pattern is disposed on any one of the second conductive layer and the third conductive layer, and the negative electrode pattern is disposed on another conductive layer.

3. The power module according to claim 1, wherein,
the first conductive layer comprises a first common electrode pattern connected to the same type of the main electrodes of a plurality of the first semiconductor devices.

4. The power module according to claim 3, further comprising:
a second common electrode pattern different from the first common electrode pattern of the first conductive layer;
a second semiconductor device disposed on the second common electrode pattern; and
a lead member configured to connect between the first common electrode pattern and one side of a main electrode of the second semiconductor device.

5. The power module according to claim 4, wherein
any one of the main electrode of the semiconductor device and the first common electrode pattern or second common electrode pattern are connected via the third conductive layer of the second insulating substrate and the first pillar electrode, and
the other of the first common electrode pattern and the second common electrode pattern is connected to the second conductive layer via the second pillar electrode and a via hole configured to pass through the second insulating substrate.

6. The power module according to claim 1, wherein
the second conductive layer comprises a plurality of electrode patterns, and the positive electrode pattern and the negative electrode pattern are alternately disposed on both surfaces of the second insulating substrate.

7. The power module according to claim 5, wherein
the via holes are disposed in series on the second insulating substrate, and the pillar electrodes are disposed in parallel to the row of the via holes.

8. The power module according to claim 7, wherein
in the row of the via holes, a via hole of the positive electrode and a via hole of the negative electrode are alternately disposed.

9. The power module according to claim 1, wherein
the first insulating substrate comprises an output terminal, and
the second insulating substrate comprises a power terminal.

10. A power module comprising:
a first insulating substrate;
a second insulating substrate disposed at an upper side of the first insulating substrate; and
a first semiconductor device disposed on the first insulating substrate, the first semiconductor device comprising a first main electrode and a first control electrode on a front side surface thereof, wherein
the first main electrode is disposed at a superimposed portion between the first insulating substrate and the second insulating substrate, and
the first control electrode is disposed at a non-superimposed portion between the first insulating substrate and the second insulating substrate.

11. The power module according to claim 10, further comprising
a second semiconductor device disposed on the second insulating substrate, the second semiconductor device comprising a second main electrode and a second control electrode on a front side surface thereof, wherein
the second control electrode is disposed at the non-superimposed portion.

12. The power module according to claim 11, wherein
a position of the superimposed portion is displaced with respect to a position of the non-superimposed portion so that the first main electrode and the second main electrode are respectively superimposed on the opposite substrates, and the first control electrode and the second control electrode are not respectively superimposed on the opposite substrates, in a planar view.

13. The power module according to claim 11, further comprising:
a first non-superimposed portion; and
a second non-superimposed portion, wherein
the first control electrode is disposed at the first non-superimposed portion, and the second control electrode is disposed at the second non-superimposed portion, in a planar view.

14. A power module comprising:
a first insulating substrate comprising a first conductive layer;
a second insulating substrate of which at least a portion is disposed so as to be opposite to the first insulating substrate, the second insulating substrate comprising a second conductive layer formed so as to be opposite to the first conductive layer;
a first semiconductor device of which a first main electrode is connected to the first conductive layer;
a second semiconductor device of which a first main electrode is connected to the second conductive layer;
a non-superimposed portion comprising only any one of the first conductive layer and the second conductive layer, in a planar view; and
a superimposed portion comprising both of the first conductive layer and the second conductive layer, in a planar view, wherein
the second main electrode of the first semiconductor device and the second conductive layer, and the second main electrode of the second semiconductor device and the first conductive layer are disposed at the superimposed portion, in a planar view, and
the first control electrode of the first semiconductor device and the second control electrode of the second semiconductor device are disposed at the non-superimposed portion, in a planar view.

15. The power module according to claim 14, further comprising:
a plurality of the superimposed portions; and
a plurality of the non-superimposed portions, wherein
the first semiconductor device and the second semiconductor device are formed so that a plurality of elements are aligned to one another in a line in series, and
the non-superimposed portion and the superimposed portion are alternately disposed in an arrangement direction of the first semiconductor device and the second semiconductor device.

16. The power module according to claim 11, further comprising:
an output pattern formed by patterning the first conductive layer on an upper side surface of the first insulating substrate; and
a positive electrode pattern and negative electrode pattern formed by patterning the second conductive layer on a lower side surface of the second insulating substrate, wherein
one of the main electrode of the first semiconductor device is connected to the output pattern,
the other of the main electrode of the first semiconductor device is connected to the negative electrode pattern,
one of the main electrode of the second semiconductor device is connected to the positive electrode pattern, and
the other of the main electrode of the second semiconductor device is connected to the output pattern.

17. The power module according to claim 16, wherein
the output pattern, the positive electrode pattern, and the negative electrode pattern are disposed so as to be extended to the outside of the first insulating substrate and the second insulating substrate, on which each pattern is formed, in a planar view.

18. The power module according to claim 16, wherein
the first conductive layer comprises a first common electrode pattern connected to the same type of the main electrodes of a plurality of the first semiconductor devices, and
the second conductive layer comprises a second common electrode pattern connected to the same type of the main electrodes of a plurality of the second semiconductor devices.

19. The power module according to claim 16, further comprising
a third conductive layer on an upper side surface of the second insulating substrate, wherein
the third conductive layer comprising the positive electrode pattern or the negative electrode pattern.
